(19) United States
(12) Patent Application Publication
(10) Pub. No.: US 2024/0365602 A1
(43) Pub. Date: Oct. 31, 2024

(54) Display Apparatus, Display Module, Electronic Device, And Method For Manufacturing Display Apparatus

(71) Applicant: Semiconductor Energy Laboratory Co., Ltd., Kanagawa-ken (JP)

(72) Inventors: Shunpei YAMAZAKI, setagaya, Tokyo (JP); Hidekazu MIYAIRI, Hadano, Kanagawa (JP); Ryo TAGASHIRA, Isehara, Kanagawa (JP)

(73) Assignee: Semiconductor Energy Laboratory Co., Ltd., Kanagawa-ken (JP)

(21) Appl. No.: 18/685,679

(22) PCT Filed: Aug. 9, 2022
(86) PCT No.: PCT/IB2022/057404

§ 371 Date: Feb. 22, 2024

(30) Foreign Application Priority Data
Aug. 26, 2021 (JP) 2021-138046

(51) Int. Cl. H10K 59/122; H10K 59/12

(52) U.S. Cl. CPC H10K 59/122; H10K 59/1201

(57) ABSTRACT

A highly reliable display apparatus is provided. The display apparatus includes a first light-emitting element, a second light-emitting element, a first insulating layer, and a second insulating layer. The first light-emitting element includes a first pixel electrode, a first EL layer over the first pixel electrode, and a common electrode over the first EL layer. The second light-emitting element includes a second pixel electrode, a second EL layer over the second pixel electrode, and the common electrode over the second EL layer. The first insulating layer covers the side surface and part of the top surface of the first EL layer and the side surface and part of the top surface of the second EL layer. The second insulating layer overlaps with part of the top surface of the first EL layer and part of the top surface of the second EL layer with the first insulating layer therebetween, includes a region positioned between the side surface of the first EL layer and the side surface of the second EL layer, and includes a depressed portion in a position overlapping with the region. The common electrode is provided over the second insulating layer.

### TECHNICAL FIELD

One embodiment of the present invention relates to a display apparatus, a display module, and an electronic device. One embodiment of the present invention relates to a method for manufacturing a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

Recent display apparatuses have been expected to be applied to a variety of uses. Examples of uses for a large display apparatus include a television device for home use (also referred to as a TV or a television receiver), digital signage, and a PID (Public Information Display). In addition, a smartphone, a tablet terminal, and the like including a touch panel are being developed as portable information terminals.

Furthermore, display apparatuses have been required to have higher resolution. For example, devices for virtual reality (VR), augmented reality (AR), substitutional reality (SR), and mixed reality (MR) are given as devices required by high-resolution display apparatuses and have been actively developed.

Light-emitting apparatuses including light-emitting elements (also referred to as light-emitting devices) have been developed as display apparatuses, for example. Light-emitting elements (also referred to as EL elements or organic light-emitting elements) utilizing an electroluminescence (hereinafter referred to as EL) phenomenon have features such as ease of reduction in thickness and weight, high-speed response to an input signal, and driving with a direct-constant voltage source, and have been used in display apparatuses.
Patent Document 1 discloses a display apparatus for VR using an organic EL element (also referred to as an organic EL device).
Non-Patent Document 1 discloses a method for manufacturing an organic optoelectronic device using standard UV photolithography.

### REFERENCE

### Patent Document

[Patent Document 1] PCT International Publication No. 2018/087625
[Non-Patent Document 1] B. Lamprecht et al., “Organic optoelectronic device fabrication using standard UV photolithography” phys. Stat. sol. (RRL) 2, No. 1, p. 16-18 (2008)

### SUMMARY OF THE INVENTION

### Problems to be Solved by the Invention

For example, when stress is applied to a layer included in a display apparatus, the adhesion between films is decreased, leading to film separation in some cases. This reduces the yield of the display apparatus and the reliability of the display apparatus in some cases.

An object of one embodiment of the present invention is to provide a highly reliable display apparatus. Another object of one embodiment of the present invention is to provide a display apparatus with high display quality. Another object of one embodiment of the present invention is to provide a high-resolution display apparatus. Another object of one embodiment of the present invention is to provide a high-definition display apparatus. Another object of one embodiment of the present invention is to provide a novel display apparatus.

Another object of one embodiment of the present invention is to provide a method for manufacturing a display apparatus with a high yield. Another object of one embodiment of the present invention is to provide a method for manufacturing a highly reliable display apparatus. Another object of one embodiment of the present invention is to provide a method for manufacturing a display apparatus with high display quality. Another object of one embodiment of the present invention is to provide a method for manufacturing a high-resolution display apparatus. Another object of one embodiment of the present invention is to provide a method for manufacturing a high-definition display apparatus. Another object of one embodiment of the present invention is to provide a method for manufacturing a novel display apparatus.

Note that the description of these objects does not preclude the existence of other objects. One embodiment of the present invention does not need to achieve all of these objects. Other objects can be derived from the description of the specification, the drawings, or the claims.

### Means for Solving the Problems

One embodiment of the present invention is a display apparatus that includes a first light-emitting element, a second light-emitting element, a first insulating layer, and a second insulating layer. The first light-emitting element includes a first pixel electrode, a first EL layer over the first pixel electrode, and a common electrode over the first EL layer. The second light-emitting element includes a second pixel electrode, a second EL layer over the second pixel electrode, and the common electrode over the second EL layer. The first insulating layer covers a side surface and part of a top surface of the first EL layer and a side surface and part of a top surface of the second EL layer. The second insulating layer overlaps with the part of the top surface of the first EL layer and the part of the top surface of the second EL layer with the first insulating layer therebetween. The second insulating layer includes a region positioned between the side surface of the first EL layer and the side surface of the second EL layer. The second insulating layer includes a depressed portion in a position overlapping with the region. The common electrode is provided over the second insulating layer.

In the above embodiment, the depressed portion of the second insulating layer may have a concave shape.

In the above embodiment, a shortest part in the depressed portion in a cross-sectional view does not necessarily overlap with either the first EL layer or the second EL layer.

In the above embodiment, the first EL layer may include a first light-emitting layer and a first functional layer over the first light-emitting layer, the second EL layer may include a second light-emitting layer and a second functional layer over the second light-emitting layer, and the first functional layer and the second functional layer may each include at least one of a hole-injection layer, an electron-injection layer, a hole-transport layer, an electron-transport layer, a hole-blocking layer, and an electron-blocking layer.

In the above embodiment, the second insulating layer may cover at least part of a side surface of the first insulating layer.

In the above embodiment, an end portion of the second insulating layer may be positioned on an outer side of an end portion of the first insulating layer.

In the above embodiment, the end portion of the first insulating layer and the end portion of the second insulating layer may have a tapered shape with a taper angle of less than 90° in a cross-sectional view.

In the above embodiment, a third insulating layer and a fourth insulating layer may be included, the third insulating layer may be positioned between the top surface of the first EL layer and the first insulating layer, the fourth insulating layer may be positioned between the top surface of the second EL layer and the first insulating layer, and an end portion of the third insulating layer and an end portion of the fourth insulating layer may each be positioned on the outer side of the end portion of the first insulating layer.

In the above embodiment, the second insulating layer may cover at least part of a side surface of the third insulating layer and at least part of a side surface of the fourth insulating layer. In the above embodiment, the end portion of the third insulating layer and the end portion of the fourth insulating layer may each have a tapered shape with a taper angle of less than 90° in a cross-sectional view.

In the above embodiment, the first insulating layer may be an inorganic insulating layer and the second insulating layer may be an organic insulating layer.

A display module including the display apparatus of one embodiment of the present invention and at least one of a connector and an integrated circuit is also one embodiment of the present invention.

An electronic device including the display module of one embodiment of the present invention and at least one of a housing, a battery, a camera, a speaker, and a microphone is also one embodiment of the present invention.

Another embodiment of the present invention is a method for manufacturing a display apparatus that includes: forming a first pixel electrode and a second pixel electrode; forming a first EL film over the first pixel electrode and the second pixel electrode; forming a first mask film over the first EL film; forming a first EL layer over the first pixel electrode and a first mask layer over the first EL layer by processing the first EL film and the first mask film; forming a second EL film over the first mask layer and over the second pixel electrode; forming a second mask film over the second EL film; forming a second EL layer over the second pixel electrode and a second mask layer over the second EL layer by processing the second EL film and the second mask film; forming an inorganic insulating film over the first mask layer and over the second mask layer;

forming an organic insulating film over the inorganic insulating film with the use of a photosensitive material; forming an organic insulating layer in a region positioned between a side surface of the first EL layer and a side surface of the second EL layer by performing first light exposure and first development on the organic insulating film; reducing the thickness of part of the inorganic insulating film by performing first etching treatment on the inorganic insulating film with the use of a first chemical solution and the organic insulating layer as a mask; performing second light exposure on the organic insulating layer; performing, with the use of a second chemical solution functioning as a developer, second development on the organic insulating layer and second etching treatment on the inorganic insulating film, the first mask layer, and the second mask layer with the use of the organic insulating layer as a mask to form a depressed portion in the organic insulating layer in a position overlapping with the region, form an inorganic insulating layer under the organic insulating layer, and reduce a thickness of part of the first mask layer and a thickness of part of the second mask layer; curing the organic insulating layer by performing heat treatment; performing third etching treatment on the first mask layer and the second mask layer with the use of a third chemical solution and the organic insulating layer as a mask to expose a top surface of the first EL layer and a top surface of the second EL layer; and forming a common electrode over the first EL layer, over the second EL layer, and over the organic insulating layer.

In the above embodiment, energy density of the second light exposure may be lower than energy density of the first light exposure.

In the above embodiment, the first chemical solution may function as a developer.

In the above embodiment, the first chemical solution and the third chemical solution may function as a developer.

In the above embodiment, the first mask film and the second mask film may contain the same material as the inorganic insulating film.

In the above embodiment, the first mask film, the second mask film, and the inorganic insulating film may each be formed by an ALD method.

In the above embodiment, a first light-emitting film and a first functional film over the first light-emitting film may be formed as the first EL film, a second light-emitting film and a second functional film over the second light-emitting film may be formed as the second EL film, and the first functional film and the second functional film may each include at least one of films to be a hole-injection layer, an electron-injection layer, a hole-transport layer, an electron-transport layer, a hole-blocking layer, and an electron-blocking layer.

### Effect of the Invention

According to one embodiment of the present invention, a highly reliable display apparatus can be provided. According to another embodiment of the present invention, a display apparatus with high display quality can be provided. According to another embodiment of the present invention, a high-resolution display apparatus can be provided. According to another embodiment of the present invention, a high-definition display apparatus can be provided.

According to another embodiment of the present invention, a novel display apparatus can be provided.

According to another embodiment of the present invention, a method for manufacturing a display apparatus with a high yield can be provided. According to another embodiment of the present invention, a method for manufacturing a highly reliable display apparatus can be provided. According to another embodiment of the present invention, a method for manufacturing a display apparatus with high display quality can be provided. According to another embodiment of the present invention, a method for manufacturing of a high-definition display apparatus can be provided. According to another embodiment of the present invention, a method for manufacturing a high-resolution display apparatus can be provided. According to another embodiment of the present invention, a method for manufacturing a novel display apparatus can be provided.

Note that the description of these effects does not preclude the existence of other effects. One embodiment of the present invention does not necessarily have all of these effects. Other effects can be derived from the description of the specification, the drawings, or the claims.

### BRIEF DESCRIPTION OF THE DRAWINGS

FIG. 1 is a plan view illustrating a structure example of a display apparatus.

FIG. 2 is a cross-sectional view illustrating a structure example of a display apparatus.

FIG. 3A and FIG. 3B are cross-sectional views illustrating a structure example of a display apparatus.

FIG. 4A and FIG. 4B are cross-sectional views illustrating a structure example of a display apparatus.

FIG. 5A and FIG. 5B are cross-sectional views illustrating a structure example of a display apparatus.

FIG. 6A and FIG. 6B are cross-sectional views illustrating a structure example of a display apparatus.

FIG. 7A and FIG. 7B are cross-sectional views each illustrating a structure example of a display apparatus.

FIG. 8A and FIG. 8B are cross-sectional views illustrating a structure example of a display apparatus.

FIG. 9 is a cross-sectional view illustrating a structure example of a display apparatus.

FIG. 10A to FIG. 10D are cross-sectional views illustrating an example of a method for manufacturing a display apparatus.

FIG. 11A to FIG. 11D are cross-sectional views illustrating an example of a method for manufacturing a display apparatus.

FIG. 12A to FIG. 12C are cross-sectional views illustrating an example of a method for manufacturing a display apparatus.

FIG. 13A, FIG. 13B1, and FIG. 13B2 are cross-sectional views illustrating an example of a method for manufacturing a display apparatus.

FIG. 14A1, FIG. 14A2, and FIG. 14B are cross-sectional views illustrating an example of a method for manufacturing a display apparatus.

FIG. 15A1, FIG. 15A2, and FIG. 15B are cross-sectional views illustrating an example of a method for manufacturing a display apparatus.

FIG. 16A and FIG. 16B are cross-sectional views illustrating an example of a method for manufacturing a display apparatus.

FIG. 17A and FIG. 17B are cross-sectional views illustrating an example of a method for manufacturing a display apparatus.

FIG. 18A and FIG. 18B are cross-sectional views illustrating an example of a method for manufacturing a display apparatus.

FIG. 19A to FIG. 19C are cross-sectional views illustrating an example of a method for manufacturing of a display apparatus.

FIG. 20A to FIG. 20G are plan views each illustrating a structure example of a pixel.

FIG. 21A to FIG. 21H are plan views each illustrating a structure example of a pixel.

FIG. 22A and FIG. 22B are perspective views illustrating a structure example of a display module.

FIG. 23A and FIG. 23B are cross-sectional views illustrating a structure example of a display apparatus.

FIG. 24 is a cross-sectional view illustrating a structure example of a display apparatus.

FIG. 25 is a cross-sectional view illustrating a structure example of a display apparatus.

FIG. 26 is a cross-sectional view illustrating a structure example of a display apparatus.

FIG. 27 is a cross-sectional view illustrating a structure example of a display apparatus.

FIG. 28 is a cross-sectional view illustrating a structure example of a display apparatus.

FIG. 29 is a perspective view illustrating a structure example of a display apparatus.

FIG. 30A is a cross-sectional view of a structure example of a display apparatus. FIG. 30B and FIG. 30C are cross-sectional views illustrating structure examples of transistors.

FIG. 31A to FIG. 31D are cross-sectional views illustrating structure examples of a display apparatus.

FIG. 32 is a cross-sectional view illustrating a structure example of a display apparatus.

FIG. 33 is a cross-sectional view illustrating a structure example of a display apparatus.

FIG. 34A to FIG. 34F are cross-sectional views illustrating structure examples of light-emitting elements.

FIG. 35A to FIG. 35D are diagrams illustrating examples of electronic devices.

FIG. 36A to FIG. 36F are diagrams illustrating examples of electronic devices.

FIG. 37A to FIG. 37G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description of embodiments below.

Note that in structures of the invention described below, the same reference numerals are commonly used for the same portions or portions having similar functions in different drawings, and a repeated description thereof is omitted. The same hatching pattern is applied to portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in the drawings.

In this specification and the like, the terms for describing positioning, such as “over” “under”, “above” and “below” are sometimes used for convenience to describe the positional relationship between components with reference to drawings. The positional relationship between components is changed as appropriate in accordance with a direction in which each component is described. Thus, the positional relation is not limited to the terms described in this specification and the like, and can be described with another term as appropriate depending on the situation. For example, the expression “an insulating layer positioned over (on) a top surface of a conductive layer” can be replaced with the expression “an insulating layer positioned under (on) a bottom surface of a conductive layer” when the direction of a drawing showing these components is rotated by 180°.

Note that the term “film” and the term “layer” can be interchanged with each other depending on the case or circumstances. For example, the term “conductive layer” can be changed into the term “conductive film” in some cases. As another example, the term “insulating film” can be changed into the term “insulating layer” in some cases.

In this specification and the like, a device formed using a metal mask or an FMM (fine metal mask, high-resolution metal mask) may be referred to as a device having an MM (metal mask) structure. In this specification and the like, a device formed without using a metal mask or an FMM is sometimes referred to as a device having an MML (metal maskless) structure.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that the above-described carrier-injection layer, carrier-transport layer, and carrier-blocking layer cannot be distinguished from each other in some cases by the cross-sectional shape, the characteristics, or the like. Furthermore, one layer may have two or three functions of the carrier-injection layer, the carrier-transport layer, and the carrier-blocking layer in some cases.

In this specification and the like, a light-emitting element includes an EL layer between a pair of electrodes. The EL layer includes at least a light-emitting layer. Examples of the layers in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a tapered shape indicates a shape in which at least part of the side surface of a structure is inclined to a substrate surface. For example, a tapered shape refers to a shape including a region where the angle between the inclined side surface and the substrate surface (also referred to as a taper angle) is less than 90°. Note that the side surface of a structure and the substrate surface are not necessarily completely flat and may be substantially flat with a slight curvature or substantially flat with slight unevenness.

### Embodiment 1

In this embodiment, a display apparatus of one embodiment of the present invention and a method for manufacturing the display apparatus will be described.

The display apparatus of one embodiment of the present invention is capable of full-color display. For example, a display apparatus capable of full-color display can be manufactured by separately forming EL layers including at least light-emitting layers for the respective emission colors. Alternatively, a display apparatus capable of full-color display can be manufactured by providing a coloring layer (also referred to as a color filter) over an EL layer that emits white light, for example.

In this specification and the like, a structure in which light-emitting layers in light-emitting elements of respective colors (e.g., blue (B), green (G), and red (R)) are separately formed or the light-emitting layers are separately patterned may be referred to as an SBS (Side By Side) structure. A light-emitting element capable of emitting white light may be referred to as a white-light-emitting element.

In the case of manufacturing a display apparatus including a plurality of light-emitting elements emitting light of different colors, light-emitting layers emitting light of different colors each need to be formed into an island shape. Even in the case of manufacturing a display apparatus including a white light-emitting element, light-emitting layers are each preferably formed into an island shape, in which case leakage current that would be generated between adjacent light-emitting elements through the light-emitting layers can be reduced.

Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

For example, an island-shaped light-emitting layer can be formed by a vacuum evaporation method using a metal mask. However, this method causes a deviation from the designed shape and position of an island-shaped light-emitting layer due to various influences such as the accuracy of the metal mask, the positional deviation between the metal mask and a substrate, a warp of the metal mask, and expansion of outline of the deposited film due to vapor scattering or the like; accordingly, it is difficult to achieve high resolution and a high aperture ratio of the display apparatus. In addition, the outline of a layer may blur during vapor deposition, whereby the thickness of an end portion may be small. That is, the thickness of the island-shaped light-emitting layer may vary from area to area. In the case of manufacturing a display apparatus with a large size, high definition, or high resolution, the manufacturing yield might be reduced because of low dimensional accuracy of the metal mask and deformation due to heat or the like.

In view of the above, to manufacture the display apparatus of one embodiment of the present invention, a light-emitting layer is processed into a fine pattern by photolithography without using a shadow mask such as a metal mask. Specifically, a light-emitting layer is formed across a plurality of pixel electrodes that have been formed for the respective subpixels. Then, the light-emitting layer is processed by photolithography, so that one island-shaped light-emitting layer is formed for every pixel electrode. Thus, the light-emitting layer can be divided for the respective subpixels, so that island-shaped light-emitting layers can be formed for the respective subpixels.

In the case of processing the light-emitting layer into an island shape, a conceivable structure is such that the light-emitting layer is processed by performing photolithography directly on the light-emitting layer. In the case of the structure, damage to the light-emitting layer, for example, processing damage might significantly degrade the reliability. In view of the above, to manufacture the display apparatus of one embodiment of the present invention, a method is preferably employed in which a mask layer (also referred to as a sacrificial layer, a protective layer, or the like) or the like is formed over a functional layer (e.g., a carrier-blocking layer, a carrier-transport layer, or a carrier-injection layer, specifically, a hole-blocking layer, an electron-transport layer, or an electron-injection layer) which is positioned above a light-emitting layer and is included, as well as the light-emitting layer, in an EL layer, and the light-emitting layer and the functional layer are processed into an island shape. This method enables a highly reliable display apparatus to be provided. A functional layer between the light-emitting layer and the mask layer can inhibit the light-emitting layer from being exposed on the outermost surface during the manufacturing process of the display apparatus and can reduce damage to the light-emitting layer.

In this specification and the like, a mask film (also referred to as a sacrificial film, a protective film, or the like) and a mask layer are positioned above at least a light-emitting layer (specifically, a layer processed into an island shape among layers included in an EL layer) and have a function of protecting the light-emitting layer in the manufacturing process.

An EL layer can include a functional layer below as well as above a light-emitting layer. Here, in the case where the light-emitting layer is processed into an island shape, a functional layer positioned below the light-emitting layer (e.g., a carrier-injection layer, a carrier-transport layer, or a carrier-blocking layer, and specifically, a hole-injection layer, a hole-transport layer, or an electron-blocking layer) is preferably processed into an island shape with the same pattern as the light-emitting layer. Processing the layer positioned below the light-emitting layer into an island shape with the same pattern as the light-emitting layer can reduce leakage current (sometimes referred to as horizontal-direction leakage current, horizontal leakage current, or a lateral leakage current) that would be generated between adjacent subpixels. For example, in the case where a hole-injection layer is shared by adjacent subpixels, horizontal leakage current would be generated because of the hole-injection layer. By contrast, in the display apparatus of one embodiment of the present invention, the hole-injection layer can be processed into an island shape with the same pattern as the light-emitting layer; thus, horizontal leakage current between adjacent subpixels is not substantially generated or can be extremely small.

Here, the EL layer is preferably provided to cover the top surface and the side surface of a pixel electrode. In that case, the aperture ratio can be easily increased as compared with the structure where an end portion of the EL layer is positioned inward from an end portion of the pixel electrode.

Note that it is not necessary to form all layers included in EL layers separately between light-emitting elements that exhibit different colors, and some of the layers can be formed in the same step. In the method for manufacturing a display apparatus of one embodiment of the present invention, after some layers included in the EL layers are formed into an island shape separately for the respective colors, at least part of the mask layer is removed and then the other layer included in the EL layers (sometimes referred to as a common layer) and a common electrode (also referred to as an upper electrode) are each formed (as a single film) to be shared by the light-emitting elements of all the colors. For example, a carrier-injection layer and the common electrode can be formed so as to be shared by the light-emitting elements of different colors.

Meanwhile, the carrier-injection layer is often a layer having relatively high conductivity in the EL layer. Therefore, when the carrier-injection layer is in contact with the side surface of any layer included in the island-shaped EL layer or the side surface of the pixel electrode, the light-emitting element might be short-circuited. Note that also in the case where the carrier-injection layer is formed into an island shape and the common electrode is formed to be shared by the light-emitting elements of the different colors, the light-emitting element might be short-circuited when the common electrode is in contact with the side surface of the EL layer or the side surface of the pixel electrode.

In view of the above, the display apparatus of one embodiment of the present invention includes an insulating layer between adjacent light-emitting elements. Specifically, the display apparatus of one embodiment of the present invention preferably includes an inorganic insulating layer that covers the side surfaces of island-shaped EL layers and the top and side surfaces of mask layers over the EL layers, and an organic insulating layer over the inorganic insulating layer.

This can inhibit at least some layers in the island-shaped EL layer and the pixel electrode from being in contact with the carrier-injection layer or the common electrode. Thus, a short circuit in the light-emitting element can be inhibited, leading to improved reliability of the light-emitting element.

Here, for example, in the case where the organic insulating layer has a convex shape, stress, specifically, compressive stress might be applied to an end portion of the organic insulating layer. This might cause the adhesion of a layer in contact with the organic insulating layer with another layer to be decreased, leading to film separation. For example, the adhesion between the EL layer including the light-emitting layer and the mask layer might be decreased, leading to film separation between the EL layer and the mask layer. This might reduce the yield of the display apparatus and increase the manufacturing cost of the display apparatus. Moreover, the reliability of the display apparatus might be lowered.

In view of the above, in the display apparatus of one embodiment of the present invention, a depressed portion is formed in the organic insulating layer. For example, a depressed portion is formed in the middle of the organic insulating layer in a cross-sectional view. Accordingly, local stress generated in an end portion of the organic insulating layer can be relieved, and the above-described film separation can be prevented, for example. Thus, generation of a defect in the display apparatus can be inhibited, which makes the display apparatus of one embodiment of the present invention highly reliable. Moreover, the display apparatus of one embodiment of the present invention can be manufactured by a high-yield method.

The organic insulating layer can contain a photosensitive material. In this case, in order to form an organic insulating layer having a depressed portion, an inorganic insulating film to be an inorganic insulating layer is formed, and then a photosensitive material is applied onto the inorganic insulating film. Then, first light exposure and first development are performed on the photosensitive material, whereby an organic insulating layer not having a depressed portion is formed between adjacent light-emitting elements. Next, second light exposure and second development are performed on the organic insulating layer not having a depressed portion, whereby a depressed portion is formed in the organic insulating layer. Note that when the energy density of the second light exposure is lower than the energy density of the first light exposure, the organic insulating layer can be prevented from being removed in a light-exposure portion in the second light exposure and the organic insulating layer from being split.

After the organic insulating layer is formed, the inorganic insulating film and the mask layer are processed using the organic insulating layer as a mask. In this manner, the inorganic insulating layer under the organic insulating layer is formed and at least part of the mask layer is removed, so that the top surface of the EL layer can be exposed. Then, a common layer and a common electrode are formed. Through the above steps, the light-emitting element including the pixel electrode, the EL layer, the common layer, and the common electrode can be formed.

A wet etching method is preferably used to process the inorganic insulating film and the mask layer. The use of a wet etching method can reduce damage to the EL layer as compared with the case of using a dry etching method. Here, in the case where the mask layer contains an inorganic insulating material, for example, wet etching can be performed on the inorganic insulating film and the mask layer with the use of a developer. Thus, the inorganic insulating film and the mask layer can be processed using the same chemical solution as the first development and the second development.

In that case, formation of the depressed portion in the organic insulating layer by the second development and processing of the inorganic insulating film, for example, are performed in parallel. In other words, formation of the depressed portion in the organic insulating layer by the second development and processing of the inorganic insulating film, for example, are performed at the same time or in the same step. Here, when the second development time is short, insufficient removal of the inorganic insulating film is caused. By contrast, when the second development time is long, the depressed portion in the organic insulating layer becomes deeper, and defective connection due to breakage, an increase in electric resistance due to local thinning, or the like is caused in some cases in the common layer and the common electrode provided over the organic insulating layer.

Note that in this specification and the like, breakage refers to a phenomenon in which a layer, a film, or an electrode is split because of the shape of the formation surface (e.g., a step).

In view of the above, in the method for manufacturing a display apparatus of one embodiment of the present invention, an organic insulating layer without a depressed portion is formed by first development, and then wet etching treatment using the organic insulating layer as a mask is performed on an inorganic insulating film with the use of a developer before second light exposure. Accordingly, the thickness of part of the inorganic insulating film is reduced. Since the second light exposure is not yet performed, the organic insulating layer is not processed, and therefore a depressed portion is not formed in the organic insulating layer.

In this manner, even when the second development time is short, the inorganic insulating film can be removed sufficiently. Thus, the depressed portion in the organic insulating layer can be inhibited from becoming deeper and a defect can be inhibited from being caused. Therefore, the method for manufacturing a display apparatus of one embodiment of the present invention can achieve a high yield. Note that the mask layer as well as the inorganic insulating film is processed by the second development in some cases. For example, the thickness of part of the mask layer is reduced by the second development in some cases.

After the second development, heat treatment is performed to cure the organic insulating layer. After that, wet etching treatment is performed on the mask layer using the organic insulating layer as a mask. Accordingly, at least part of the mask layer is removed to expose the top surface of the EL layer. Since the organic insulating layer is cured by the heat treatment, the organic insulating layer is not processed even when a developer is used for the wet etching treatment performed on the mask layer. Thus, the heat treatment can prevent the depressed portion in the organic insulating layer from becoming deeper due to the wet etching treatment, for example.

Then, a common layer and a common electrode are formed. Through the above steps, the light-emitting element including the pixel electrode, the EL layer, the common layer, and the common electrode can be formed.

Note that in a cross-sectional view, an end portion of the organic insulating layer preferably has a tapered shape with a taper angle of less than 90°. In that case, breakage of the common layer and the common electrode provided over the organic insulating layer can be prevented. Consequently, defective connection due to breakage can be inhibited. In addition, an increase in electric resistance, which is caused by local thinning of the common electrode due to a step, can be inhibited.

As described above, the island-shaped light-emitting layer formed by the method for manufacturing a display apparatus of one embodiment of the present invention is not formed by using a fine metal mask but by processing a light-emitting layer deposited over the entire surface. Accordingly, a high-resolution display apparatus or a display apparatus with a high aperture ratio, which has been difficult to achieve, can be manufactured. Moreover, light-emitting layers can be formed separately for the respective colors, enabling the display apparatus to perform extremely clear display with high contrast and high display quality. Furthermore, providing the mask layer over the light-emitting layer can reduce damage to the light-emitting layer in the manufacturing process of the display apparatus, thereby improving the reliability of the light-emitting element.

A formation method using a fine metal mask, for example, does not easily reduce the distance between adjacent light-emitting elements to less than 10 μm; by contrast, the method of one embodiment of the present invention employing photolithography can shorten the distance between adjacent light-emitting elements, the distance between adjacent EL layers, or the distance between adjacent pixel electrodes to less than 10 μm, 5 μm or less, 3 μm or less, 2 μm or less, 1.5 μm or less, 1 μm or less, or even 0.5 μm or less, for example, in a process over a glass substrate. Using a light exposure apparatus for LSI can further shorten the distance between adjacent light-emitting elements, the distance between adjacent EL layers, or the distance between adjacent pixel electrodes to 500 nm or less, 200 nm or less, 100 nm or less, or even 50 nm or less, for example, in a process over a Si wafer. Accordingly, the area of a non-light-emitting region that may exist between two light-emitting elements can be significantly reduced, and the aperture ratio can be close to 100%. For example, the aperture ratio of the display apparatus of one embodiment of the present invention is higher than or equal to 40%, higher than or equal to 50%, higher than or equal to 60%, higher than or equal to 70%, higher than or equal to 80%, or higher than or equal to 90%; that is, an aperture ratio lower than 100% can be achieved.

Increasing the aperture ratio of the display apparatus can improve the reliability of the display apparatus. Specifically, with reference to the lifetime of a display apparatus including an organic EL element and having an aperture ratio of 10%, a display apparatus having an aperture ratio of 20% (i.e., having an aperture ratio two times higher than the reference) has a lifetime approximately 3.25 times longer than the reference, and a display apparatus having an aperture ratio of 40% (i.e., having an aperture ratio four times higher than the reference) has a lifetime approximately 10.6 times longer than the reference. Thus, the density of current flowing to the organic EL element can be reduced with increasing aperture ratio, and accordingly the lifetime of the display apparatus can be increased. The display apparatus of one embodiment of the present invention can have a higher aperture ratio and thus can have higher display quality. Furthermore, the display apparatus of one embodiment of the present invention has excellent effect that the reliability (especially the lifetime) can be significantly improved with increasing aperture ratio.

A pattern of the light-emitting layer itself can be made much smaller than that in the case of using a fine metal mask. For example, in the case of using a metal mask for forming light-emitting layers separately, the thickness varies between the center and the edge of the pattern, causing a reduction in effective area that can be used for a light-emitting region with respect to the entire pattern area. By contrast, in the above manufacturing method, the film formed to have a uniform thickness is processed, so that island-shaped light-emitting layers can be formed to have a uniform thickness. Accordingly, even in a fine pattern, almost the entire area can be used as a light-emitting region. Thus, a display apparatus having both high resolution and a high aperture ratio can be manufactured. Furthermore, the display apparatus can be reduced in size and weight.

Specifically, for example, the display apparatus of one embodiment of the present invention can have a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi

### [Structure Example 1]

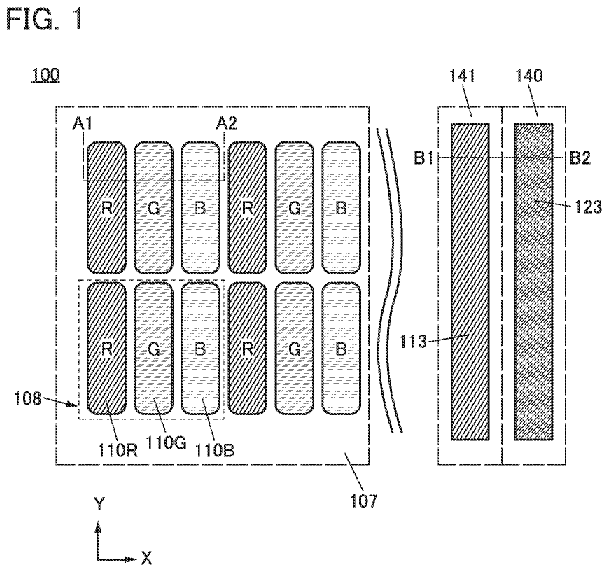

FIG. 1 is a plan view illustrating a structure example of a display apparatus 100. The display apparatus 100 includes a pixel portion 107 in which a plurality of pixels 108 are arranged in matrix. The pixel 108 includes a subpixel 110R, a subpixel 110G, and a subpixel 110B. FIG. 1 illustrates subpixels 110 arranged in two rows and six columns, which form pixels 108 in two rows and two columns. Note that a plan view can be rephrased as a top view in some cases.

In this specification and the like, for example, matters common to the subpixel 110R, the subpixel 110G, and the subpixel 110B are sometimes described using the collective term “subpixel 110”. As for other components that are distinguished from each other using letters of the alphabet, matters common to the components are sometimes described using reference numerals without the letters of the alphabet.

The subpixel 110R emits red light, the subpixel 110G emits green light, and the subpixel 110B emits blue light. Accordingly, an image can be displayed on the pixel portion 107. The pixel portion 107 can therefore be referred to as a display portion. Note that in this embodiment, subpixels of three colors of red (R), green (G), and blue (B) are given as examples; however, subpixels of three colors of yellow (Y), cyan (C), and magenta (M) may be used. The number of types of subpixels is not limited to three, and four or more types of subpixels may be used. Examples of four subpixels include subpixels of four colors of R, G, B, and white (W), subpixels of four colors of R, G, B, and Y, and four subpixels of R, G, B, and infrared light (IR).

It can also be said that stripe arrangement is employed for the pixels 108 illustrated in FIG. 1. Note that the arrangement method that can be employed for the pixels 108 is not limited thereto; another arrangement method such as stripe arrangement, S stripe arrangement, delta arrangement, Bayer arrangement, or zigzag arrangement may be used, or PenTile arrangement, diamond arrangement, or the like can be used.

In this specification and the like, the row direction and the column direction are sometimes referred to as the X direction and the Y direction, respectively. The X direction and the Y direction intersect with each other and are perpendicular to each other, for example. FIG. 1 illustrates an example where subpixels of different colors are arranged in the X direction and subpixels of the same color are arranged in the Y direction. Note that subpixels of different colors may be arranged in the Y direction, and subpixels of the same color may be arranged in the X direction.

A region 141 and a connection portion 140 are provided outside the pixel portion 107, and the region 141 is provided between the pixel portion 107 and the connection portion 140. An EL layer 113 is provided in the region 141. A conductive layer 123 is provided in the connection portion 140.

Although FIG. 1 illustrates an example where the region 141 and the connection portion 140 are positioned on the right side of the pixel portion 107 in the plan view, the position of the region 141 and the connection portion 140 is not particularly limited. The region 141 and the connection portion 140 are provided in at least one of the upper side, the right side, the left side, and the lower side of the pixel portion 107 in plan top view, and may be provided so as to surround the four sides of the pixel portion 107. The top surface shape of the region 141 and the connection portion 140 can be a belt-like shape, an L shape, a U shape, a frame-like shape, or the like. The number of regions 141 and the number of connection portions 140 can each be one or more. Note that a plan view can be rephrased as a top view in some cases.

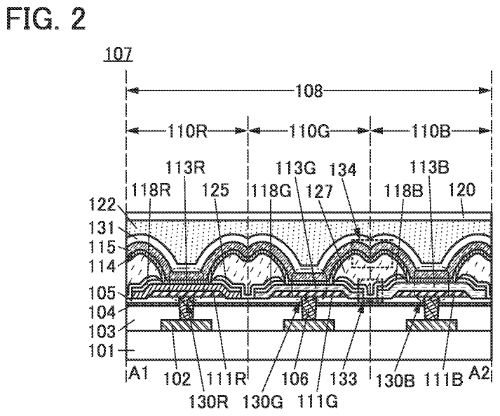

FIG. 2 is a cross-sectional view along the dashed-dotted line A1-A2 in FIG. 1 and illustrates a structure example of the pixel 108 provided in the pixel portion 107. As illustrated in FIG. 2, the display apparatus 100 includes an insulating layer 101, a conductive layer 102 over the insulating layer 101, an insulating layer 103 over the insulating layer 101 and the conductive layer 102, an insulating layer 104 over the insulating layer 103, and an insulating layer 105 over the insulating layer 104. The insulating layer 101 is provided over a substrate (not illustrated). An opening reaching the conductive layer 102 is provided in the insulating layer 105, the insulating layer 104, and the insulating layer 103, and a plug 106 is provided so as to fill the opening.

In the pixel portion 107, a light-emitting element 130 is provided over the insulating layer 105 and the plug 106. A protective layer 131 is provided to cover the light-emitting element 130. A substrate 120 is bonded to the protective layer 131 with a resin layer 122. An insulating layer 125 and an insulating layer 127 over the insulating layer 125 are provided between the adjacent light-emitting elements 130.

Although FIG. 2 illustrates cross sections of a plurality of the insulating layers 125 and a plurality of the insulating layers 127, the insulating layers 125 are connected to each other and the insulating layers 127 are connected to each other when the display apparatus 100 is seen from above. In other words, the display apparatus 100 can have a structure including one insulating layer 125 and one insulating layer 127, for example. Note that the display apparatus 100 may include a plurality of insulating layers 125 that are separated from each other and a plurality of insulating layers 127 that are separated from each other.

In FIG. 2, a light-emitting element 130R, a light-emitting element 130G, and a light-emitting element 130B are illustrated as the light-emitting element 130. The light-emitting element 130R, the light-emitting element 130G, and the light-emitting element 130B emit light of different colors. For example, the light-emitting element 130R can emit red light, the light-emitting element 130G can emit green light, and the light-emitting element 130B can emit blue light. Alternatively, the light-emitting element 130R, the light-emitting element 130G, or the light-emitting element 130B may emit cyan light, magenta light, yellow light, white light, infrared light, or the like.

The display apparatus of one embodiment of the present invention can have any of the following structures: a top-emission structure in which light is emitted in a direction opposite to a substrate where the light-emitting element 130 is formed, a bottom-emission structure in which light is emitted toward a substrate where the light-emitting element 130 is formed, and a dual-emission structure in which light is emitted toward both surfaces, for example.

As the light-emitting element 130, an organic light-emitting diode (OLED) or a quantum-dot light-emitting diode (QLED) is preferably used, for example. Examples of a light-emitting substance included in the light-emitting element 130 include a substance exhibiting fluorescence (a fluorescent material), a substance exhibiting phosphorescence (a phosphorescent material), an inorganic compound (e.g., a quantum dot material), and a substance exhibiting thermally activated delayed fluorescence (a thermally activated delayed fluorescent (TADF) material). Alternatively, an LED such as a micro-LED can be used as the light-emitting element 130.

The light-emitting element 130R includes a pixel electrode 111R over the plug 106 and the insulating layer 105, an EL layer 113R covering the top surface and the side surfaces of the pixel electrode 111R, a common layer 114 over the EL layer 113R, and a common electrode 115 over the common layer 114. Note that in the light-emitting element 130R, the EL layer 113R and the common layer 114 can be collectively referred to as an EL layer.

The light-emitting element 130G includes a pixel electrode 111G over the plug 106 and the insulating layer 105, an EL layer 113G covering the top surface and the side surfaces of the pixel electrode 111G, the common layer 114 over the EL layer 113G, and the common electrode 115 over the common layer 114. Note that in the light-emitting element 130G, the EL layer 113G and the common layer 114 can be collectively referred to as an EL layer.

The light-emitting element 130B includes a pixel electrode 111B over the plug 106 and the insulating layer 105, an EL layer 113B covering the top surface and the side surfaces of the pixel electrode 111B, the common layer 114 over the EL layer 113B, and the common electrode 115 over the common layer 114. Note that in the light-emitting element 130B, the EL layer 113B and the common layer 114 can be collectively referred to as an EL layer.

In the light-emitting element, one of the pixel electrode and the common electrode functions as an anode and the other functions as a cathode. Hereinafter, the pixel electrode may function as the anode and the common electrode may function as the cathode unless otherwise specified.

In the example illustrated in FIG. 2, a mask layer 118R is positioned over the EL layer 113R included in the light-emitting element 130R, a mask layer 118G is positioned over the EL layer 113G included in the light-emitting element 130G, and a mask layer 118B is positioned over the EL layer 113B included in the light-emitting element 130B. The mask layer 118R is a remaining part of a mask layer provided in contact with the top surface of the EL layer 113R at the time of processing the EL layer 113R. Similarly, the mask layer 118G is a remaining part of a mask layer provided at the time of forming the EL layer 113G, and the mask layer 118B is a remaining part of a mask layer provided at the time of forming the EL layer 113B. Thus, part of the mask layer used to protect the EL layer in manufacture of the display apparatus may remain in the display apparatus 100. Two or all of the mask layer 118R, the mask layer 118G, and the mask layer 118B may be formed using the same material or different materials. Note that hereinafter the mask layer 118R, the mask layer 118G, and the mask layer 118B may be collectively referred to as the mask layer 118.

In FIG. 2, one end portion of the mask layer 118R is aligned or substantially aligned with an end portion of the EL layer 113R, and the other end portion of the mask layer 118R is positioned over the EL layer 113R. Here, the other end portion of the mask layer 118R preferably overlaps with the pixel electrode 111R. In that case, the other end portion of the mask layer 118R is likely to be formed on a substantially flat surface of the EL layer 113R. Note that the same applies to the mask layer 118G and the mask layer 118B. The mask layer 118 remains between the top surface of the EL layer 113 processed into an island shape and the insulating layer 125, for example.

In the case where end portions are aligned or substantially aligned with each other and the case where top surface shapes are the same or substantially the same, it can be said that outlines of stacked layers at least partly overlap with each other in a plan view. For example, the case of processing or partly processing an upper layer and a lower layer with the use of the same mask pattern is included. Note that, in some cases, the outlines do not exactly coincide with each other and the upper layer is positioned on the inner side of the lower layer or the upper layer is positioned on the outer side of the lower layer; such a case is also expressed as “end portions are substantially aligned with each other” or “top surface shapes are substantially the same”.

The side surfaces of the EL layer 113R, the EL layer 113G, and the EL layer 113B are each covered with the insulating layer 125. The insulating layer 127 overlaps the side surfaces of the EL layer 113R, the EL layer 113G, and the EL layer 113B with the insulating layer 125 therebetween.

The top surface of the EL layer the EL layer 113R, the EL layer 113G, and the EL layer 113B are partly covered with the mask layer 118. The insulating layer 125 and the insulating layer 127 overlap with part of the top surface of each of the EL layer 113R, the EL layer 113G, and the EL layer 113B with the mask layer 118 therebetween.

The side surface and part of the top surface of each of the EL layer 113R, the EL layer 113G, and the EL layer 113B are covered with at least one of the insulating layer 125, the insulating layer 127, and the mask layer 118, whereby the common layer 114 or the common electrode 115 can be inhibited from being in contact with the side surfaces of the EL layer 113R, the EL layer 113G, and the EL layer 113B, leading to inhibition of a short circuit of the light-emitting element 130. Thus, the reliability of the light-emitting element 130 can be improved.

The insulating layer 125 is preferably in contact with the side surfaces of the EL layer 113R, the EL layer 113G, and the EL layer 113B. In that case, separation of the EL layer 113R, the EL layer 113G, and the EL layer 113B can be prevented. When the insulating layer 125 and the EL layers 113 are in close contact with each other, the EL layers 113 can be fixed or bonded to each other by the insulating layer 125. Thus, the reliability of the light-emitting elements 130 can be improved. Moreover, the manufacturing yield of the light-emitting elements can be increased.

As illustrated in FIG. 2, the insulating layer 125 and the insulating layer 127 cover the side surface and part of the top surface of each of the EL layer 113R, the EL layer 113G, and the EL layer 113B, whereby film separation of the EL layers 113 can be favorably prevented, resulting in increased reliability of the light-emitting elements 130. In addition, the manufacturing yield of the light-emitting elements 130 can be favorably increased.

FIG. 2 illustrates an example in which a stacked-layer structure of the EL layer 113R, the mask layer 118R, the insulating layer 125, and the insulating layer 127 is positioned over end portions of the pixel electrode 111R. Similarly, a stacked layer structure of the EL layer 113G, the mask layer 118G, the insulating layer 125, and the insulating layer 127 is positioned over end portions of the pixel electrode 111G, and a stacked layer structure of the EL layer 113B, the mask layer 118B, the insulating layer 125, and the insulating layer 127 is positioned over end portions of the pixel electrode 111B.

FIG. 2 illustrates a structure in which the end portions of the pixel electrode 111R are covered with the EL layer 113R and the insulating layer 125 is in contact with the side surfaces of the EL layer 113R. Similarly, the end portions of the pixel electrode 111G are covered with the EL layer 113G, the end portions of the pixel electrode 111B are covered with the EL layer 113B, and the insulating layer 125 is in contact with the side surfaces of the EL layer 113G and the side surfaces of the EL layer 113B.

The insulating layer 127 is provided over the insulating layer 125 to fill a depressed portion formed by the insulating layer 125. The insulating layer 127 can overlap with the side surface and part of the top surface of each of the EL layer 113R, the EL layer 113G, and the EL layer 113B with the insulating layer 125 therebetween. The insulating layer 127 preferably covers at least part of the side surface of the insulating layer 125.

Providing the insulating layer 125 and the insulating layer 127 can fill a gap between adjacent island-shaped layers, whereby extreme unevenness of a formation surface of a layer (e.g., the common layer 114 and the common electrode 115) to be provided over the EL layer 113 can be reduced and the formation surface can be made flatter. Consequently, the coverage with the common layer 114, the common electrode 115, and the like can be improved.

The top surface of the insulating layer 127 is provided with a depressed portion 134. For example, the depressed portion 134 of the insulating layer 127 can have a concave shape. The depressed portion 134 includes a region overlapping with a region 133 between two adjacent light-emitting elements 130. The region 133 can be a region positioned between two adjacent EL layers 113, for example. The insulating layer 127 can be provided in the region 133. It can be said that the insulating layer 127 includes the region 133.

The depressed portion 134 is preferably provided in the middle of the insulating layer 127 and the vicinity thereof in a cross-sectional view. For example, the shortest part in the depressed portion 134 in the cross-sectional view can be provided in a position that does not overlap with the EL layer 113. For example, the shortest part in the depressed portion 134 can be provided in the middle of the insulating layer 127 or the vicinity thereof in the cross-sectional view. Accordingly, stress of the insulating layer 127 applied to two adjacent EL layers 113 can be dispersed, for example. As a result, for example, one of the two adjacent EL layers 113 can be inhibited from being subjected to higher stress than the other EL layer 113. However, one embodiment of the present invention is not limited thereto; the shortest part in the depressed portion 134 in the cross-sectional view may overlap with the EL layer 113, for example. Even in that case, for example, a structure with which stress of the insulating layer 127 applied to two adjacent EL layers 113 can be dispersed is preferably employed in consideration of a difference in thickness between the two adjacent EL layers 113.

By providing the depressed portion 134 in the insulating layer 127, stress of the insulating layer 127 can be reduced as compared, for example, with the case where the depressed portion 134 is not provided in the insulating layer 127 and the tallest part in the depressed portion 134 in a cross-sectional view is positioned in the middle of the insulating layer 127. Specifically, by providing the depressed portion 134 in the insulating layer 127, compressive stress locally generated in an end portion of the insulating layer 127 can be reduced, so that one or more of film separation between the EL layer 113 and the mask layer 118, film separation between the mask layer 118 and the insulating layer 125, and film separation between the insulating layer 125 and the insulating layer 127 can be inhibited. As a result, the display apparatus 100 can be a highly reliable display apparatus. Moreover, the display apparatus 100 can be manufactured by a high-yield method.

Note that as described above, the insulating layer 127 is provided over the insulating layer 125 to fill the depressed portion formed by the insulating layer 125. The insulating layer 127 is provided between the island-shaped EL layers 113. In other words, the display apparatus 100 employs a process (hereinafter referred to as a process 1) in which the island-shaped EL layer 113 is formed and then the insulating layer 127 is formed to overlap with an end portion of the island-shaped EL layer 113. By contrast, as a process different from the process 1, there is a process (hereinafter referred to as a process 2) in which the pixel electrode 111 is formed in an island shape, an insulating layer (also referred to as a bank or a structure body) that covers an end portion of the top surface of the pixel electrode 111 is formed, and then the island-shaped EL layer 113 is formed over the pixel electrode 111 and the insulating layer.

The process 1 is preferable to the process 2 because of having a wider margin. Specifically, the process 1 has a wider margin with respect to alignment accuracy between different patterning steps than the process 2 and can provide a display apparatus with few variations. Since the method for manufacturing the display apparatus 100 is based on the process 1, a display apparatus with few variations and high display quality can be provided.

Each of the EL layer 113R, the EL layer 113G, and the EL layer 113B includes at least a light-emitting layer. For example, the EL layer 113R includes a light-emitting layer that emits red light, the EL layer 113G includes a light-emitting layer that emits green light, and a light-emitting layer that emits blue light. The EL layer 113R, the EL layer 113G, or the EL layer 113B may emit cyan light, magenta light, yellow light, white light, infrared light, or the like.

The EL layer 113R, the EL layer 113G, and the EL layer 113B are separated from each other. Providing the island-shaped EL layer 113 in each of the light-emitting elements 130 can suppress leakage current between the light-emitting elements 130 adjacent to each other. This can prevent crosstalk due to unintended light emission, so that a display apparatus with extremely high contrast can be obtained. Specifically, a display apparatus having high current efficiency at low luminance can be obtained.

The island-shaped EL layer 113 can be formed by forming an EL film and processing the EL film by photolithography, for example. For example, the EL layer 113R can be formed by forming and processing an EL film to be the EL layer 113R, the EL layer 113G can be formed by forming and processing an EL film to be the EL layer 113G, and the EL layer 113B can be formed by forming and processing an EL film to be the EL layer 113B.

The EL layer 113 is provided to cover the top surface and the side surface of the pixel electrode 111. In this case, the aperture ratio of the display apparatus 100 can be easily increased as compared with the structure where an end portion of the EL layer 113 is positioned inward from an end portion of the pixel electrode 111. Covering the side surface of the pixel electrode 111 with the EL layer 113 can inhibit contact between the pixel electrode 111 and the common electrode 115, thereby inhibiting a short circuit of the light-emitting element 130. Furthermore, the distance between the light-emitting region (i.e., the region overlapping with the pixel electrode 111) in the EL layer 113 and the end portion of the EL layer 113 can be increased. Since the end portion of the EL layer 113 might be damaged by processing, using a region that is away from the end portion of the EL layer 113 as the light-emitting region may improve the reliability of the light-emitting element 130.

The thicknesses of the EL layer 113R, the EL layer 113G, and the EL layer 113B can be different from each other. For example, the thicknesses of the EL layer 113R, the EL layer 113G, and the EL layer 113B are preferably set to match an optical path length that intensifies light emitted from each EL layer. Thus, a microcavity structure is achieved, and the color purity of light emitted from the subpixels 110 can be improved.

The end portions of the pixel electrode 111R, the pixel electrode 111G, and the pixel electrode 111B each preferably have a tapered shape. Specifically, the end portions of the pixel electrode 111R, the pixel electrode 111G, and the pixel electrode 111B each preferably have a tapered shape with a taper angle of less than 90°. In the case where the end portions of the pixel electrodes have a tapered shape, the EL layer 113R, the EL layer 113G, and the EL layer 113B provided along the side surfaces of the pixel electrodes have an inclined surface. When the side surface of the pixel electrode has a tapered shape, coverage with the EL layer provided along the side surface of the pixel electrode can be improved.

In FIG. 2, an insulating layer that covers an end portion of the top surface of the pixel electrode 111R is not provided between the pixel electrode 111R and the EL layer 113R. An insulating layer that covers an end portion of the top surface of the pixel electrode 111G is not provided between the pixel electrode 111G and the EL layer 113G. An insulating layer that covers an end portion of the top surface of the pixel electrode 111B is not provided between the pixel electrode 111B and the EL layer 113B. Thus, the distance between the adjacent light-emitting elements 130 can be extremely small. Accordingly, the display apparatus can have high resolution or high definition. In addition, a mask for forming the insulating layer is not needed, which leads to a reduction in manufacturing cost of the display apparatus.

Furthermore, light emitted from the EL layer 113 can be extracted efficiently with a structure where an insulating layer that covers the end portion of the pixel electrodes 111 is not provided between the pixel electrode 111 and the EL layer 113, i.e., a structure where an insulating layer is not provided between the pixel electrode 111 and the EL layer 113. Therefore, the viewing angle dependence of the display apparatus 100 can be extremely small. A small viewing angle dependence leads to an increase in visibility of images on the display apparatus 100. For example, in the display apparatus 100, the viewing angle (the maximum angle at which a given constant ratio is maintained when the screen is seen in an oblique direction) can be greater than or equal to 100° and less than 180°, preferably greater than or equal to 150° and less than or equal to 170°. Note that the viewing angle refers to that in both the vertical direction and the horizontal direction.

The insulating layer 101, the insulating layer 103, and the insulating layer 105 function as interlayer insulating layers. As the insulating layer 101, the insulating layer 103, and the insulating layer 105, a variety of inorganic insulating films such as an oxide insulating film, a nitride insulating film, an oxynitride insulating film, and a nitride oxide insulating film can be suitably used; specifically, a silicon oxide film, a silicon oxynitride film, an aluminum oxide film, a silicon nitride film, or a silicon nitride oxide film can be used, for example.

Note that in this specification and the like, oxynitride refers to a material that contains more oxygen than nitrogen, and nitride oxide refers to a material that contains more nitrogen than oxygen. For example, silicon oxynitride refers to a material in which an oxygen content is higher than a nitrogen content, and silicon nitride oxide refers to a material in which a nitrogen content is higher than an oxygen content.

The insulating layer 104 functions as a barrier layer that inhibits entry of impurities such as water into the light-emitting element 130, for example. As the insulating layer 104, it is possible to use, for example, a film in which hydrogen or oxygen is less likely to be diffused than in a silicon oxide film, such as a silicon nitride film, an aluminum oxide film, or a hafnium oxide film.

The thickness of the insulating layer 105 in a region not overlapping with the pixel electrode 111 is sometimes smaller than that of the insulating layer 105 in a region overlapping with the pixel electrode 111. That is, the insulating layer 105 may have a depressed portion in the region not overlapping with the pixel electrode 111. The depressed portion is formed because of a formation step of the pixel electrode 111, for example.

The conductive layer 102 functions as a wiring. The conductive layer 102 is electrically connected to the light-emitting element 130 through the plug 106.

For the conductive layer 102 and the plug 106, it is possible to use a variety of conductive materials, for example, a metal such as aluminum (Al), titanium (Ti), chromium (Cr), nickel (Ni), copper (Cu), yttrium (Y), zirconium (Zr), tin (Sn), zinc (Zn), silver (Ag), platinum (Pt), gold (Au), molybdenum (Mo), tantalum (Ta), or tungsten (W) or an alloy containing the metal as its main component (e.g., an alloy of silver, palladium (Pd), and copper (Ag—Pd—Cu (APC))). For the conductive layer 102 and the plug 106, an oxide such as tin oxide or zinc oxide may be used.

The light-emitting element 130 may employ a single structure (a structure including only one light-emitting unit) or a tandem structure (a structure including a plurality of light-emitting units). The light-emitting unit includes at least one light-emitting layer.

As described above, each of the EL layer 113R, the EL layer 113G, and the EL layer 113B includes at least a light-emitting layer. For example, the EL layer 113R can include a light-emitting layer that emits red light, the EL layer 113G can include a light-emitting layer that emits green light, and the EL layer 113B can include a light-emitting layer that emits blue light.

In the case of using a tandem light-emitting element, for example, the EL layer 113R can include a plurality of light-emitting units that emit red light, the EL layer 113G can include a plurality of light-emitting units that emit green light, and the EL layer 113B can include a plurality of light-emitting units that emit blue light. A charge-generation layer is preferably provided between the light-emitting units.

Each of the EL layer 113R, the EL layer 113G, and the EL layer 113B may include one or more of a hole-injection layer, a hole-transport layer, a hole-blocking layer, a charge-generation layer, an electron-blocking layer, an electron-transport layer, and an electron-injection layer.

In this specification and the like, a layer other than the light-emitting layer among the layers included in the EL layer is referred to as a functional layer. The functional layer can include, for example, one or more of the above-described hole-injection layer, hole-transport layer, hole-blocking layer, charge-generation layer, electron-blocking layer, electron-transport layer, and electron-injection layer.

For example, in the case where the pixel electrode of the light-emitting element 130 functions as an anode and the common electrode 115 functions as a cathode, the EL layer 113R, the EL layer 113G, and the EL layer 113B may include a hole-injection layer, a hole-transport layer, a light-emitting layer, and an electron-transport layer in this order. In other words, for example, the EL layer 113 can have a structure in which a first functional layer including a hole-injection layer and a hole-transport layer, a light-emitting layer, and a second functional layer including an electron-transport layer are stacked in this order from the bottom. In addition, an electron-blocking layer may be provided between the hole-transport layer and the light-emitting layer. Moreover, a hole-blocking layer may be provided between the electron-transport layer and the light-emitting layer. The first functional layer may include one of the hole-injection layer and the hole-transport layer and does not necessarily include the other. The second functional layer may include an electron-injection layer and does not necessarily include the electron-transport layer.

For example, in the case where the pixel electrode of the light-emitting element 130 functions as a cathode and the common electrode 115 functions as an anode, the EL layer 113R, the EL layer 113G, and the EL layer 113B may include an electron-injection layer, an electron-transport layer, a light-emitting layer, and a hole-transport layer in this order. In other words, for example, the EL layer 113 can have a structure in which a first functional layer including an electron-injection layer and an electron-transport layer, a light-emitting layer, and a second functional layer including a hole-transport layer are stacked in this order from the bottom. In addition, a hole-blocking layer may be provided between the electron-transport layer and the light-emitting layer. Moreover, an electron-blocking layer may be provided between the hole-transport layer and the light-emitting layer. Furthermore, a hole-injection layer may be provided over the hole-transport layer. The first functional layer may include one of the electron-injection layer and the electron-transport layer and does not necessarily include the other. The second functional layer may include a hole-injection layer and does not necessarily include the hole-transport layer.

As described above, the EL layer 113R, the EL layer 113G, and the EL layer 113B preferably include a light-emitting layer and a carrier-transport layer (an electron-transport layer or a hole-transport layer) over the light-emitting layer. Alternatively, the EL layer 113R, the EL layer 113G, and the EL layer 113B preferably include a light-emitting layer and a carrier-blocking layer (a hole-blocking layer or an electron-blocking layer) over the light-emitting layer. Alternatively, the EL layer 113R, the EL layer 113G, and the EL layer 113B preferably include a light-emitting layer, a carrier-blocking layer over the light-emitting layer, and a carrier-transport layer over the carrier-blocking layer. Surfaces of the EL layer 113R, the EL layer 113G, and the EL layer 113B are exposed in the manufacturing process of the display apparatus; providing one or both of the carrier-transport layer and the carrier-blocking layer over the light-emitting layer prevents the light-emitting layer from being exposed on the outermost surface, so that damage to the light-emitting layer can be reduced. As a result, the reliability of the light-emitting element can be improved.

The upper temperature limit of compounds contained in the EL layer 113R, the EL layer 113G, and the EL layer 113B is preferably higher than or equal to 100° C. and lower than or equal to 180° C., further preferably higher than or equal to 120° C. and lower than or equal to 180° C., still further preferably higher than or equal to 140° C. and lower than or equal to 180° C. For example, the glass transition point (Tg) of these compounds is preferably higher than or equal to 100° C. and lower than or equal to 180° C., further preferably higher than or equal to 120° C. and lower than or equal to 180° C., still further preferably higher than or equal to 140° C. and lower than or equal to 180° C.

In particular, the upper temperature limit of the functional layer provided over the light-emitting layer is preferably high. It is further preferable that the upper temperature limit of the functional layer provided on and in contact with the light-emitting layer be high. When the functional layer has high heat resistance, the light-emitting layer can be effectively protected and less damaged.

The functional layer provided over the light-emitting layer preferably contains an organic compound including a bicarbazole skeleton and a heteroaromatic ring skeleton having one selected from a pyridine ring, a diazine ring, and a triazine ring or an organic compound which includes a bicarbazole skeleton and a condensed heteroaromatic ring skeleton having a pyridine ring or a diazine ring and whose Tg is higher than or equal to 100° C. and lower than or equal to 180° C., preferably higher than or equal to 120° C. and lower than or equal to 180° C., further preferably higher than or equal to 140° C. and lower than or equal to 180° C. A functional layer containing such an organic compound can function as one or both of a hole-blocking layer and an electron-transport layer. Note that the functional layer containing such an organic compound may be provided below the light-emitting layer (the lower electrode side) without limitation to the position above the light-emitting layer (the upper electrode side).

Specific examples of such an organic compound include 2-{3-[3-(9-phenyl-9H-carbazol-3-yl)-9H-carbazol-9-yl]phenyl}dibenzo[f,h]quinoxaline (abbreviation: 2mPCCzPDBq), 2-{3-[2-(9-phenyl-9H-carbazol-3-yl)-9H-carbazol-9-yl]phenyl}dibenzo[f,h]quinoxaline (abbreviation: 2mPCCzPDBq-02), 9-[3-(4,6-diphenyl-1,3,5-triazin-2-yl)phenyl]-9′-phenyl-3,3′-bi-9H-carbazole (abbreviation: mPCCzPTzn), 9-[3-(4,6-diphenyl-1,3,5-triazin-2-yl)phenyl]-9′-phenyl-2,3′-bi-9H-carbazole (abbreviation: mPCCzPTzn-02), 9-[4-(4,6-diphenyl-1,3,5-triazin-2-yl)phenyl]-9′-phenyl-3,3′-bi-9H-carbazole (abbreviation: PCCzPTzn), 9-(4,6-diphenyl-1,3,5-triazin-2-yl)-9′-phenyl-3,3′-bi-9H-carbazole (abbreviation: PCCzTzn), 9-[3-(4,6-diphenyl-pyrimidin-2-yl)phenyl]-9′-phenyl-3,3′-bi-9H-carbazole (abbreviation: 2PCCzPPm), 9-(4,6-diphenyl-pyrimidin-2-yl)-9′-phenyl-2,3′-bi-9H-carbazole (abbreviation: 2PCCzPm), 9-(4,6-diphenylpyrimidin-2-yl)-9′-phenyl-3,3′-bi-9H-carbazole (abbreviation: 2PCCZPm-02), 4-(9′-phenyl[2,3′-bi-9H-carbazol]-9-yl)benzofuro[3,2-d]pyrimidine (abbreviation: 4PCCzBfpm-02), and 4-{3-[3-(9-phenyl-9H-carbazol-3-yl)-9H-carbazol-9-yl]phenyl}benzo[h]quinazoline.

The upper temperature limit of the light-emitting layer is preferably high. In that case, the light-emitting layer can be inhibited from being damaged by heating and being decreased in emission efficiency and lifetime.

The EL layer 113R, the EL layer 113G, and the EL layer 113B can include, for example, a first light-emitting unit, a charge-generation layer, and a second light-emitting unit.

The second light-emitting unit preferably includes a light-emitting layer and a carrier-transport layer (an electron-transport layer or a hole-transport layer) over the light-emitting layer. Alternatively, the second light-emitting unit preferably includes a light-emitting layer and a carrier-blocking layer (a hole-blocking layer or an electron-blocking layer) over the light-emitting layer. Alternatively, the second light-emitting unit preferably includes a light-emitting layer, a carrier-blocking layer over the light-emitting layer, and a carrier-transport layer over the carrier-blocking layer. A surface of the second light-emitting unit is exposed in the manufacturing process of the display apparatus; providing one or both of the carrier-transport layer and the carrier-blocking layer over the light-emitting layer inhibits the light-emitting layer from being exposed on the outermost surface, so that damage to the light-emitting layer can be reduced. As a result, the reliability of the light-emitting element can be improved. Note that in the case where three or more light-emitting units are provided, the uppermost light-emitting unit preferably includes a light-emitting layer and one or both of a carrier-transport layer and a carrier-blocking layer over the light-emitting layer.

In the case where the pixel electrode 111 functions as an anode and the common electrode 115 functions as a cathode, the common layer 114 includes at least one of an electron-injection layer and an electron-transport layer and, for example, includes an electron-injection layer. Alternatively, the common layer 114 may include a stack of an electron-transport layer and an electron-injection layer. Meanwhile, in the case where the pixel electrode 111 functions as a cathode and the common electrode 115 functions as an anode, the common layer 114 includes at least one of a hole-injection layer and a hole-transport layer and, for example, includes a hole-injection layer. Alternatively, the common layer 114 may include a stack of a hole-transport layer and a hole-injection layer. The common layer 114 is shared by the light-emitting element 130R, the light-emitting element 130G, and the light-emitting element 130B.

Like the common layer 114, the common electrode 115 is shared by the light-emitting element 130R, the light-emitting element 130G, and the light-emitting element 130B.

The common layer 114 and the common electrode 115 are provided over the EL layer 113R, the EL layer 113G, the EL layer 113B, the mask layer 118, the insulating layer 125, and the insulating layer 127. At the stage before the insulating layer 125 and the insulating layer 127 are provided, a step due to a region where the pixel electrode 111 and the EL layer 113 are provided and a region where the pixel electrode 111 and the EL layer 113 are not provided (a region between the light-emitting elements 130) is generated. By providing the insulating layer 125 and the insulating layer 127 in the display apparatus 100, the step can be eliminated and the coverage with the common layer 114 and the common electrode 115 can be improved. Consequently, defective connection due to breakage can be inhibited. In addition, an increase in electric resistance, which is caused by local thinning of the common electrode 115 due to the step, can be inhibited.

Next, examples of materials for the insulating layer 125 and the insulating layer 127 are described.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. Aluminum oxide is particularly preferable because it has high etching selectivity with the EL layer and has a function of protecting the EL layer during formation of the insulating layer 127 described later. In particular, when an inorganic insulating film such as an aluminum oxide film, a hafnium oxide film, or a silicon oxide film formed by an atomic layer deposition (ALD) method is used as the insulating layer 125, the insulating layer 125 can have few pin holes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like means a function of inhibiting diffusion of a particular substance (also referred to as a function of less easily transmitting the substance). Alternatively, a barrier property means a function of capturing or fixing (also referred to as gettering) a particular substance.

When the insulating layer 125 has a function of the barrier insulating layer or a gettering function, entry of impurities (typically, at least one of water and oxygen) that would diffuse into the light-emitting element 130 from the outside can be suppressed. With this structure, a highly reliable light-emitting element and a highly reliable display apparatus can be provided.

The insulating layer 125 preferably has a low impurity concentration. In this case, deterioration of the EL layer 113 due to entry of impurities from the insulating layer 125 into the EL layer 113 can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

Note that the insulating layer 125 can be formed using the same material as the mask layer 118R, the mask layer 118G, and the mask layer 118B. In this case, the boundary between the insulating layer 125 and any of the mask layer 118R, the mask layer 118G, and the mask layer 118B may be unclear so that they cannot be distinguished from each other. Thus, the insulating layer 125 and any of the mask layer 118R, the mask layer 118G, and the mask layer 118B are observed as one layer in some cases. In other words, it sometimes appears that one layer is provided in contact with the side surfaces and part of the top surfaces of the EL layer 113R, the EL layer 113G and the EL layer 113B and that the insulating layer 127 covers at least part of the side surface of the one layer.

The insulating layer 127 provided over the insulating layer 125 has a function of filling extreme unevenness of the insulating layer 125, which is formed between the light-emitting elements 130 adjacent to each other. In other words, the insulating layer 127 has an effect of improving the planarity of the formation surface of the common electrode 115.

As the insulating layer 127, an insulating layer containing an organic material can be suitably used. As the organic material, a photosensitive material such as a photosensitive organic resin is preferably used, and for example, a photosensitive resin composition containing an acrylic resin is preferably used. Note that in this specification and the like, an acrylic resin refers to not only a polymethacrylic acid ester or a methacrylic resin, but also all the acrylic polymer in a broad sense in some cases.

Alternatively, the insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. The insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive resin. As the photosensitive organic resin, a positive-type material can be used.

The insulating layer 127 may be formed using a material absorbing visible light. When the insulating layer 127 absorbs light emitted from the light-emitting element 130, light leakage (stray light) from the light-emitting element 130 to the adjacent light-emitting element 130 through the insulating layer 127 can be suppressed. Thus, the display quality of the display apparatus can be improved. Since the display quality of the display apparatus can be improved without using a polarizing plate, the weight and thickness of the display apparatus can be reduced.

Examples of the material absorbing visible light include materials containing pigment of black or the like, materials containing dye, light-absorbing resin materials (e.g., polyimide), and resin materials that can be used for color filters (color filter materials). A resin material obtained by stacking or mixing color filter materials of two or three or more colors is particularly preferably used, in which case the effect of blocking visible light can be enhanced. In particular, mixing color filter materials of three or more colors enables the formation of a black or nearly black resin layer.

The volume shrinkage rate of the material used for the insulating layer 127 is preferably low. In that case, the insulating layer 127 can be easily formed to have a desired shape. Moreover, the volume shrinkage rate of the insulating layer 127 after curing is preferably low. In that case, the shape of the insulating layer 127 can be easily maintained in various steps after the formation of the insulating layer 127. Specifically, the volume shrinkage rate of the insulating layer 127 after thermal curing is preferably lower than or equal to 10%, further preferably lower than or equal to 5%, still further preferably lower than or equal to 1%. Here, the volume shrinkage rate can be one of the rate of volume shrinkage by light irradiation and the rate of volume shrinkage by heating, or the sum of these rates.

By providing the protective layer 131 over the light-emitting element 130, the reliability of the light-emitting element 130 can be improved. The protective layer 131 may have a single-layer structure or a stacked-layer structure of two or more layers.

There is no limitation on the conductivity of the protective layer 131. As the protective layer 131, at least one type of an insulating film, a semiconductor film, and a conductive film can be used.

As the protective layer 131, an inorganic insulating film such as an oxide insulating film, a nitride insulating film, an oxynitride insulating film, or a nitride oxide insulating film can be used, for example. Specific examples of these inorganic insulating films are as listed in the description of the insulating layer 125. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display apparatus can be improved.

When light emitted from the light-emitting element 130 is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can be, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer 113 side.

Furthermore, the protective layer 131 may include an organic film. For example, the protective layer 131 may include both an organic film and an inorganic film. Examples of an organic material that can be used for the protective layer 131 include organic insulating materials that can be used for the insulating layer 127.

The protective layer 131 may have a stacked-layer structure of two layers formed by different formation methods. Specifically, the first layer of the protective layer 131 may be formed by an ALD method, and the second layer of the protective layer 131 may be formed by a sputtering method.

A light-blocking layer may be provided on the surface of the substrate 120 on the resin layer 122 side. Moreover, a variety of optical members can be provided on the outer side of the substrate 120. Examples of the optical members include a polarizing plate, a retardation plate, a light diffusion layer (e.g., a diffusion film), an anti-reflective layer, and a light-condensing film. Furthermore, an antistatic film preventing the attachment of dust, a water repellent film suppressing the attachment of stain, a hard coat film suppressing generation of a scratch caused by the use, an impact-absorbing layer, or the like may be provided as a surface protective layer on the outer side of the substrate 120. For example, a glass layer or a silica layer (SiOx layer) is preferably provided as the surface protective layer, in which case surface contamination and damage can be prevented from being generated. The surface protective layer may be formed using DLC (diamond like carbon), aluminum oxide (AlOx), a polyester-based material, a polycarbonate-based material, or the like. For the surface protective layer, a material having a high visible light transmittance is preferably used. The surface protective layer is preferably formed using a material with high hardness.

For the substrate 120, glass, quartz, ceramics, sapphire, a resin, a metal, an alloy, a semiconductor, or the like can be used. The substrate on the side where light from the light-emitting element is extracted is formed using a material that transmits the light. When a flexible material is used for the substrate 120, the flexibility of the display apparatus can be increased. Furthermore, a polarizing plate may be used as the substrate 120.

For the substrate 120, polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, or the like can be used. Glass that is thin enough to have flexibility may be used as the substrate 120.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic film.

When a film used as the substrate absorbs water, the shape of the display apparatus might be changed, e.g., creases might be caused. Thus, as the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the resin layer 122, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet may be used, for example.

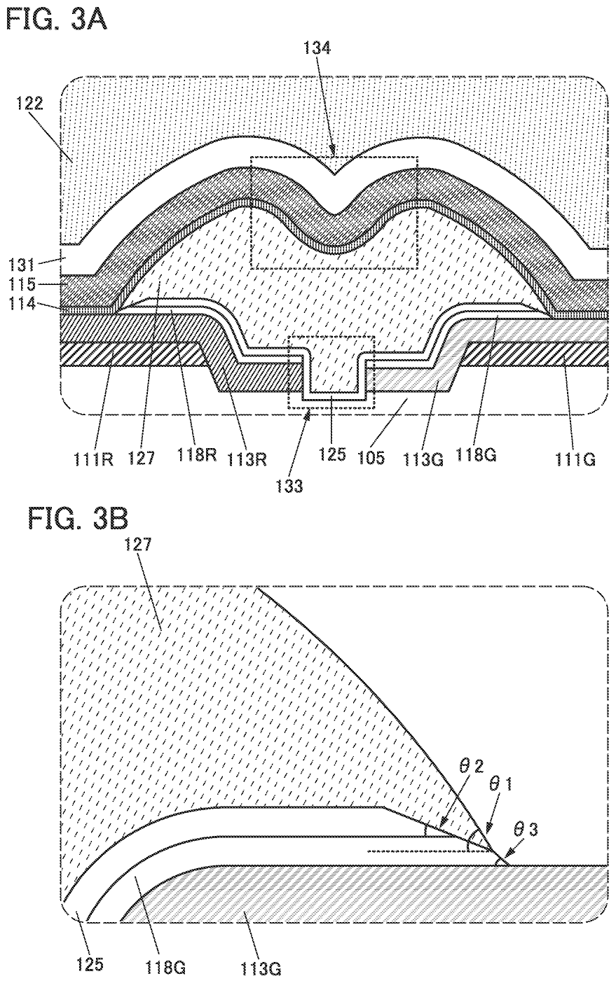

Next, a structure of the insulating layer 127 and the vicinity thereof is described with reference to FIG. 3A and FIG. 3B. FIG. 3A is a cross-sectional enlarged view of the insulating layer 127 between the EL layer 113R and the EL layer 113G and a peripheral region thereof. The description is made below using the insulating layer 127 between the EL layer 113R and the EL layer 113G as an example; the same applies to the insulating layer 127 between the EL layer 113G and the EL layer 113B and the insulating layer 127 between the EL layer 113B and the EL layer 113R. FIG. 3B is an enlarged view of an end portion of the insulating layer 127 over the EL layer 113G illustrated in FIG. 3A and the vicinity thereof. The description is made below using the end portion of the insulating layer 127 over the EL layer 113G as an example in some cases; the same applies to an end portion of the insulating layer 127 over the EL layer 113R and an end portion of the insulating layer 127 over the EL layer 113B.

As illustrated in FIG. 3A, the EL layer 113R is provided to cover the pixel electrode 111R and the EL layer 113G is provided to cover the pixel electrode 111G. The mask layer 118R is provided in contact with part of the top surface of the EL layer 113R, and the mask layer 118G is provided in contact with part of the top surface of the EL layer 113G.

The insulating layer 125 is provided in contact with the top and side surfaces of the mask layer 118R, the top and side surfaces of the mask layer 118G, the side surface of the EL layer 113R, the side surface of the EL layer 113G, and the top surface of the insulating layer 105. The insulating layer 127 is provided in contact with the top surface of the insulating layer 125. The insulating layer 127 overlaps with the side surface and part of the top surface of the EL layer 113R and the side surface and part of the top surface of the EL layer 113G with the insulating layer 125 therebetween, and is in contact with at least part of the side surface of the insulating layer 125. The insulating layer 127 includes the depressed portion 134. The depressed portion 134 includes a region overlapping with the region 133 between two adjacent EL layers 113 (between the EL layer 113R and the EL layer 113G in FIG. 3A), for example.

As described above, by providing the insulating layer 125 and the insulating layer 127 in the display apparatus 100, a step between the EL layer 113R and the EL layer 113G can be eliminated and the coverage with the common layer 114 and the common electrode 115 can be improved. Thus, defective connection due to breakage can be inhibited, and an increase in electric resistance, which is caused by local thinning of the common electrode 115 due to the step, can be inhibited. In addition, by providing the depressed portion 134 in the insulating layer 127, stress locally generated in an end portion of the insulating layer 127 can be reduced, so that one or more of film separation between the EL layer 113 and the mask layer 118, film separation between the mask layer 118 and the insulating layer 125, and film separation between the insulating layer 125 and the insulating layer 127 can be inhibited. As a result, the display apparatus 100 can be a highly reliable display apparatus. Moreover, the display apparatus 100 can be manufactured by a high-yield method.

The common layer 114 is provided to cover the EL layer 113R, the mask layer 118R, the EL layer 113G, the mask layer 118G, the insulating layer 125, and the insulating layer 127, and the common electrode 115 is provided over the common layer 114.

As illustrated in FIG. 3A, the thickness of the insulating layer 105 in a region not overlapping with the EL layer 113 may be smaller than that of the insulating layer 105 in a region overlapping with the EL layer 113. In other words, the insulating layer 105 may have a depression portion in the region not overlapping with the EL layer 113. The depression portion is formed because of the step of forming the EL layer 113, for example.

As illustrated in FIG. 3B, the end portion of the insulating layer 127 preferably has a tapered shape with a taper angle θ1 in the cross-sectional view of the display apparatus 100. The taper angle θ1 is an angle formed by the side surface of the insulating layer 127 and the substrate surface. Note that the taper angle θ1 is not limited to the angle and may be an angle formed by the side surface of the insulating layer 127 and the top surface of a flat portion of the EL layer 113G or the top surface of a flat portion of the pixel electrode 111G.

The taper angle θ1 of the insulating layer 127 is less than 90°, preferably less than or equal to 60°, further preferably less than or equal to 45°, still further preferably less than or equal to 20°. When the end portion of the insulating layer 127 has such a forward tapered shape, the common layer 114 and the common electrode 115 that are provided over the insulating layer 127 can be formed to provide favorable coverage, thereby inhibiting generation of breakage, local thinning, or the like. Consequently, the in-plane uniformity of the common layer 114 and the common electrode 115 can be increased, so that the display quality of the display apparatus can be improved.

As illustrated in FIG. 3B, the end portion of the insulating layer 127 is preferably positioned on the outer side of the end portion of the insulating layer 125. In that case, unevenness of the surface where the common layer 114 and the common electrode 115 are formed can be reduced and coverage with the common layer 114 and the common electrode 115 can be improved.

As illustrated in FIG. 3B, the end portion of the insulating layer 125 preferably has a tapered shape with a taper angle θ2 in the cross-sectional view of the display apparatus 100. The taper angle θ2 is an angle formed by the side surface of the insulating layer 125 and the substrate surface. Note that the taper angle θ2 is not limited to the angle and may be an angle formed by the side surface of the insulating layer 125 and the top surface of a flat portion of the EL layer 113G or the top surface of a flat portion of the pixel electrode 111G.

The taper angle θ2 of the insulating layer 125 is less than 90°, preferably less than or equal to 60°, further preferably less than or equal to 45°, still further preferably less than or equal to 20°.

As illustrated in FIG. 3B, the end portion of the mask layer 118G preferably has a tapered shape with a taper angle θ3 in the cross-sectional view of the display apparatus 100. The taper angle θ3 is an angle formed by the side surface of the mask layer 118G and the substrate surface. Note that the taper angle θ3 is not limited to the angle and may be an angle formed by the side surface of the mask layer 118G and the top surface of a flat portion of the EL layer 113G or the top surface of a flat portion of the pixel electrode 111G.

The taper angle θ3 of the mask layer 118G is less than 90°, preferably less than or equal to 60°, further preferably less than or equal to 45°, still further preferably less than or equal to 20°. When the end portion of the mask layer 118G has such a forward tapered shape, the common layer 114 and the common electrode 115 that are provided over the mask layer 118G can be formed to provide favorable coverage.

The end portion of the mask layer 118R and the end portion of the mask layer 118G are preferably positioned on the outer side of the end portion of the insulating layer 125. In that case, unevenness of the surface where the common layer 114 and the common electrode 115 are formed can be reduced and coverage with the common layer 114 and the common electrode 115 can be improved.

Although the details will be described later, when the insulating layer 125 and the mask layer 118 are etched at once, the insulating layer 125 and the mask layer under the end portion of the insulating layer 127 may disappear because of side etching and a void may be formed. The void causes unevenness on the formation surface of the common layer 114 and the common electrode 115; hence, breakage is more likely to be caused in the common layer 114 and the common electrode 115. Accordingly, when etching treatment is divided into two steps and heat treatment is performed between the two etching steps, even if a void is formed by the first etching treatment, the shape of the insulating layer 127 can be changed by the heat treatment to fill the void. Since the second etching treatment etches a thin film, the amount of side etching is small; thus, a void is less likely to be formed or can be extremely small even when formed. Thus, unevenness can be inhibited from being formed on the formation surface of the common layer 114 and the common electrode 115, and breakage of the common layer 114 and the common electrode 115 can be inhibited. Since the etching treatment is performed twice in this manner, the taper angle θ2 and the taper angle θ3 are different from each other in some cases. The taper angle θ2 and the taper angle θ3 may be the same. Furthermore, the taper angle θ2 and the taper angle θ3 may each be smaller than the taper angle θ1.

The insulating layer 127 may cover at least part of the side surface of the mask layer 118R and at least part of the side surface of the mask layer 118G. For example, FIG. 3B illustrates an example where the insulating layer 127 touches and covers an inclined surface that is formed by the first etching treatment and positioned at the end portion of the mask layer 118G and where an inclined surface that is formed by the second etching treatment and positioned at the end portion of the mask layer 118G is exposed. These two inclined surfaces can sometimes be distinguished from each other because of different taper angles. In some cases, they cannot be distinguished from each other because the taper angles on the side surface formed by the two etching treatments are almost the same.

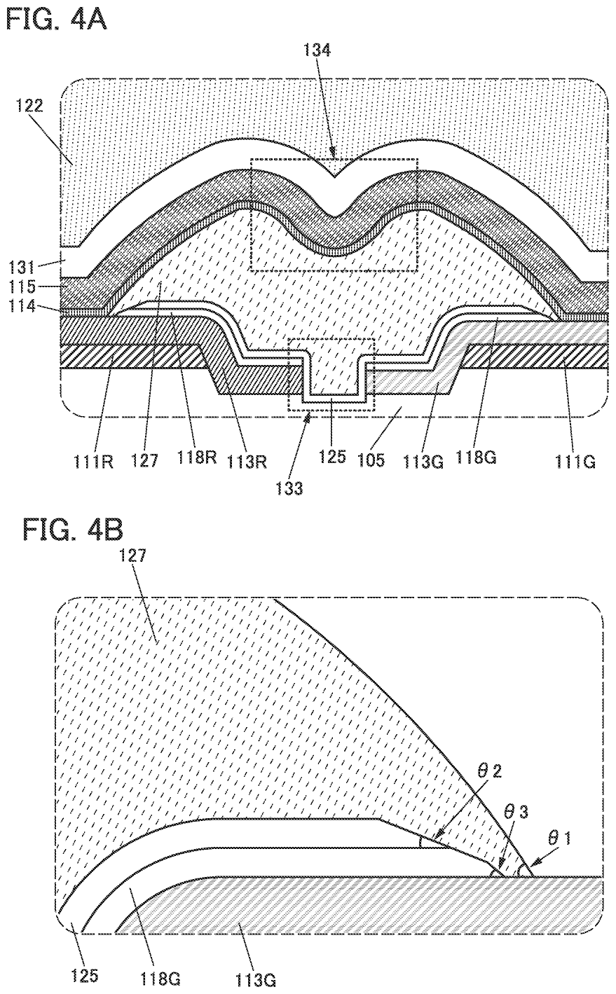

FIG. 4A and FIG. 4B illustrate a variation example of the structure illustrated in FIG. 3A and FIG. 3B and illustrate an example where the insulating layer 127 covers the entire side surface of the mask layer 118R and the entire side surface of the mask layer 118G. Specifically, in FIG. 4B, the insulating layer 127 touches and covers both of the two inclined surfaces. This is preferable because unevenness of the formation surface of the common layer 114 and the common electrode 115 can be further reduced. FIG. 4B illustrates an example where the end portion of the insulating layer 127 is positioned on the outer side of the end portion of the mask layer 118G. As illustrated in FIG. 4B, the end portion of the insulating layer 127 may be positioned on the outer side of the end portion of the mask layer 118G, or may be aligned or substantially aligned with the end portion of the mask layer 118G. As illustrated in FIG. 4B, the insulating layer 127 is in contact with the EL layer 113G in some cases.

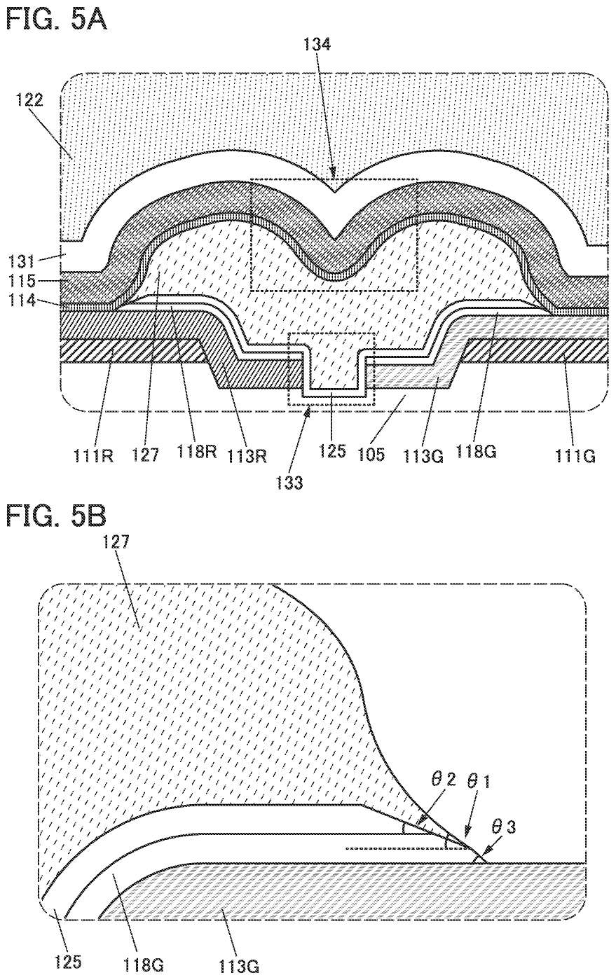

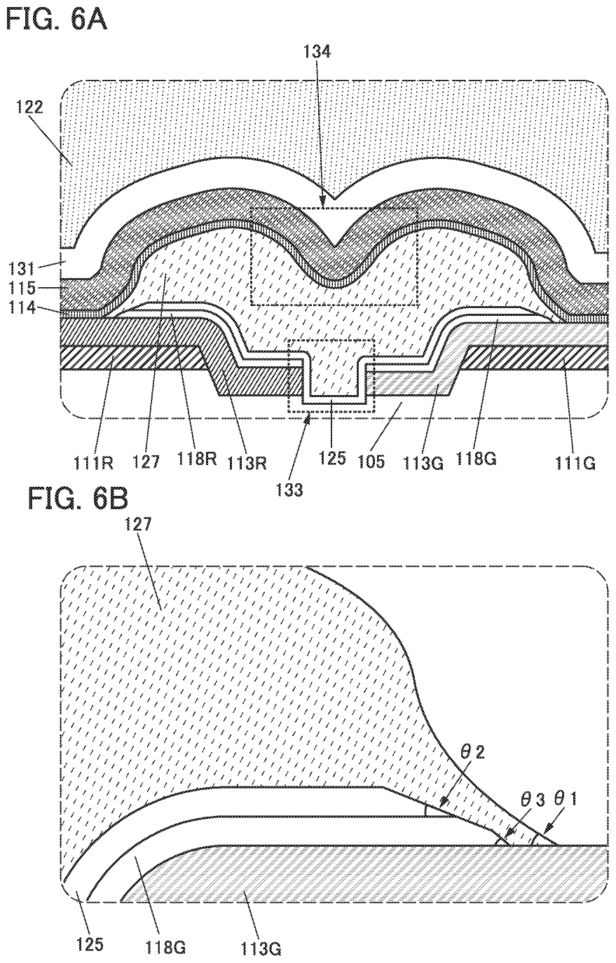

FIG. 5A and FIG. 6A are variation examples of the structure illustrated in FIG. 3A, and FIG. 5B and FIG. 6B are variation examples of the structure illustrated in FIG. 3B. FIG. 5A, FIG. 5B, FIG. 6A, and FIG. 6B illustrate examples where the side surface of the insulating layer 127 has a concave shape (also referred to as a narrowed portion, a depressed portion, a dent, a hollow, or the like). Depending on the material and formation conditions (e.g., heating temperature, heating time, and heating atmosphere) of the insulating layer 127, the side surface of the insulating layer 127 has a concave shape in some cases.

FIGS. 5A and 5B illustrate an example where the insulating layer 127 covers part of the side surface of the mask layer 118G and the other part of the side surface of the mask layer 118G is exposed. FIG. 6A and FIG. 6B illustrate an example where the insulating layer 127 touches and covers the entire side surface of the mask layer 118R and the entire side surface of the mask layer 118G.

Also in the structures illustrated in FIG. 4B, FIG. 5B, and FIG. 6B, each of the taper angles θ1 to θ3 is preferably in the above range.

As illustrated in FIG. 3A, FIG. 4A, FIG. 5A, and FIG. 6A, one end portion of the insulating layer 127 preferably overlaps with the top surface of the pixel electrode 111R and the other end portion of the insulating layer 127 preferably overlaps with the top surface of the pixel electrode 111G. With such a structure, the end portions of the insulating layer 127 can be formed over substantially flat regions of the EL layer 113R and the EL layer 113G. Thus, it becomes relatively easy to form tapered shapes of the insulating layer 127, the insulating layer 125, and the mask layer 118. In addition, film separation of the pixel electrode 111R, the pixel electrode 111G, the EL layer 113R, and the EL layer 113G can be inhibited. Meanwhile, a portion where the top surface of the pixel electrode 111 and the insulating layer 127 overlap with each other is preferably smaller, in which case a light-emitting region of the light-emitting element 130 can be wider and the aperture ratio can be higher.

As described above, in the structures illustrated in FIG. 3A to FIG. 6B, providing the insulating layer 127, the insulating layer 125, the mask layer 118R, and the mask layer 118G enables the common layer 114 and the common electrode 115 to be formed to favorably cover a region from the substantially flat region of the EL layer 113R to the substantially flat region of the EL layer 113G. Moreover, a split portion and a locally thinned portion can be prevented from being formed in the common layer 114 and the common electrode 115. Accordingly, defective connection due to a split portion and an increase in electric resistance due to a locally thinned portion can be inhibited from being caused in the common layer 114 and the common electrode 115 in different light-emitting elements 130. Consequently, the display apparatus 100 can have high display quality.

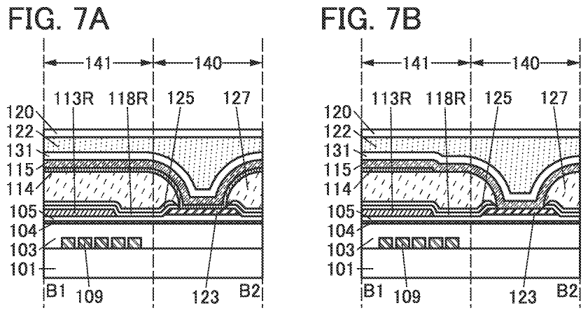

FIG. 7A is a cross-sectional view illustrating a structure example of the region 141 and the connection portion 140. In the region 141, a conductive layer 109 is provided over the insulating layer 101, and the insulating layer 103 is provided over the insulating layer 101 and the conductive layer 109. The conductive layer 109 can be formed in the same step as the conductive layer 102 illustrated in FIG. 2 and contain the same material as the conductive layer 102.

In the region 141, the EL layer 113R over the insulating layer 105, the mask layer 118R over the insulating layer 105 and the EL layer 113R, the insulating layer 125 over the mask layer 118R, the insulating layer 127 over the insulating layer 125, the common layer 114 over the insulating layer 127, the common electrode 115 over the common layer 114, the protective layer 131 over the common electrode 115, the resin layer 122 over the protective layer 131, and the substrate 120 over the resin layer 122 are provided. In the region 141, the mask layer 118R is provided to cover the end portion of the EL layer 113R, for example. Note that in some cases, depending on the manufacturing process of the display apparatus 100, for example, the EL layer 113G or the EL layer 113B instead of the EL layer 113R is provided in the region 141. In some cases, the mask layer 118G or the mask layer 118B instead of the mask layer 118R is provided in the region 141.

The EL layer 113R provided in the region 141 is not electrically connected to the common electrode 115. Accordingly, a structure can be obtained in which no voltage is applied to the EL layer 113R provided in the region 141, so that a structure can be obtained in which the EL layer 113R provided in the region 141 does not emit light.

Although the details will be described later, in the display apparatus in which the EL layer 113R and the mask layer 118R are provided in the region 141, it is possible to prevent the insulating layer 105, the insulating layer 104, and the insulating layer 103 from being partly removed by etching or the like during the manufacturing process of the display apparatus and thus prevent the conductive layer 109 from being exposed. Hence, the conductive layer 109 can be prevented from being unintentionally in the contact with other electrodes, layers, or the like. For example, a short circuit between the conductive layer 109 and the common electrode 115 can be prevented. Consequently, the display apparatus 100 can be a highly reliable display apparatus. Moreover, the display apparatus 100 can be manufactured by a high-yield method.

The connection portion 140 includes the conductive layer 123 over the insulating layer 105, the common layer 114 over the conductive layer 123, the common electrode 115 over the common layer 114, the protective layer 131 over the common electrode 115, the resin layer 122 over the protective layer 131, and the substrate 120 over the resin layer 122. The mask layer 118R is provided to cover the end portion of the conductive layer 123. The insulating layer 125, the insulating layer 127, the common layer 114, the common electrode 115, and the protective layer 131 are stacked in this order over the mask layer 118R. In the case where the mask layer 118G or the mask layer 118B is provided in the region 141 instead of the mask layer 118R, the mask layer 118G or the mask layer 118B is also provided in the connection portion 140 instead of the mask layer 118R.

In the connection portion 140, the conductive layer 123 is electrically connected to the common electrode 115. The conductive layer 123 is electrically connected to an FPC (not illustrated), for example. Accordingly, by supplying a power supply potential to the FPC, for example, the power supply potential can be supplied to the common electrode 115 through the conductive layer 123. The conductive layer 123 can contain the same material as the pixel electrode 111 illustrated in FIG. 2, for example.

Here, in the case where the electric resistance of the common layer 114 in the thickness direction is low enough to be negligible, electrical continuity between the conductive layer 123 and the common electrode 115 can be maintained even when the common layer 114 is provided between the conductive layer 123 and the common electrode 115. When the common layer 114 is provided not only in the pixel portion 107 but also in the region 141 and the connection portion 140, the common layer 114 can be formed, for example, without using a metal mask such as a mask for specifying a film formation area (also referred to as an area mask or a rough metal mask to be distinguished from a fine metal mask). Accordingly, the manufacturing process of the display apparatus 100 can be simplified.

Although the insulating layer 127 provided in the region 141 and the insulating layer 127 provided in the connection portion 140 do not include the depressed portion 134 in FIG. 7A, these insulating layers 127 may include the depressed portion 134.

FIG. 7B is a variation example of the structure in FIG. 7A and illustrates an example where the common layer 114 is not provided in the connection portion 140. In the example illustrated in FIG. 7B, the conductive layer 123 and the common electrode 115 can be in contact with each other. Thus, electric resistance between the conductive layer 123 and the common electrode 115 can be decreased. Although FIG. 7B illustrates a structure where in the region 141, the common layer 114 is provided in a region overlapping with the EL layer 113R and the common layer 114 is not provided in a region not overlapping with the EL layer 113R, one embodiment of the present invention is not limited thereto. For example, in the region 141, it is possible that the common layer 114 is not provided in a region overlapping with the EL layer 113R or the common layer 114 is provided in a region not overlapping with the EL layer 113R.

### [Structure Example 2]

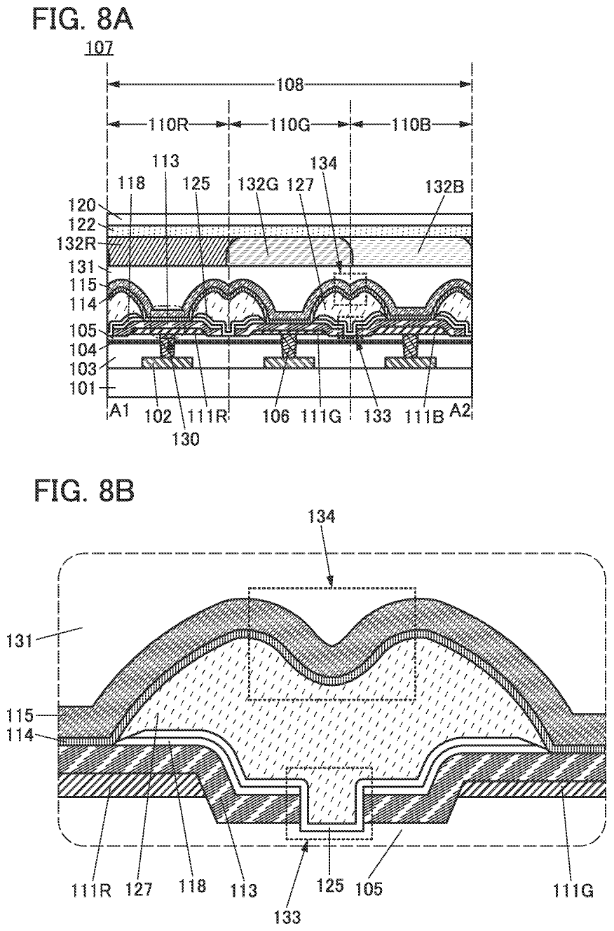

FIG. 8A is a variation example of the structure illustrated in FIG. 2 and illustrates an example where the subpixel 110R includes a coloring layer 132R, the subpixel 110G includes a coloring layer 132G, and the subpixel 110B includes a coloring layer 132B.

As illustrated in FIG. 8A, the coloring layer 132R, the coloring layer 132G, and the coloring layer 132B can be provided over the protective layer 131. In this case, the protective layer 131 is preferably planarized but is not necessarily planarized.

In the example illustrated in FIG. 8A, the light-emitting element 130 included in the subpixel 110R, the light-emitting element 130 included in the subpixel 110G, and the light-emitting element 130 included in the subpixel 110B can emit light of the same color, e.g., white light. In this case, for example, when the coloring layer 132R transmits red light, the coloring layer 132G transmits green light, and the coloring layer 132B transmits blue light, the display apparatus 100 having the structure illustrated in FIG. 8A can perform full-color display. Note that the coloring layer 132R, the coloring layer 132G, or the coloring layer 132B may transmit cyan light, magenta light, yellow light, white light, infrared light, or the like. The light-emitting element 130 may emit infrared light, for example.

Since the EL layers 113 do not have to be formed separately for the respective colors in the display apparatus 100 including the pixel portion 107 with the structure illustrated in FIG. 8A, the manufacturing process of the display apparatus 100 can be simplified. Consequently, the manufacturing cost of the display apparatus 100 can be reduced, making the display apparatus 100 inexpensive.

The adjacent coloring layers 132 include an overlap region over the insulating layer 127. For example, in the cross section illustrated in FIG. 8A, one end portion of the coloring layer 132G overlaps with the coloring layer 132R, and the other end portion of the coloring layer 132G overlaps with the coloring layer 132B. This can prevent leakage of light emitted from the light-emitting element 130 to the adjacent subpixels 110. Thus, for example, light emitted from the light-emitting element 130 provided in the subpixel 110G can be prevented from entering the coloring layer 132R and the coloring layer 132B. Consequently, the display apparatus 100 can have high display quality.

FIG. 8B is a cross-sectional enlarged view of a region including the insulating layer 127 between the two EL layers 113 illustrated in FIG. 8A and the vicinity thereof. Note that FIG. 8B illustrates the pixel electrode 111R and the pixel electrode 111G as the pixel electrode 111. The shapes of the mask layer 118, the insulating layer 125, the insulating layer 127, and the like illustrated in FIG. 8B are the same as those in FIG. 3A.

As illustrated in FIG. 8A and FIG. 8B, the pixel electrode 111R, the pixel electrode 111G, and the pixel electrode 111B can have different thicknesses. For example, the thickness is preferably set in accordance with an optical path length for intensifying light of a color that passes through the coloring layer 132. For example, in the case where the coloring layer 132R transmits red light, the thickness of the pixel electrode 111R is preferably set to intensify red light; in the case where the coloring layer 132G transmits green light, the thickness of the pixel electrode 111G is preferably set to intensify green light; in the case where the coloring layer 132B transmits blue light, the thickness of the pixel electrode 111B is preferably set to intensify blue light. Thus, a microcavity structure is achieved, and the color purity of light emitted from the subpixels 110 can be improved. Note that the pixel electrode 111R, the pixel electrode 111G, and the pixel electrode 111B may have different thicknesses in the structure illustrated in FIG. 2, for example. In that case, a microcavity structure is achieved even when the EL layer 113R, the EL layer 113G, and the EL layer 113B have the same thickness.

### [Structure Example 3]

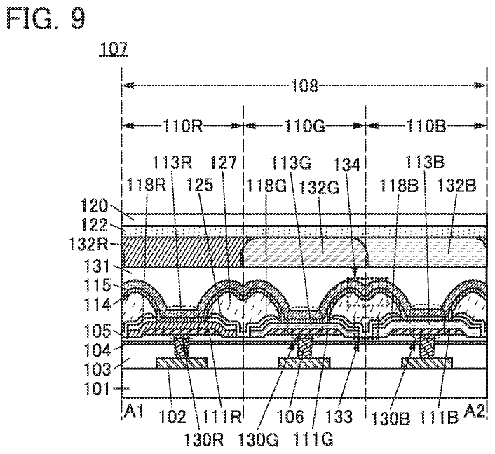

FIG. 9 is a variation example of the structure illustrated in FIG. 2 and illustrates an example where the subpixel 110R includes the coloring layer 132R, the subpixel 110G includes the coloring layer 132G, and the subpixel 110B includes the coloring layer 132B. As illustrated in FIG. 9, the coloring layer 132R, the coloring layer 132G, and the coloring layer 132B can be provided over the protective layer 131. In this case, the protective layer 131 is preferably planarized but is not necessarily planarized.

In FIG. 9, as in the pixel 108 illustrated in FIG. 2, for example, the EL layer 113R provided in the subpixel 110R, the EL layer 113G provided in the subpixel 110G, and the EL layer 113B provided in the subpixel 110B emit light of different colors. For example, the EL layer 113R emits red light, the EL layer 113G emits green light, and the EL layer 113B emits blue light. As in the pixel 108 illustrated in FIG. 2, the EL layer 113R, the EL layer 113G, and the EL layer 113B have different thicknesses, whereby a microcavity structure is obtained.

When the subpixel 110 is provided with the coloring layer 132 and employs a microcavity structure as illustrated in FIG. 9, external light that enters the subpixel 110 and is reflected by the pixel electrode 111, for example, can be inhibited from being perceived without providing a circular polarizing plate over the substrate 120, for example. In addition, the color purity of light emitted from the subpixel 110 can be improved. Accordingly, the display apparatus 100 including the pixel portion 107 with the structure illustrated in FIG. 9 can have high display quality. Note that even in the case where the subpixel 110 is provided with the coloring layer 132, the subpixel 110 does not necessarily employ a microcavity structure. Even in that case, the color purity of light emitted from the subpixel 110 can be improved as compared with the case where the subpixel 110 is not provided with the coloring layer 132.

As described above, by providing the depressed portion 134 in the insulating layer 127 between two EL layers 113 in the display apparatus of one embodiment of the present invention, stress of the insulating layer 127 can be reduced as compared, for example, with the case where the depressed portion 134 is not provided in the insulating layer 127. Accordingly, it is possible to inhibit film separation between the insulating layer 127 and at least one of the layers in contact with the insulating layer 127. Consequently, the display apparatus of one embodiment of the present invention can be a highly reliable display apparatus. Moreover, the display apparatus of one embodiment of the present invention can be manufactured by a high-yield method.

In the display apparatus of one embodiment of the present invention, the island-shaped EL layers are provided in the respective light-emitting elements, whereby generation of leakage current between the subpixels (referred to as lateral direction leakage current, horizontal leakage current, or lateral leakage current in some cases) can be inhibited. This can prevent crosstalk due to unintended light emission, so that a display apparatus with extremely high contrast can be obtained. In addition, the insulating layer having a tapered end portion is provided between adjacent island-shaped EL layers, whereby breakage can be inhibited from being caused at the time of forming the common electrode and a locally thinned portion can be prevented from being formed in the common electrode. Accordingly, defective connection due to a split portion and an increase in electric resistance due to a locally thinned portion can be inhibited from being caused in the common layer and the common electrode. Consequently, the display apparatus of one embodiment of the present invention achieves both high resolution and high display quality.

### [Manufacturing Method Example 1]

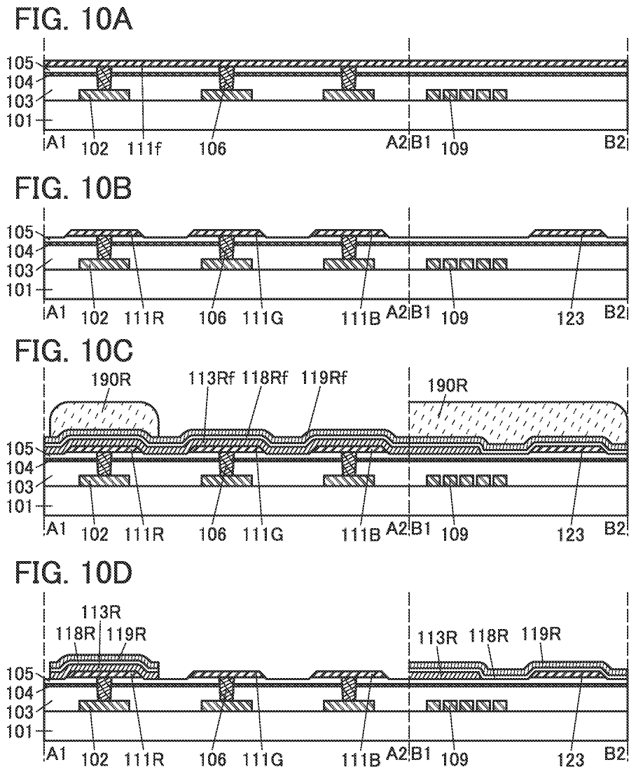

An example of a method for manufacturing the display apparatus 100 having the structure illustrated in FIG. 2 and the structure illustrated in FIG. 7A will be described below with reference to FIG. 10A to FIG. 18B. FIG. 10A to FIG. 18B each illustrate, side by side, a cross section along dashed-dotted line A1-A2 and a cross section along dashed-dotted line B1-B2 in FIG. 1.

Thin films included in the display apparatus (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of the CVD method include a plasma-enhanced chemical vapor deposition (PECVD) method and a thermal CVD method. An example of the thermal CVD method is a metal organic chemical vapor deposition (MOCVD) method.

Alternatively, thin films included in the display apparatus (e.g., insulating films, semiconductor films, and conductive films) can be formed by a wet process such as spin coating, dipping, spray coating, ink-jetting, dispensing, screen printing, offset printing, doctor blade coating, slit coating, roll coating, curtain coating, or knife coating.

To manufacture the light-emitting element, a vacuum process such as an evaporation method and a solution process such as a spin coating method or an ink-jet method can be used. Examples of the evaporation method include a physical vapor deposition method (PVD method) such as a sputtering method, an ion plating method, an ion beam evaporation method, a molecular beam evaporation method, or a vacuum evaporation method and a chemical vapor deposition method (CVD method). Specifically, the functional layers (e.g., the hole-injection layer, the hole-transport layer, the hole-blocking layer, the electron-blocking layer, the electron-transport layer, the electron-injection layer, and the charge-generation layer) included in the EL layer can be formed by an evaporation method (e.g., a vacuum evaporation method), a coating method (e.g., a dip coating method, a die coating method, a bar coating method, a spin coating method, and a spray coating method), a printing method (e.g., an ink-jet method, a screen printing (stencil) method, an offset printing (planography) method, a flexography (relief printing) method, a gravure printing method, or a micro-contact printing method), or the like.

In addition, when the thin films included in the display apparatus are processed, photolithography can be used, for example. Alternatively, a nanoimprinting method, a sandblasting method, a lift-off method, or the like may be used to process the thin films. An island-shaped thin film may be directly formed by a deposition method using a shielding mask such as a metal mask.

There are two typical examples of photolithography. In one of the methods, a resist mask is formed over a thin film that is to be processed, the thin film is processed by etching, for example, and then the resist mask is removed. In the other method, a photosensitive thin film is formed and then processed into a desired shape by light exposure and development.

As light used for light exposure in photolithography, for example, an i-line (with a wavelength of 365 nm), a g-line (with a wavelength of 436 nm), an h-line (with a wavelength of 405 nm), or light in which these lines are mixed can be used. Besides, ultraviolet light, KrF laser light, ArF laser light, or the like can be used. Light exposure may be performed by liquid immersion exposure technique. As the light used for the light exposure, extreme ultraviolet (EUV) light or X-rays may be used. Instead of the light used for the light exposure, an electron beam can also be used. Extreme ultraviolet light, X-rays, or an electron beam is preferably used, in which case extremely minute processing can be performed. Note that when light exposure is performed by scanning of a beam such as an electron beam, a photomask is not needed.

For etching of the thin films, a dry etching method, a wet etching method, a sandblasting method, or the like can be used.

First, as illustrated in FIG. 10A, the insulating layer 101 is formed over a substrate (not illustrated). Next, the conductive layer 102 and the conductive layer 109 are formed over the insulating layer 101, and the insulating layer 103 is formed over the insulating layer 101 so as to cover the conductive layer 102 and the conductive layer 109. Then, the insulating layer 104 is formed over the insulating layer 103, and the insulating layer 105 is formed over the insulating layer 104.

As the substrate, a substrate having at least heat resistance high enough to withstand heat treatment performed later can be used. In the case where an insulating substrate is used as the substrate, a glass substrate, a quartz substrate, a sapphire substrate, a ceramic substrate, an organic resin substrate, or the like can be used. Alternatively, it is possible to use a semiconductor substrate such as a single crystal semiconductor substrate or a polycrystalline semiconductor substrate including silicon, silicon carbide, or the like as a material; a compound semiconductor substrate of silicon germanium or the like; or an SOI substrate.

Next, as illustrated in FIG. 10A, openings reaching the conductive layer 102 are formed in the insulating layer 105, the insulating layer 104, and the insulating layer 103. Then, the plugs 106 are formed to fill the openings.

Next, as illustrated in FIG. 10A, a conductive film 111f to be the pixel electrode 111R, the pixel electrode 111G, the pixel electrode 111B, and the conductive layer 123 is formed over the plugs 106 and the insulating layer 105. The conductive film 111f can be formed by a sputtering method or a vacuum evaporation method, for example. A metal material can be used for the conductive film 111f, for example.

Next, as illustrated in FIG. 10B, the conductive film 111f is processed by, for example, photolithography to form the pixel electrode 111R, the pixel electrode 111G, the pixel electrode 111B, and the conductive layer 123. Specifically, after a resist mask is formed, part of the conductive film 111f is removed by an etching method, for example. The conductive film 111f can be removed by, for example, a dry etching method. Here, in the case where part of the conductive film 111f is removed by a dry etching method, for example, a depressed portion may be formed in a region of the insulating layer 105 that does not overlap with the pixel electrode 111.

Then, hydrophobic treatment is preferably performed on the pixel electrode 111. The hydrophobic treatment can change the hydrophilic properties of the subject surface to hydrophobic properties or increase the hydrophobic properties of the subject surface. The hydrophobic treatment for the pixel electrode 111 can increase the adhesion between the pixel electrode 111 and the EL layer 113 formed in a later step and suppress film separation. Note that the hydrophobic treatment is not necessarily performed.

The hydrophobic treatment can be performed by fluorination of the pixel electrode 111, for example. The fluorination can be performed by, for example, treatment or heat treatment using a fluorine-containing gas, plasma treatment in an atmosphere of a fluorine-containing gas, or the like. As the fluorine-containing gas, a fluorine gas such as a fluorocarbon gas can be used, for example. As the fluorocarbon gas, a low carbon fluoride gas such as a carbon tetrafluoride (CF₄) gas, a C₄F₆ gas, a C₂F₆ gas, a C₄F₈ gas, or a C₅F₈ gas can be used, for example. Moreover, as the fluorine-containing gas, a SF₆ gas, a NF₃ gas, a CHF₃ gas, or the like can be used, for example. Furthermore, a helium gas, an argon gas, a hydrogen gas, an oxygen gas, or the like can be added to these gases as appropriate.

In addition, treatment using a silylation agent is performed on the surface of the pixel electrode 111 after plasma treatment is performed in a gas atmosphere containing a Group 18 element such as argon, so that the surface of the pixel electrode 111 can have a hydrophobic property. As the silylation agent, hexamethyldisilazane (HMDS), trimethylsilylimidazole (TMSI), or the like can be used. Alternatively, treatment using a silane coupling agent is performed on the surface of the pixel electrode 111 after plasma treatment is performed in a gas atmosphere containing a Group 18 element such as argon, so that the surface of the pixel electrode 111 can be hydrophobic.

Plasma treatment in a gas atmosphere containing a Group 18 element such as argon is performed on the surface of the pixel electrode 111, whereby the surface of the pixel electrode 111 can be damaged. Accordingly, a methyl group contained in the silylation agent such as HMDS is likely to bond to the surface of the pixel electrode 111. Moreover, silane coupling due to the silane coupling agent is likely to occur. As described above, treatment using a silylation agent or a silane coupling agent performed on the surface of the pixel electrode 111 after plasma treatment in a gas atmosphere containing a Group 18 element such as argon enables the surface of the pixel electrode 111 to be hydrophobic.

The treatment using the silylation agent, the silane coupling agent, or the like can be performed by application of the silylation agent, the silane coupling agent, or the like by a spin coating method or a dipping method, for example. The treatment using the silylation agent, the silane coupling agent, or the like can also be performed by forming a film containing the silylation agent, a film containing the silane coupling agent, or the like over the pixel electrode 111 and the like by a gas phase method, for example. In a gas phase method, first, a material containing the silylation agent, a material containing the silane coupling agent, or the like is volatilized so that the silylation agent, the silane coupling agent, or the like is included in the atmosphere. Then, the substrate where the pixel electrode 111, for example, is formed is put in the atmosphere. In this manner, a film containing a silylation agent, a silane coupling agent, or the like can be formed over the pixel electrode 111, whereby the surface of the pixel electrode 111 can be hydrophobic.

Next, as illustrated in FIG. 10C, an EL film 113Rf to be the EL layer 113R is formed over the pixel electrode 111R, the pixel electrode 111G, the pixel electrode 111B, and the insulating layer 105.

As illustrated in FIG. 10C, the EL film 113Rf is not formed over the conductive layer 123. For example, a mask for specifying a film formation area (also referred to as an area mask or a rough metal mask to be distinguished from a fine metal mask) is used, so that the EL film 113Rf can be formed only in a desired region. Employing a film formation step using an area mask and a processing step using a resist mask enables a light-emitting element to be manufactured by a relatively easy process.

The EL film 113Rf can be formed by an evaporation method, specifically a vacuum evaporation method, for example. The EL film 113Rf may be formed by a transfer method, a printing method, an inkjet method, a coating method, or the like.

The EL film 113Rf includes at least a light-emitting film to be a light-emitting layer. The EL film 113Rf includes a functional film to be a functional layer. The EL film 113Rf includes, for example, a light-emitting film and a functional film over the light-emitting film. The functional film can include one or more of films to be a hole-injection layer, a hole-transport layer, a hole-blocking layer, a charge-generation layer, an electron-blocking layer, an electron-transport layer, and an electron-injection layer, for example. Thus, forming the EL film 113Rf means forming a light-emitting film and a functional film over the light-emitting film, for example.

Next, as illustrated in FIG. 10C, a mask film 118Rf to be the mask layer 118R and a mask film 119Rf to be the mask layer 119R are sequentially formed over the EL film 113Rf, the conductive layer 123, and the insulating layer 105.

Although this embodiment describes an example where the mask film is formed with a two-layer structure of the mask film 118Rf and the mask film 119Rf, the mask film may have a single-layer structure or a stacked-layer structure of three or more layers.

Providing the mask film over the EL film 113Rf can reduce damage to the EL film 113Rf in the manufacturing process of the display apparatus, resulting in improved reliability of the light-emitting element.

As the mask film 118Rf, a film that is highly resistant to the processing conditions for the EL film 113Rf, specifically, a film having high etching selectivity to the EL film 113Rf is used. As the mask film 119Rf, a film having high etching selectivity to the mask film 118Rf is used.

The mask film 118Rf and the mask film 119Rf are formed at a temperature lower than the upper temperature limit of the EL film 113Rf. The typical substrate temperatures in formation of the mask film 118Rf and the mask film 119Rf are each lower than or equal to 200° C., preferably lower than or equal to 150° C., further preferably lower than or equal to 120° C., still further preferably lower than or equal to 100° C., yet still further preferably lower than or equal to 80° C.

The mask film 118Rf and the mask film 119Rf are preferably films that can be removed by a wet etching method. The use of a wet etching method can reduce damage to the EL film 113Rf in processing of the mask film 118Rf and the mask film 119Rf, as compared with the case of using a dry etching method.

The mask film 118Rf and the mask film 119Rf can be formed by a sputtering method, an ALD method (a thermal ALD method or a PEALD method), a CVD method, or a vacuum evaporation method, for example. Alternatively, the mask film 118Rf and the mask film 119Rf may be formed by the above-described wet process.

Note that the mask film 118Rf that is formed on and in contact with the EL film 113Rf is preferably formed by a formation method that is less likely to damage the EL film 113Rf than a formation method of the mask film 119Rf. For example, the mask film 118Rf is preferably formed by an ALD method or a vacuum evaporation method rather than a sputtering method.

For each of the mask film 118Rf and the mask film 119Rf, one or more of a metal film, an alloy film, a metal oxide film, a semiconductor film, an organic insulating film, and an inorganic insulating film, for example, can be used.

For each of the mask film 118Rf and the mask film 119Rf, it is preferable to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. A metal material that can block ultraviolet rays is preferably used for one or both of the mask film 118Rf and the mask film 119Rf, in which case the EL film 113Rf can be prevented from being irradiated with ultraviolet rays and deterioration of the EL film 113Rf can be suppressed.

For each of the mask film 118Rf and the mask film 119Rf, a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon can be used.

Note that an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium described above. Specifically, M is preferably one or more kinds selected from gallium, aluminum, and yttrium.

As the mask film, a film containing a material having a light-blocking property, particularly with respect to ultraviolet rays, can be used. For example, a film having a property of reflecting ultraviolet rays or a film absorbing ultraviolet rays can be used. Although a variety of materials such as a metal, an insulator, a semiconductor, and a metalloid that have a property of blocking ultraviolet rays can be used as a light-blocking material, the mask film is preferably a film capable of being processed by etching and is particularly preferably a film having good processability because part or the whole of the mask film is removed in a later step.

For example, a semiconductor material such as silicon or germanium can be used as a material with an affinity for the semiconductor manufacturing process. An oxide or a nitride of the semiconductor material can be used. A nonmetal (metalloid) material such as carbon or a compound thereof can be used. A metal such as titanium, tantalum, tungsten, chromium, or aluminum or an alloy containing at least one of these metals can be used. Alternatively, an oxide containing the above-described metal, such as titanium oxide or chromium oxide, or a nitride such as titanium nitride, chromium nitride, or tantalum nitride can be used.

When a film containing a material having a property of blocking ultraviolet rays is used as the mask film, the EL layer can be prevented from being irradiated with ultraviolet rays in a light exposure step, for example. The EL layer is inhibited from being damaged by ultraviolet rays, so that the reliability of the light-emitting element can be improved.

Note that the same effect is obtained when a film containing a material having a property of blocking ultraviolet rays is used as an insulating film 125f to be described later.

As the mask film 118Rf and the mask film 119Rf, a variety of inorganic insulating films that can be used as the protective layer 131 can be used. In particular, an oxide insulating film is preferable because its adhesion to the EL film 113Rf is higher than that of a nitride insulating film. For example, an inorganic insulating material such as aluminum oxide, hafnium oxide, or silicon oxide can be used for the mask film 118Rf and the mask film 119Rf. As the mask film 118Rf and the mask film 119Rf, an aluminum oxide film can be formed by an ALD method, for example. An ALD method is preferably used, in which case damage to a base (in particular, the EL layer) can be reduced.

For example, an inorganic insulating film (e.g., an aluminum oxide film) formed by an ALD method can be used as the mask film 118Rf, and an inorganic film (e.g., an In—Ga—Zn oxide film, an aluminum film, or a tungsten film) formed by a sputtering method can be used as the mask film 119Rf.

Note that the same inorganic insulating film can be used for both the mask film 118Rf and the insulating layer 125 that is to be formed later. For example, an aluminum oxide film formed by an ALD method can be used for both the mask film 118Rf and the insulating layer 125. For the mask film 118Rf and the insulating layer 125, the same deposition conditions may be used or different deposition conditions may be used. For example, when the mask film 118Rf is formed under conditions similar to those of the insulating layer 125, the mask film 118Rf can be an insulating layer having a high barrier property against at least one of water and oxygen. Meanwhile, the mask film 118Rf is a layer most or all of which is to be removed in a later step, and thus is preferably easy to process. Therefore, the mask film 118Rf is preferably formed with a substrate temperature lower than that for formation of the insulating layer 125.

One or both of the mask film 118Rf and the mask film 119Rf may be formed using an organic material. For example, as the organic material, a material that can be dissolved in a solvent chemically stable with respect to at least the uppermost film of the EL film 113Rf may be used. Specifically, a material that will be dissolved in water or alcohol can be suitably used. In forming a film of such a material, it is preferable to apply the material dissolved in a solvent such as water or alcohol by a wet film formation method and then perform heat treatment for evaporating the solvent. In that case, the heat treatment is preferably performed in a reduced-pressure atmosphere, in which case the solvent can be removed at a low temperature in a short time and thermal damage to the EL film 113Rf can be reduced accordingly.

The mask film 118Rf and the mask film 119Rf may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluorine resin like perfluoropolymer.

For example, an organic film (e.g., a PVA film) formed by an evaporation method or any of the above wet processes can be used as the mask film 118Rf, and an inorganic film (e.g., a silicon nitride film) formed by a sputtering method can be used as the mask film 119Rf.

Note that in the display apparatus of one embodiment of the present invention, part of the mask film remains as a mask layer in some cases.

Subsequently, a resist mask 190R is formed over the mask film 119Rf as illustrated in FIG. 10C. The resist mask 190R can be formed by application of a photosensitive material (photoresist), light exposure, and development.

The resist mask 190R may be formed using either a positive resist material or a negative resist material.

The resist mask 190R is provided at a position overlapping with the pixel electrode 111R. Note that the resist mask 190R is preferably provided also at a position overlapping with the conductive layer 123. This can inhibit the conductive layer 123 from being damaged during the step of manufacturing the display apparatus. Note that the resist mask 190R is not necessarily provided over the conductive layer 123. The resist mask 190R is preferably provided to cover the area from the end portion of the EL film 113Rf to the end portion of the conductive layer 123 (the end portion on the EL film 113Rf side), as illustrated in the cross-sectional view along B1-B2 in FIG. 10C.

Next, as illustrated in FIG. 10D, part of the mask film 119Rf is removed using the resist mask 190R, whereby the mask layer 119R is formed. The mask layer 119R remains over the pixel electrode 111R and the conductive layer 123. After that, the resist mask 190R is removed. Then, part of the mask film 118Rf is removed using the mask layer 119R as a mask (also referred to as a hard mask), whereby the mask layer 118R is formed.

The mask film 118Rf and the mask film 119Rf can be processed by a wet etching method or a dry etching method. The mask film 118Rf and the mask film 119Rf are preferably processed by anisotropic etching.

The use of a wet etching method can reduce damage to the EL film 113Rf in processing of the mask film 118Rf and the mask film 119Rf, as compared with the case of using a dry etching method. In the case of using a wet etching method, it is preferable to use a developer, a tetramethylammonium hydroxide (TMAH) aqueous solution, dilute hydrofluoric acid, oxalic acid, phosphoric acid, acetic acid, nitric acid, or a chemical solution containing a mixed solution of any of these acids, for example.

Since the EL film 113Rf is not exposed in the processing of the mask film 119Rf, the range of choice for a processing method for the mask film 119Rf is wider than that for the mask film 118Rf. Specifically, even in the case where a gas containing oxygen is used as an etching gas in the processing of the mask film 119Rf, deterioration of the EL film 113Rf can be suppressed.

In the case of using a dry etching method to process the mask film 118Rf, deterioration of the EL film 113Rf can be suppressed by not using a gas containing oxygen as the etching gas.

In the case of using a dry etching method, it is preferable to use a gas containing CF₄, C₄F₈, SF₆, CHF₃, Cl₂, H₂O, BCl₃, or a Group 18 element such as He, for example, as the etching gas.

For example, in the case where an aluminum oxide film formed by an ALD method is used as the mask film 118Rf, part of the mask film 118Rf can be removed by a dry etching method using CHF₃ and He or a combination of CHF₃, He, and CH₄. In the case where an In—Ga—Zn oxide film formed by a sputtering method is used as the mask film 119Rf, part of the mask film 119Rf can be removed by a wet etching method using diluted phosphoric acid. Alternatively, part of the mask film 119Rf may be removed by a dry etching method using CH₄ and Ar. Alternatively, part of the mask film 119Rf can be removed by a wet etching method using diluted phosphoric acid. In the case where a tungsten film formed by a sputtering method is used as the mask film 119Rf, part of the mask film 119Rf can be removed by a dry etching method using a combination of SF₆, CF₄, and O₂ or a combination of CF₄, Cl₂, and O₂.

The resist mask 190R can be removed by ashing using oxygen plasma, for example. Alternatively, an oxygen gas and any of CF₄, C₄F₈, SF₆, CHF₃, Cl₂, H₂O, BCl₃, and a Group 18 element such as He may be used. Alternatively, the resist mask 190R may be removed by wet etching. In that case, the mask film 118Rf is positioned on the outermost surface, and the EL film 113Rf is not exposed; thus, the EL film 113Rf can be prevented from being damaged in the step of removing the resist mask 190R. In addition, the range of choices for the method for removing the resist mask 190R can be widened.

Next, as illustrated in FIG. 10D, the EL film 113Rf is processed to form the EL layer 113R. For example, part of the EL film 113Rf is removed using the mask layer 119R and the mask layer 118R as a mask to form the EL layer 113R.

Accordingly, as illustrated in FIG. 10D, a stacked-layer structure of the EL layer 113R, the mask layer 118R, and the mask layer 119R remains over the pixel electrode 111R. In addition, the pixel electrode 111G and the pixel electrode 111B are exposed.

FIG. 10D illustrates an example where the end portion of the EL layer 113R is positioned on the outer side of the end portion of the pixel electrode 111R. Such a structure can increase the aperture ratio of the pixel. Although not illustrated in FIG. 10D, by the above etching treatment, a depressed portion may be formed in the insulating layer 105 in a region not overlapping with the EL layer 113R.

The EL layer 113R covering the top surface and the side surface of the pixel electrode 111R makes it possible to perform the subsequent steps without exposure of the pixel electrode 111R. When the end portion of the pixel electrode 111R is exposed, corrosion might occur in an etching step, for example. A product generated by corrosion of the pixel electrode 111R might be unstable; for example, the product might be dissolved in a solution in wet etching and might be scattered in an atmosphere when dry etching is performed. The product dissolved in a solution or scattered in an atmosphere might be attached to a surface to be processed, the side surface of the EL layer 113R, for example, which might adversely affect the characteristics of the light-emitting element or form a leakage path between the light-emitting elements. In a region where the end portion of the pixel electrode 111R is exposed, adhesion between layers in contact with each other might be lowered, which might be likely to cause separation of the EL layer 113R or the pixel electrode 111R.

Thus, with the structure where the EL layer 113R covers the top surface and the side surface of the pixel electrode 111R, for example, the yield and characteristics of the light-emitting element can be improved

As described above, the resist mask 190R is preferably provided to cover the area from the end portion of the EL layer 113R to the end portion of the conductive layer 123 (the end portion on the EL layer 113R side) in the cross section B1-B2. Thus, as illustrated in FIG. 10D, the mask layer 118R and the mask layer 119R are provided to cover the area from the end portion of the EL layer 113R to the end portion of the conductive layer 123 (the end portion on the EL layer 113R side) in the cross section B1-B2. Hence, the insulating layer 105 can be inhibited from being exposed in the cross section B1-B2, for example. This can prevent the insulating layer 105, the insulating layer 104, and the insulating layer 103 from being partly removed by etching or the like, and thus prevent the conductive layer 109 from being exposed. Accordingly, the conductive layer 109 can be inhibited from being unintentionally electrically connected to another conductive layer. For example, a short circuit between the conductive layer 109 and the common electrode 115 to be formed in a later step can be suppressed.

The EL film 113Rf is preferably processed by anisotropic etching. Anisotropic dry etching is particularly preferable. Alternatively, a wet etching may be used.

In the case of using a dry etching method, deterioration of the EL film 113Rf can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Thus, damage to the EL film 113Rf can be suppressed. Furthermore, a defect such as attachment of a reaction product generated at the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one of the above is preferably used as the etching gas. Alternatively, an oxygen gas may be used as the etching gas. Specifically, for example, a gas containing H₂ and Ar or a gas containing CF₄ and He can be used as the etching gas. As another example, a gas containing CF₄, He, and oxygen can be used as the etching gas. As another example, a gas containing H₂ and Ar and a gas containing oxygen can be used as the etching gas.

As described above, in one embodiment of the present invention, the mask layer 119R is formed in the following manner: the resist mask 190R is formed over the mask film 119Rf and part of the mask film 119Rf is removed using the resist mask 190R. After that, part of the EL film 113Rf is removed using the mask layer 119R as a mask, so that the EL layer 113R is formed.

In other words, the EL layer 113R can be formed by processing the EL film 113Rf by photolithography. Note that part of the EL film 113Rf may be removed using the resist mask 190R. Then, the resist mask 190R may be removed.

Next, hydrophobic treatment for the pixel electrode 111G, for example, is preferably performed. At the time of processing the EL film 113Rf, the surface of the pixel electrode 111G changes to have hydrophilic properties in some cases, for example. The hydrophobic treatment for the pixel electrode 111G, for example, can increase the adhesion between the pixel electrode 111G and a layer to be formed in a later step (here, the EL layer 113G) and suppress film separation. Note that the hydrophobic treatment is not necessarily performed.

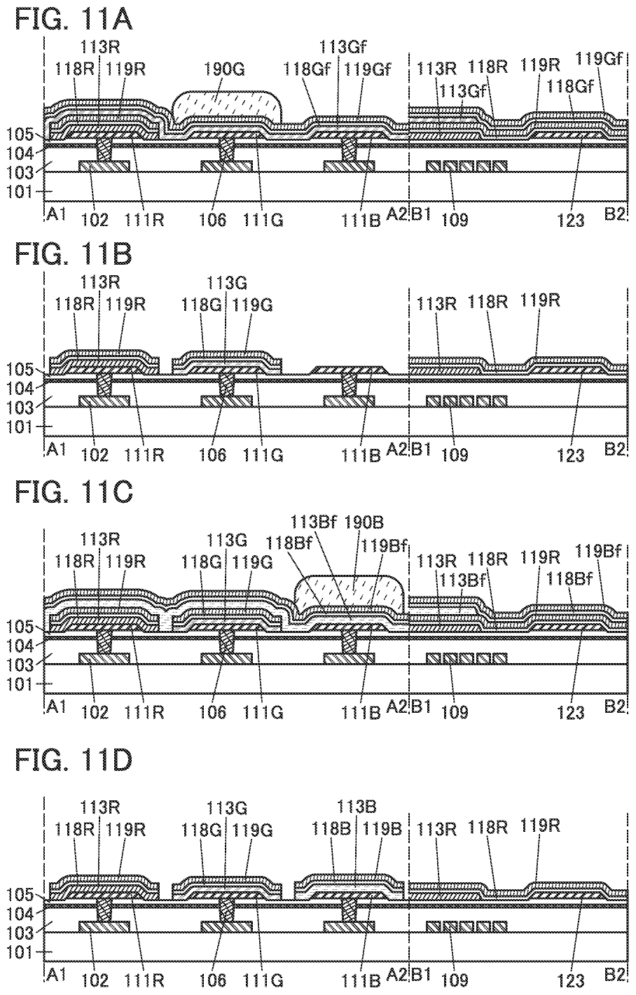

Next, as illustrated in FIG. 11A, an EL film 113Gf to be the EL layer 113G is formed over the pixel electrode 111G, the pixel electrode 111B, the mask layer 119R, and the insulating layer 105.

The EL film 113Gf can be formed by a method similar to that for forming the EL film 113Rf. Like the EL film 113Rf, the EL film 113Gf includes, for example, a light-emitting film and a functional film over the light-emitting film. Thus, forming the EL film 113Gf means forming a light-emitting film and a functional film over the light-emitting film, for example.

Then, as illustrated in FIG. 11A, a mask film 118Gf to be the mask layer 118G and a mask film 119Gf to be a mask layer 119G are sequentially formed over the EL film 113Gf and the mask layer 119R. After that, a resist mask 190G is formed. The materials and the formation methods of the mask film 118Gf and the mask film 119Gf are similar to those for the mask film 118Rf and the mask film 119Rf. The material and the formation method of the resist mask 190G are similar to those for the resist mask 190R.

The resist mask 190G is provided at a position overlapping with the pixel electrode 111G.

Subsequently, as illustrated in FIG. 11B, part of the mask film 119Gf is removed using the resist mask 190G to form the mask layer 119G. The mask layer 119G remains over the pixel electrode 111G. After that, the resist mask 190G is removed. Then, part of the mask film 118Gf is removed using the mask layer 119G as a mask to form the mask layer 118G. Next, the EL film 113Gf is processed to form the EL layer 113G. For example, part of the EL film 113Gf is removed using the mask layer 119G and the mask layer 118G as a mask to form the EL layer 113G.

Accordingly, as illustrated in FIG. 11B, a stacked-layer structure of the EL layer 113G, the mask layer 118G, and the mask layer 119G remains over the pixel electrode 111G. The mask layer 119R and the pixel electrode 111B are exposed.

Next, hydrophobic treatment for the pixel electrode 111B, for example, is preferably performed. At the time of processing the EL film 113Gf, the surface of the pixel electrode 111B changes to have hydrophilic properties in some cases, for example. The hydrophobic treatment for the pixel electrode 111B, for example, can increase the adhesion between the pixel electrode 111B and a layer to be formed in a later step (here, the EL layer 113B) and suppress film separation. Note that the hydrophobic treatment is not necessarily performed.

Next, as illustrated in FIG. 11C, an EL film 113Bf to be the EL layer 113B is formed over the pixel electrode 111B, the mask layer 119R, the mask layer 119G, and the insulating layer 105.

The EL film 113Bf can be formed by a method similar to that for forming the EL film 113Rf. Like the EL film 113Rf, the EL film 113Bf includes, for example, a light-emitting film and a functional film over the light-emitting film. Thus, forming the EL film 113Bf means forming a light-emitting film and a functional film over the light-emitting film, for example.

Then, as illustrated in FIG. 11C, a mask film 118Bf to be the mask layer 118B and a mask film 119Bf to be a mask layer 119B are sequentially formed over the EL film 113Bf and the mask layer 119R. After that, a resist mask 190B is formed. The materials and the formation methods of the mask film 118Bf and the mask film 119Bf are similar to those for the mask film 118Rf and the mask film 119Rf. The material and the formation method of the resist mask 190B are similar to those for the resist mask 190R.

The resist mask 190B is provided at a position overlapping with the pixel electrode 111B.

Subsequently, as illustrated in FIG. 11D, part of the mask film 119Bf is removed using the resist mask 190B to form the mask layer 119B. The mask layer 119B remains over the pixel electrode 111B. After that, the resist mask 190B is removed. Then, part of the mask film 118Bf is removed using the mask layer 119B as a mask to form the mask layer 118B. Next, the EL film 113Bf is processed to form the EL layer 113B. For example, part of the EL film 113Bf is removed using the mask layer 119B and the mask layer 118B as a mask to form the EL layer 113B. Accordingly, as illustrated in FIG. 11D, a stacked-layer structure of the EL layer 113B, the mask layer 118B, and the mask layer 119B remains over the pixel electrode 111B. The mask layer 119R and the mask layer 119G are exposed.

Note that the side surfaces of the EL layer 113R, the EL layer 113G, and the EL layer 113B are preferably perpendicular or substantially perpendicular to their formation surfaces. For example, the angle between the formation surfaces and these side surfaces is preferably greater than or equal to 60° and less than or equal to 90°.

The distance between two adjacent layers among the EL layer 113R, the EL layer 113G, and the EL layer 113B, which are formed by photolithography as described above, can be reduced to 8 μm or less, 5 μm or less, 3 μm or less, 2 μm or less, or 1 μm or less. Here, the distance can be specified, for example, by the distance between opposite end portions of two adjacent layers among the EL layer 113R, the EL layer 113G, and the EL layer 113B. Reducing the distance between the adjacent EL layers 113 can provide a display apparatus having high resolution and a high aperture ratio.

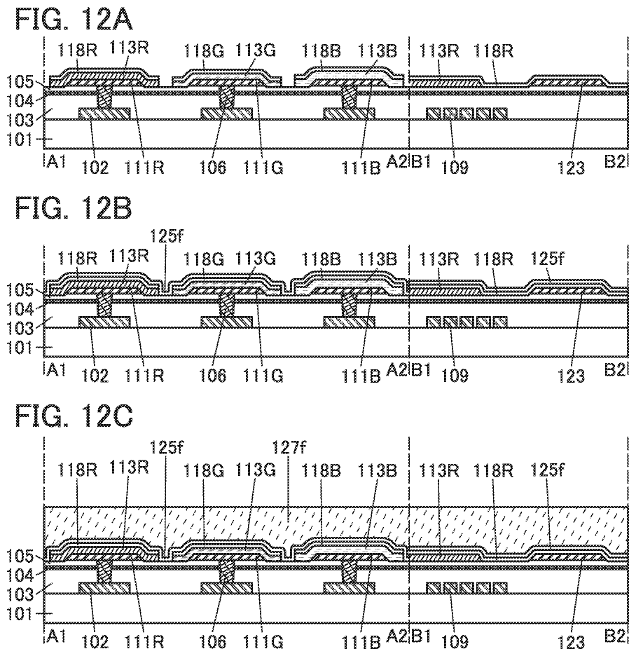

Next, as illustrated in FIG. 12A, the mask layer 119R, the mask layer 119G, and the mask layer 119B are preferably removed. The mask layer 118R, the mask layer 118G, the mask layer 118B, the mask layer 119R, the mask layer 119G, and the mask layer 119B remain in the display apparatus in some cases depending on the subsequent steps. Removing the mask layer 119R, the mask layer 119G, and the mask layer 119B at this stage can prevent the mask layer 119R, the mask layer 119G, and the mask layer 119B from remaining in the display apparatus. For example, in the case where a conductive material is used for the mask layer 119R, the mask layer 119G, and the mask layer 119B, removing the mask layer 119R, the mask layer 119G, and the mask layer 119B in advance can suppress generation of leakage current, formation of a capacitor, and the like due to the remaining mask layers 119R, 119G, and 119B.

This embodiment describes an example where the mask layer 119R, the mask layer 119G, and the mask layer 119B are removed; however, the mask layer 119R, the mask layer 119G, and the mask layer 119B are not necessarily removed.

The step of removing the mask layers can be performed by a method similar to that for the step of processing the mask layers. In particular, using a wet etching method can reduce damage to the EL layer 113R, the EL layer 113G, and the EL layer 113B in removing the mask layers, as compared with the case of using a dry etching method.

The mask layers may be removed by being dissolved in a solvent such as water or an alcohol. Examples of an alcohol include ethyl alcohol, methyl alcohol, isopropyl alcohol (IPA), and glycerin.

After the mask layers are removed, drying treatment may be performed in order to remove water included in the EL layer 113R, the EL layer 113G, and the EL layer 113B and water adsorbed on the surfaces of the EL layer 113R, the EL layer 113G, and the EL layer 113B. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, as illustrated in FIG. 12B, the insulating film 125f to be the insulating layer 125 is formed to cover the EL layer 113R, the EL layer 113G, and the EL layer 113B, the mask layer 118R, the mask layer 118G, and the mask layer 118B.

As described later, an insulating film to be the insulating layer 127 is formed in contact with the top surface of the insulating film 125f. Therefore, the top surface of the insulating film 125f preferably has a high affinity for the material used for the insulating film (e.g., a photosensitive resin composition containing an acrylic resin). To improve the affinity, surface treatment is preferably performed so that the top surface of the inorganic insulating film 125f is made hydrophobic or its hydrophobic properties are improved. For example, it is preferable to perform the treatment using a silylation agent such as hexamethyldisilazane (HMDS). By making the top surface of the insulating film 125f hydrophobic in this manner, the insulating film 127f can be formed with high adhesion. Note that the above-described hydrophobization treatment may be performed as the surface treatment.

The same material as that can be used for the mask layer 118R, the mask layer 118G, and the mask layer 118B can be used for the insulating film 125f. For example, in the case where aluminum oxide is used for the mask layer 118R, the mask layer 118G, and the mask layer 118B, an aluminum oxide film can also be used as the insulating film 125f. The same material is preferably used for the insulating film 125f and the mask layer 118, in which case the insulating film 125f and the mask layer 118 can be processed in a later step under the same conditions, specifically the same etching conditions.

Then, as illustrated in FIG. 12C, the insulating film 127f to be the insulating layer 127 is formed over the insulating film 125f.

The insulating film 125f and the insulating film 127f are preferably formed by a formation method that is less likely to damage the EL layer 113R, the EL layer 113G, and the EL layer 113B are less damaged. The insulating film 125f, which is formed in contact with the side surfaces of the EL layer 113R, the EL layer 113G, and the EL layer 113B, is particularly preferably formed by a formation method that is less likely to damage the EL layer 113R, the EL layer 113G, and the EL layer 113B than the method of forming the insulating film 127f.

Each of the insulating film 125f and the insulating film 127f is formed at a temperature lower than the upper temperature limit of the EL layer 113R, the EL layer 113G, and the EL layer 113B. When the substrate temperature in forming the insulating film 125f is increased, the formed insulating film 125f, even with a small thickness, can have a low impurity concentration and a high barrier property against at least one of water and oxygen.

The substrate temperature in forming the insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the insulating film 125f, an insulating film having a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed in the above-described range of the substrate temperature.

For example, an ALD method is preferably used to form the insulating film 125f. An ALD method is preferably used, in which case damage by the deposition can be reduced and a film with good coverage can be formed. As the insulating film 125f, an aluminum oxide film is preferably formed by an ALD method, for example.

Alternatively, the insulating film 125f may be formed by a sputtering method, a CVD method, or a PECVD method that has a higher deposition rate than an ALD method. In that case, a highly reliable display apparatus can be manufactured with high productivity.

The insulating film 127f is preferably formed by the aforementioned wet process. The insulating film 127f is preferably formed by spin coating using a photosensitive material, for example, and specifically preferably formed using a photosensitive resin composition containing an acrylic resin.

The insulating film 127f is preferably formed using a resin composition containing a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

Heat treatment (also referred to as prebaking) is preferably performed after the insulating film 127f is formed. The heat treatment is performed at a temperature lower than the upper temperature limit of the EL layer 113R, the EL layer 113G, and the EL layer 113B. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. In that case, a solvent contained in the insulating film 127f can be removed.

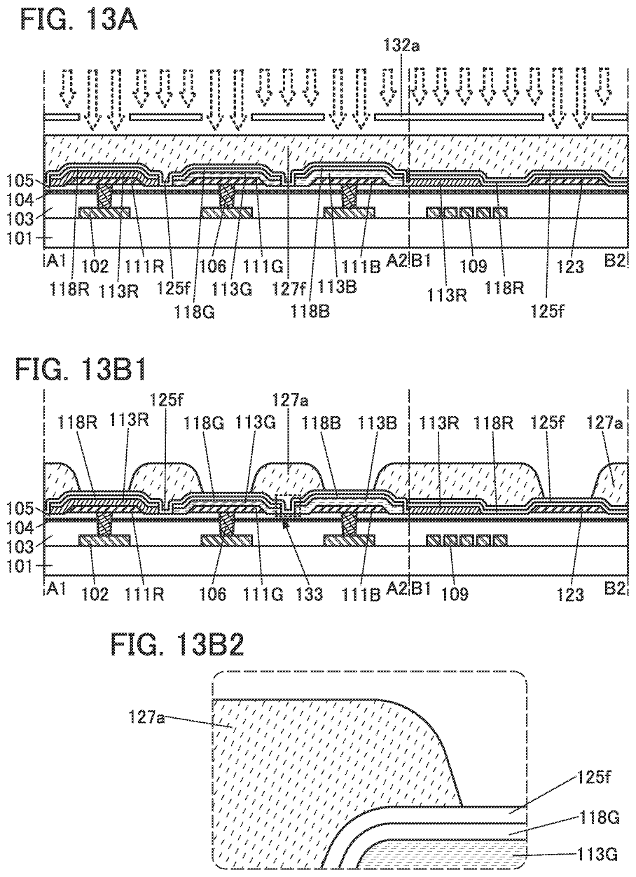

Next, as illustrated in FIG. 13A, light exposure is performed to expose part of the insulating film 127f to visible light or ultraviolet rays. In FIG. 13A, arrows indicate light for exposure. The same applies to the other drawings illustrating light exposure steps.

In the case where a positive photosensitive resin composite containing an acrylic resin is used for the insulating film 127f, a region where the insulating layer 127 is not formed in a later step is irradiated with visible light or ultraviolet rays using a mask 132a. The insulating layer 127 is formed in regions that are sandwiched between any two of the EL layer 113R, the EL layer 113G, and the EL layer 113B and around the conductive layer 123. Specifically, the insulating layer 127 is formed so that it overlaps with parts of the top surfaces of two EL layers 113 and includes a region positioned between the side surfaces of the two EL layers 113, for example. Thus, as illustrated in FIG. 13A, regions over the EL layer 113R, the EL layer 113G, the EL layer 113B, and the conductive layer 123 are irradiated with visible light or ultraviolet rays using the mask 132a. Note that light exposure to the insulating film 127f may be hereinafter referred to as first light exposure.

The width of the insulating layer 127 to be formed can be controlled by the region exposed to light in the first light exposure. For example, the insulating film 127f can be processed so that the insulating layer 127 includes a portion overlapping with the top surface of the pixel electrode 111.

Light used for the first light exposure preferably includes the i-line (wavelength: 365 nm). Furthermore, light used for the first light exposure may include at least one of the g-line (wavelength: 436 nm) and the h-line (wavelength: 405 nm).

Here, a barrier insulating layer against oxygen, a specific example of which is an aluminum oxide film, is provided as one or both of the mask layer 118 and the insulating film 125f, whereby diffusion of oxygen to the EL layer 113R, the EL layer 113G, and the EL layer 113B can be inhibited. When the EL layer 113 is irradiated with light (visible light or ultraviolet rays), the organic compound contained in the EL layer 113 is brought into an excited state and a reaction between the organic compound and oxygen in the atmosphere is promoted in some cases. Specifically, when the EL layer 113 is irradiated with light (visible light or ultraviolet rays) in an atmosphere containing oxygen, oxygen might be bonded to the organic compound contained in the EL layer 113. By providing the mask layer 118 and the insulating film 125f over the EL layer 113, bonding of oxygen in the atmosphere to the organic compound contained in the EL layer 113 can be inhibited.

Next, as illustrated in FIG. 13B1 and FIG. 13B2, development is performed to remove the region of the insulating film 127f exposed to light, so that an insulating layer 127a is formed. FIG. 13B2 is an enlarged view of the end portions of the EL layer 113G and the insulating layer 127a illustrated in FIG. 13B1 and their vicinity. The insulating layer 127a is formed in a region 133 positioned between the side surfaces of two adjacent EL layers 113. The insulating layer 127a is formed in a region surrounding the conductive layer 123. Here, when an acrylic resin is used for the insulating film 127f, a developer is preferably an alkaline solution and can be TMAH, for example. Note that development performed in forming the insulating layer 127a may be hereinafter referred to as first development.

Then, a residue (scum) due to the development may be removed. For example, the residue can be removed by ashing using oxygen plasma.

Etching may be performed so that the surface level of the insulating layer 127a is adjusted. The insulating layer 127a may be processed by ashing using oxygen plasma, for example.

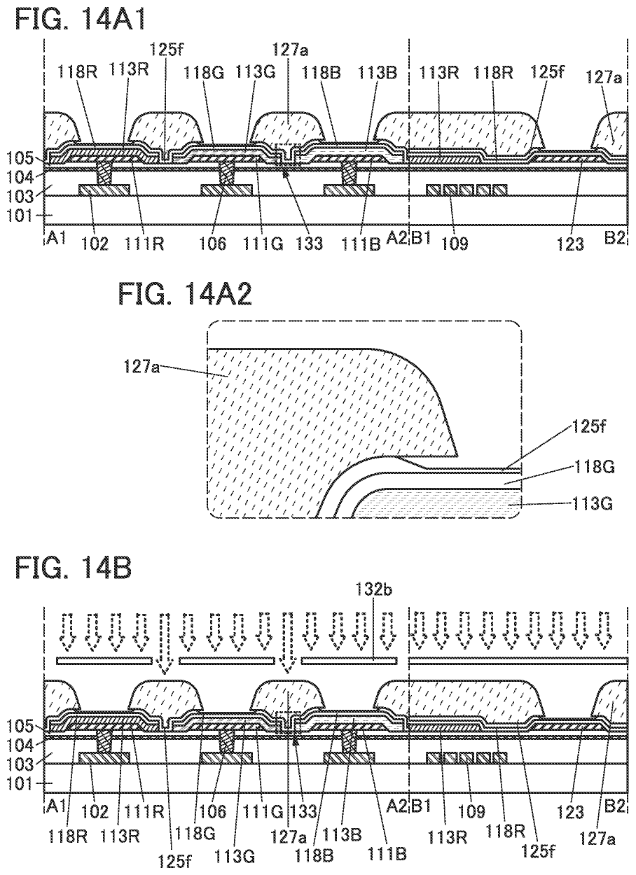

Next, as illustrated in FIG. 14A1 and FIG. 14A2, etching treatment is performed using the insulating layer 127a as a mask to reduce the thickness of part of the insulating film 125f. FIG. 14A2 is an enlarged view of the end portions of the EL layer 113G and the insulating layer 127a illustrated in FIG. 14A1 and their vicinity. Note that this etching treatment may be hereinafter referred to as first etching treatment.

The first etching treatment is performed by a wet etching method. Accordingly, damage to the EL layer 113 can be reduced as compared with the case where the first etching treatment is performed by a dry etching method. In the case where the first etching treatment is performed by a wet etching method, a chemical solution functioning as a developer can be used as an etchant. In that case, an alkaline solution is preferably used as an etchant, and TMAH can be used, for example. In other words, a chemical solution containing the same component as the developer used to perform development on the insulating film 127f can be used as an etchant in the first etching treatment. Note that the etchant used in the first etching treatment may be hereinafter referred to as a first chemical solution.

Note that although the thickness of part of the insulating film 125f is reduced and the thicknesses of the mask layer 118R, the mask layer 118G, and the mask layer 118B are not changed in FIG. 14A1 and FIG. 14A2, one embodiment of the present invention is not limited thereto. For example, part of the insulating film 125f is removed to expose the mask layer 118R, the mask layer 118G, and the mask layer 118B and the thicknesses of parts of the mask layer 118R, the mask layer 118G, and the mask layer 118B are reduced in some cases depending on the thickness of the insulating film 125f and the thicknesses of the mask layer 118R, the mask layer 118G, and the mask layer 118B. In the case where the insulating film 125f is formed using a material similar to that of the mask layer 118R, the mask layer 118G, and the mask layer 118B, the boundary between the insulating film 125f and the mask layers 118R, 118G, and 118B may be unclear; hence, whether the thicknesses of the mask layers 118R, 118G, and 118B are reduced cannot be determined in some cases.

Although FIG. 14A1 and FIG. 14A2 illustrate an example in which the shape of the insulating layer 127a is not changed from that in FIG. 13B1 and FIG. 13B2, the present invention is not limited thereto. For example, the end portion of the insulating layer 127a may droop to cover the end portion of the insulating film 125f. Moreover, for example, the end portion of the insulating layer 127a may be in contact with the top surface of the insulating film 125f in a position overlapping with the EL layer 113.

As illustrated in FIG. 14A2, etching is performed using the insulating layer 127a with a tapered side surface as a mask, so that the upper end portion of the side surface of the insulating film 125f can be tapered relatively easily.

Next, as illustrated in FIG. 14B, light exposure is performed to expose part of the insulating layer 127a to visible light or ultraviolet rays. In the case where a positive photosensitive resin composite is used for the insulating layer 127a, a region where the depressed portion 134 is formed in a later step is irradiated with visible light or ultraviolet rays using a mask 132b. Note that light exposure to the insulating layer 127a may be hereinafter referred to as second light exposure.

Light used for the second light exposure can be similar to that used for the first light exposure. For example, the light used for the second light exposure preferably includes i-line.

Here, the energy density of the second light exposure is set lower than that of the first light exposure. This can prevent the insulating layer 127a in the portion exposed to light from disappearing and the insulating layer 127a from being split in a later development step. For example, the energy density of the second light exposure is preferably less than or equal to ½, further preferably less than or equal to ⅓, still further preferably less than or equal to ¼ of the energy density of the first light exposure. Meanwhile, when the energy density of the second light exposure is too low, it is difficult to form the depressed portion 134 in the later development step. Therefore, the energy density of the second light exposure is preferably greater than or equal to 1/20, further preferably greater than or equal to 1/10, still further preferably greater than or equal to 1/7 of the energy density of the first light exposure.

In this specification and the like, the energy density of light exposure can be expressed by the product of power density of light used for exposure and light exposure time. Here, the unit of power density can be, for example, “W/m²” and the unit of energy density can be, for example, “J/m^{2”}.

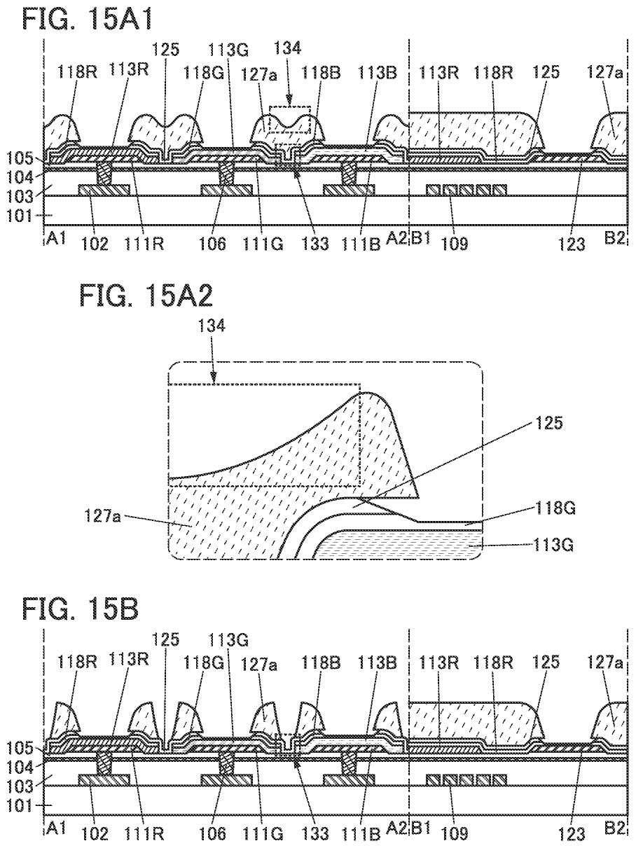

Next, as illustrated in FIG. 15A1 and FIG. 15A2, development is performed to reduce the thickness of the region of the insulating layer 127a exposed to light, so that the depressed portion 134 is formed. The depressed portion 134 is formed to include a region overlapping with the region 133 between two EL layers 113, for example. Etching treatment is performed using the insulating layer 127a as a mask to remove part of the insulating film 125f, so that the insulating layer 125 is formed and the thicknesses of parts of the mask layer 118R, the mask layer 118G, and the mask layer 118B are reduced. FIG. 15A2 is an enlarged view of the EL layer 113G, an end portion of the insulating layer 127a, and their vicinity, which are illustrated in FIG. 15A1. Development performed in forming the depressed portion 134 may be hereinafter referred to as second development. This etching treatment may be referred to as second etching treatment.

The depressed portion 134 is formed in the insulating layer 127a, whereby stress of the insulating layer 127a in the subsequent steps can be reduced. Accordingly, one or more of film separation between the EL layer 113 and the mask layer 118, film separation between the mask layer 118 and the insulating layer 125, and film separation between the insulating layer 125 and the insulating layer 127a can be inhibited. Thus, the manufacturing method of a display apparatus of one embodiment of the present invention can be a manufacturing method that can suppress generation of defects and achieve a high yield.

By using a chemical solution functioning as a developer as an etchant in the case where the second etching treatment is performed by a wet etching method, the second development and the second etching treatment can be performed in parallel. In other words, the second development and the second etching treatment can be performed at the same time or in the same step. An alkaline solution is preferably used as such a chemical solution, and TMAH can be used, for example. In other words, a chemical solution containing the same component as the chemical solution used in the first development and the first etching treatment can be used in the second development and the second etching treatment. Note that the chemical solution used in the second development and the second etching treatment may be hereinafter referred to as a second chemical solution.

In the case where the second development and the second etching treatment are performed in parallel, the second development time is equal to the second etching treatment time. Here, when the second etching time is increased, the second development time is increased, which may cause the insulating layer 127a in the position exposed to light in the second light exposure to disappear and the insulating layer 127a to be split as illustrated in FIG. 15B. Alternatively, the depressed portion 134 becomes deeper, which may cause defective connection due to breakage, an increase in electric resistance due to local thinning, or the like in the common layer 114 and the common electrode 115 to be formed in a later step.

In view of the above, in the method for manufacturing a display apparatus of one embodiment of the present invention, after the first etching treatment is performed to reduce the thickness of part of the insulating film 125f before light exposure to the insulating layer 127a (the second light exposure), the second light exposure is performed, and then the second development and the second etching treatment are performed in parallel. This can shorten the second development time and prevent the insulating layer 127a in the portion exposed to light in the second light exposure from disappearing and the insulating layer 127a from being split. Moreover, this can inhibit the depressed portion 134 from becoming deeper and defective connection due to breakage, an increase in electric resistance due to local thinning, or the like from being caused in the common layer 114 and the common electrode 115 to be formed in a later step. As described above, the manufacturing method of a display apparatus of one embodiment of the present invention can suppress generation of defects and achieve a high yield.

As illustrated in FIG. 15A2, etching is performed using the insulating layer 127a with a tapered side surface as a mask, so that the side surface of the insulating layer 125, the upper end portion of the side surface of the mask layer 118 can be tapered relatively easily.

As illustrated in FIGS. 15A1 and 15A2, the mask layer 118R, the mask layer 118G, and the mask layer 118B are not removed completely by the second etching treatment, and the etching treatment is stopped when the thickness of the mask layers is reduced. The corresponding mask layers 118R, 118G, and 118B are left over the EL layer 113R, the EL layer 113G, and the EL layer 113B in this manner, whereby the EL layer 113R, the EL layer 113G, and the EL layer 113B can be prevented from being damaged by processing in a later step.

Although the thickness of the mask layer 118R, the mask layer 118G, and the mask layer 118B is reduced in FIGS. 15A1 and 15A2, the present invention is not limited thereto. For example, depending on the thickness of the insulating film 125f and the thicknesses of the mask layer 118R, the mask layer 118G, and the mask layer 118B, the second etching treatment may be stopped before the insulating film 125f is processed into the insulating layer 125. Specifically, the second etching treatment may be stopped only after reducing the thickness of part of the insulating film 125f. In the case where the insulating film 125f is formed using the same material as the mask layer 118R, the mask layer 118G, and the mask layer 118B, the boundary between the insulating film 125f and the mask layers 118R, 118G, and 118B may become unclear. This may cause the case where whether the insulating layer 125 is formed cannot be determined and the case where whether the mask layer 118R, the mask layer 118G, and the mask layer 118B are reduced in thickness cannot be determined.

Although FIG. 15A1 and FIG. 15A2 illustrate an example in which the shape of the insulating layer 127a is not changed from that in FIG. 14A1 and FIG. 14A2, the present invention is not limited thereto. For example, the end portion of the insulating layer 127a may droop to cover the end portion of the insulating layer 125. As another example, the end portion of the insulating layer 127a may be in contact with the top surfaces of the mask layer 118R, the mask layer 118G, and the mask layer 118B.

Here, by providing a barrier insulating layer against oxygen (e.g., an aluminum oxide film) as the mask layer 118R, the mask layer 118G, and the mask layer 118B as described above, diffusion of oxygen to the EL layer 113R, the EL layer 113G, and the EL layer 113B can be suppressed.

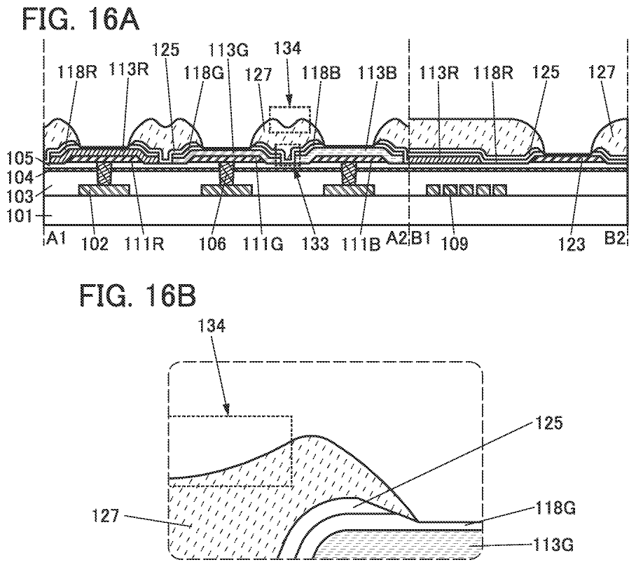

Then, heat treatment (also referred to as post-baking) is performed as illustrated in FIG. 16A and FIG. 16B. As illustrated in FIG. 16A and FIG. 16B, the insulating layer 127a can be changed into the insulating layer 127 having a tapered side surface by the heat treatment. In the case where a thermosetting resin is used for the insulating layer 127a, for example, the insulating layer 127a can be cured by the heat treatment.

Note that as described above, in some cases, the insulating layer 127a is already changed in shape and has a tapered side surface at the moment when the first etching treatment or the second etching treatment ends. The heat treatment is performed at a temperature lower than the upper temperature limit of the EL layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. The heat treatment is preferably performed in a reduced-pressure atmosphere, in which case drying can be performed at a lower temperature. The substrate temperature in the heat treatment of this step is preferably higher than that in the heat treatment (prebaking) after the formation of the insulating film 127f. Accordingly, adhesion between the insulating layer 127 and the insulating layer 125 can be improved, and corrosion resistance of the insulating layer 127 can be increased. FIG. 16B is an enlarged view of end portions of the EL layer 113G and the insulating layer 127 illustrated in FIG. 16A and their vicinity.

As described above, a material with high heat resistance is used for the light-emitting element of the display apparatus of one embodiment of the present invention. Therefore, the temperature of the prebaking and the temperature of the post-baking can each be higher than or equal to 100° C., higher than or equal to 120° C., or higher than or equal to 140° C. Thus, adhesion between the insulating layer 127 and the insulating layer 125 can be further improved, and the corrosion resistance of the insulating layer 127 can be further increased. Moreover, the range of choice for materials that can be used for the insulating layer 127 can be widened. By adequately removing a solvent included in the insulating layer 127, for example, entry of impurities such as water and oxygen into the EL layer can be suppressed.

When the mask layer 118R, the mask layer 118G, and the mask layer 118B are not completely removed by the second etching treatment and the thinned mask layers 118R, 118G, and 118B are left, the EL layer 113R, the EL layer 113G, and the EL layer 113B can be prevented from being damaged and deteriorating in the heat treatment. Thus, the reliability of the light-emitting element can be improved.

As illustrated in FIG. 5A and FIG. 5B, the side surface of the insulating layer 127 might have a concave shape depending on the materials for the insulating layer 127, or the temperature, time, and atmosphere of post-baking. For example, when the temperature of the post-baking is higher or the duration of the post-baking is longer, the shape of the insulating layer 127 is more likely to change and thus a concave shape may be more likely to be formed.

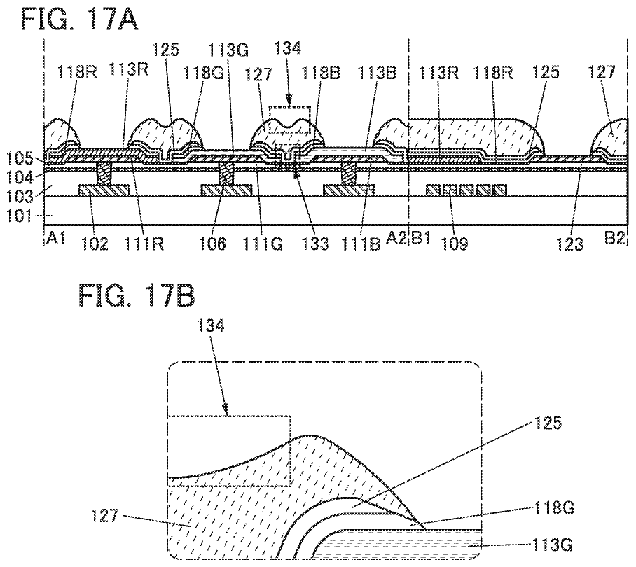

Next, as illustrated in FIG. 17A and FIG. 17B, etching treatment is performed using the insulating layer 127 as a mask to remove part of the mask layer 118R, the mask layer 118G, and the mask layer 118B. Note that part of the insulating layer 125 is also removed in some cases. Thus, openings are formed in the mask layer 118R, the mask layer 118G, and the mask layer 118B, and the top surfaces of the EL layer 113R, the EL layer 113G, and the EL layer 113B and the conductive layer 123 are exposed. FIG. 17B is an enlarged view of the end portions of the EL layer 113G and the insulating layer 127 illustrated in FIG. 17A and their vicinity. The etching treatment using the insulating layer 127 as a mask may be hereinafter referred to as third etching treatment.

The end portion of the insulating layer 125 is covered with the insulating layer 127. FIG. 17A and FIG. 17B illustrate an example where part of the end portion of the mask layer 118G (specifically, a tapered portion formed by the second etching treatment) is covered with the insulating layer 127 and the tapered portion formed by the third etching treatment is exposed. That is, the structure in FIG. 17A and FIG. 17B correspond to the structure in FIG. 3A and FIG. 3B.

Note that as illustrated in FIG. 4A and FIG. 4B, or FIG. 6A and FIG. 6B, the insulating layer 127 may cover the entire end portion of the mask layer 118G. For example, the end portion of the insulating layer 127 may droop to cover the end portion of the mask layer 118G. As another example, the end portion of the insulating layer 127 may be in contact with the top surface of at least one of the EL layer 113R, the EL layer 113G, and the EL layer 113B.

The third etching treatment is performed by wet etching. The use of a wet etching method enables damage to the EL layer 113R, the EL layer 113G, and the EL layer 113B to be reduced as compared with the case where a dry etching method is used. In the case where the third etching treatment is performed by a wet etching method, a chemical solution functioning as a developer can be used as an etchant. In that case, an alkaline solution is preferably used as an etchant, and TMAH can be used, for example. In other words, a chemical solution containing the same component as the developer used to perform development on the insulating film 127f can be used as an etchant in the third etching treatment. Note that the etchant used in the third etching treatment may be hereinafter referred to as a third chemical solution.

As described above, in the method for manufacturing a display apparatus of one embodiment of the present invention, the first chemical solution used in the first etching treatment performed after formation of the insulating layer 127a and before formation of the depressed portion 134, the second chemical solution used in the second etching treatment performed in parallel with formation of the depressed portion 134, and the third chemical solution used in the third etching treatment can each function as a developer. Therefore, the first to third chemical solutions can contain the same components.

Here, the insulating layer 127 is cured by the post-baking and thus is not processed even when a developer is used as the third chemical solution. Therefore, the post-baking treatment can prevent the depressed portion 134 in the insulating layer 127 from becoming deeper by the third etching treatment, for example.

As described above, by providing the insulating layer 127, the insulating layer 125, the mask layer 118R, the mask layer 118G, and the mask layer 118B, defective connection due to split portions and an increase in electric resistance due to locally thinned portions can be prevented from being caused in the common layer 114 and the common electrode 115 in different light-emitting elements. Consequently, the display apparatus of one embodiment of the present invention can have improved display quality.

Heat treatment may be performed after the EL layer 113R, the EL layer 113G, and the EL layer 113B are partly exposed. By the heat treatment, water contained in the EL layer 113 and water adsorbed on the surface of the EL layer 113, for example, can be removed. The shape of the insulating layer 127 may be changed by the heat treatment. Specifically, the insulating layer 127 may be widened to cover at least one of the end portion of the insulating layer 125, the end portions of the mask layers 118R, 118G, and 118B, and the top surfaces of the EL layers 113R, 113G, and 113B. For example, the insulating layer 127 may have the shape illustrated in FIG. 4A and FIG. 4B. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case dehydration at a lower temperature is possible. Note that the temperature range of the heat treatment is preferably set as appropriate also in consideration of the upper temperature limit of the EL layer 113. In consideration of the upper temperature limit of the EL layer 113, a temperature higher than or equal to 70° C. and lower than or equal to 120° C. is particularly preferable in the above temperature ranges.

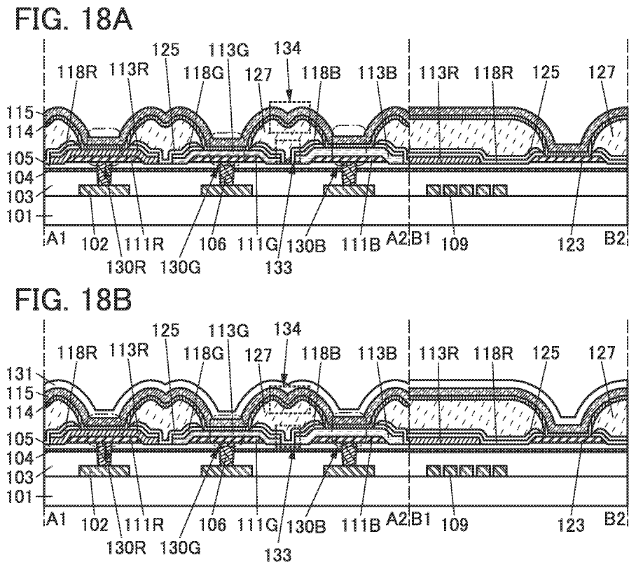

Next, as illustrated in FIG. 18A, the common layer 114 is formed over the EL layers 113R, 113G, and 113B, the conductive layer 123, and the insulating layer 127. The common layer 114 can be formed by an evaporation method (including a vacuum evaporation method), a transfer method, a printing method, an inkjet method, a coating method, or the like.

Then, as illustrated in FIG. 18A, the common electrode 115 is formed over the common layer 114. The common electrode 115 can be formed by a sputtering method, a vacuum evaporation method, or the like. Alternatively, the common electrode 115 may be formed by stacking a film formed by an evaporation method and a film formed by a sputtering method.

The common electrode 115 can be formed continuously after the formation of the common layer 114, without a step such as etching intervening therebetween. For example, after the common layer 114 is formed in a vacuum, the common electrode 115 can be formed in a vacuum without exposing the substrate to the air. In other words, the common layer 114 and the common electrode 115 can be successively formed in a vacuum. Accordingly, the bottom surface of the common electrode 115 can be a clean surface, as compared with the case where the common layer 114 is not provided in the display apparatus 100. Thus, the light-emitting element 130 can have high reliability and favorable characteristics.

Next, the protective layer 131 is formed over the common electrode 115 as illustrated in FIG. 18B. The protective layer 131 can be formed by a vacuum evaporation method, a sputtering method, a CVD method, an ALD method, or the like.

Then, the substrate 120 is attached to the protective layer 131 using the resin layer 122, whereby the display apparatus having the structure illustrated in FIG. 2 and the structure illustrated in FIG. 7A can be manufactured.

As described above, in the method for manufacturing a display apparatus of one embodiment of the present invention, the depressed portion 134 is formed in the insulating layer 127a. Accordingly, one or more of separation between the EL layer 113 and the mask layer 118, separation between the mask layer 118 and the insulating layer 125, and separation between the insulating layer 125 and the insulating layer 127a can be inhibited.

In the method for manufacturing a display apparatus of one embodiment of the present invention, the first etching treatment is performed to reduce the thickness of part of the insulating film 125f before the second light exposure performed to form the depressed portion 134, the second light exposure is performed, and then the second development and the second etching treatment are performed in parallel. By performing the first etching treatment, the time for the second development, which is a step of forming the depressed portion 134, can be shortened and the insulating layer 127a in the portion exposed to light in the second light exposure can be prevented from disappearing and the insulating layer 127a can be prevented from being split. Moreover, the depressed portion 134 can be inhibited from becoming deeper and defective connection due to breakage, an increase in electric resistance due to local thinning, or the like can be inhibited from being caused in the common layer 114 and the common electrode 115 to be formed in a later step.

As described above, the manufacturing method of a display apparatus of one embodiment of the present invention can suppress generation of defects and achieve a high yield.

In the method for manufacturing a display apparatus of one embodiment of the present invention, the EL layer 113R, the EL layer 113G, and the EL layer 113B are formed not by using a fine metal mask but by processing a film deposited over an entire surface; thus, the island-shaped layers can be formed to have a uniform thickness. Moreover, a high-resolution display apparatus or a display apparatus with a high aperture ratio can be obtained. Furthermore, even when the resolution or the aperture ratio is high and the distance between the subpixels is extremely short, the EL layer 113R, the EL layer 113G, and the EL layer 113B can be prevented from being in contact with each other in the adjacent subpixels. As a result, generation of leakage current between the subpixels can be inhibited. This can prevent crosstalk due to unintended light emission, so that a display apparatus with extremely high contrast can be obtained.

In addition, the insulating layer 127 having a tapered end portion is provided between adjacent EL layers 113, whereby breakage can be inhibited from being caused at the time of forming the common electrode 115 and a locally thinned portion can be prevented from being formed in the common electrode 115. Accordingly, defective connection due to a split portion and an increase in electric resistance due to a locally thinned portion can be inhibited from being caused in the common layer 114 and the common electrode 115. Consequently, the display apparatus of one embodiment of the present invention achieves both high resolution and high display quality.

### [Manufacturing Method Example 2]

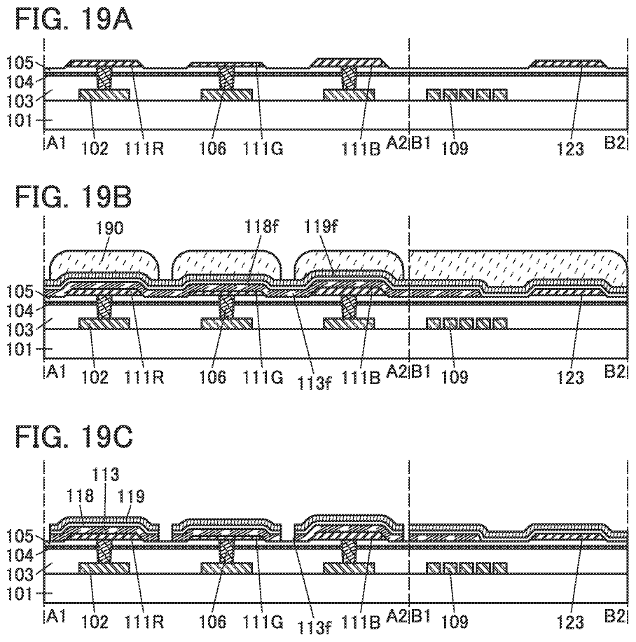

An example of a method for manufacturing the display apparatus 100 having the structure illustrated in FIG. 8A and the structure illustrated in FIG. 7A will be described below with reference to FIG. 19A to FIG. 19C. FIG. 19A to FIG. 19C each illustrate a cross section along the dashed-dotted line A1-A2 and a cross section along the dashed-dotted line B1-B2 in FIG. 1. Note that steps different from those in the method described with FIG. 10A to FIG. 18B will be mainly described, and the description of the same steps as those in the method described with FIG. 10A to FIG. 18B will be omitted as appropriate.

First, steps similar to those illustrated in FIG. 10A and FIG. 10B are performed. Thus, as illustrated in FIG. 19A, the pixel electrode 111R, the pixel electrode 111G, the pixel electrode 111B, and the conductive layer 123 are formed over the plugs 106 and the insulating layer 105. Here, deposition of a conductive film that is a step similar to that illustrated in FIG. 10A and patterning that is a step similar to that illustrated in FIG. 10B are performed repeatedly, whereby the thicknesses of the pixel electrode 111R, the pixel electrode 111G, and the pixel electrode 111B can be different from each other. For example, by performing a step including deposition of a conductive film and patterning three times, the thicknesses of the pixel electrode 111R, the pixel electrode 111G, and the pixel electrode 111B can be different from each other.

Next, as illustrated in FIG. 19B, an EL film 113f to be the EL layer 113 is formed over the pixel electrode 111R, the pixel electrode 111G, the pixel electrode 111B, and the insulating layer 105. Then, a mask film 118f to be the mask layer 118 and a mask film 119f to be a mask layer 119 are sequentially formed over the EL film 113f, the conductive layer 123, and the insulating layer 105.

Next, as illustrated in FIG. 19B, a resist mask 190 is formed over the mask film 119f. The resist mask 190 is provided at a position overlapping with the pixel electrode 111R, a position overlapping with the pixel electrode 111G, and a position overlapping with the pixel electrode 111B. The resist mask 190 is preferably provided also at a position overlapping with the conductive layer 123. Furthermore, the resist mask 190 is preferably provided to cover the area from the end portion of the EL film 113f to the end portion of the conductive layer 123 (the end portion on the EL film 113f side), as illustrated in the cross-sectional view along the line B1-B2 in FIG. 19B.

Subsequently, as illustrated in FIG. 19C, part of the mask film 119f is removed using the resist mask 190, whereby the mask layer 119 is formed. The mask layer 119 remains over the pixel electrode 111R, the pixel electrode 111G, the pixel electrode 111B, and the conductive layer 123. After that, the resist mask 190 is removed. Then, part of the mask film 118f is removed using the mask layer 119 as a mask (also referred to as a hard mask), whereby the mask layer 118 is formed.

Next, as illustrated in FIG. 19C, the EL film 113f is processed, whereby the EL layer 113 is formed. For example, part of the EL film 113f is removed using the mask layer 119 and the mask layer 118 as a hard mask, whereby the EL layer 113 is formed.

Accordingly, as illustrated in FIG. 19C, the stacked-layer structure of the EL layer 113, the mask layer 118, and the mask layer 119 remains over the pixel electrode 111R, the pixel electrode 111G, and the pixel electrode 111B. In addition, in the cross section B1-B2, the mask layer 118 and the mask layer 119 can be provided to cover the area from the end portion of the EL layer 113 to the end portion of the conductive layer 123 (the end portion on the EL layer 113 side).

Next, steps similar to those illustrated in FIG. 12A to FIG. 18B are performed. Note that the protective layer 131 can be planarized. Then, the coloring layer 132R, the coloring layer 132G, and the coloring layer 132B are formed over the protective layer 131. Subsequently, the substrate 120 is attached to the coloring layer 132 using the resin layer 122, whereby the display apparatus having the structure illustrated in FIG. 8A and the structure illustrated in FIG. 7A can be manufactured.

As described above, in the display apparatus 100 having the structure illustrated in FIG. 8A, the EL film 113f, the mask film 118f, and the mask film 119f can each be completed by one formation step and one processing step, and do not need to be formed and processed separately for each color. Thus, the manufacturing process of the display apparatus 100 can be simplified. This can reduce the manufacturing costs of the display apparatus 100 and make the display apparatus 100 inexpensive.

This embodiment can be combined with the other embodiments as appropriate. In this specification, in the case where a plurality of structure examples are described in one embodiment, the structure examples can be combined as appropriate.

### Embodiment 2

In this embodiment, examples of pixel layouts of a display apparatus of one embodiment of the present invention will be described.

There is no particular limitation on the arrangement of the subpixels 110 included in the display apparatus 100 that is a display apparatus of one embodiment of the present invention; a variety of methods can be employed. Examples of the arrangement of the subpixels 110 include stripe arrangement, S-stripe arrangement, matrix arrangement, delta arrangement, Bayer arrangement, and PenTile arrangement.

Examples of the top surface shape of the subpixel 110 include polygons such as a triangle, a tetragon (including a rectangle and a square), and a pentagon; polygons with rounded corners; an ellipse; and a circle. Here, the top surface shape of the subpixel 110 corresponds to the top surface shape of a light-emitting region of the light-emitting element 130.

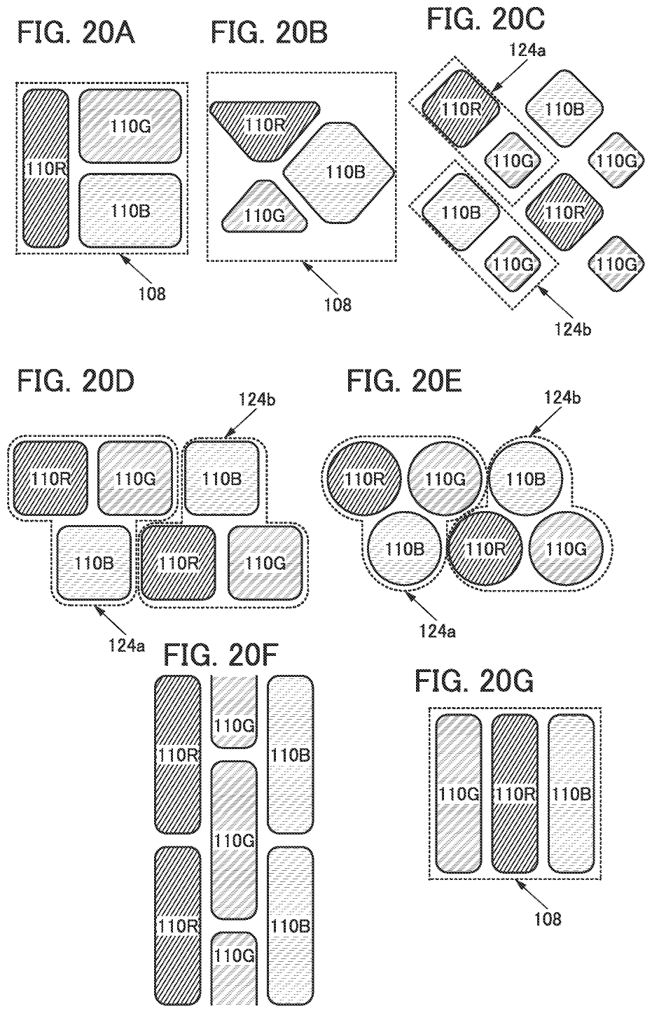

The pixel 108 illustrated in FIG. 20A employs S-stripe arrangement. The pixel 108 illustrated in FIG. 20A consists of three subpixels: the subpixel 110R, the subpixel 110G, and the subpixel 110B.

The pixel 108 illustrated in FIG. 20B includes the subpixel 110R whose top surface has a rough trapezoidal shape with rounded corners, the subpixel 110G whose top surface has a rough triangle shape with rounded corners, and the subpixel 110B whose top surface has a rough tetragonal or rough hexagonal shape with rounded corners. The subpixel 110R has a larger light-emitting area than the subpixel 110G. In this manner, the shapes and sizes of the subpixels can be determined independently. For example, the size of a subpixel including a light-emitting element with higher reliability can be smaller.

A pixel 124a and a pixel 124b illustrated in FIG. 20C employ PenTile arrangement. FIG. 20C illustrates an example in which the pixels 124a each including the subpixel 110R and the subpixel 110G and the pixels 124b each including the subpixel 110G and the subpixel 110B are alternately arranged.

The pixel 124a and the pixel 124b illustrated in FIG. 20D and FIG. 20E employ delta arrangement. The pixel 124a includes two subpixels (the subpixel 110R and the subpixel 110G) in the upper row (first row) and one subpixel (the subpixel 110B) in the lower row (second row). The pixel 124b includes one subpixel (the subpixel 110B) in the upper row (first row) and two subpixels (the subpixel 110R and the subpixel 110G) in the lower row (second row).

FIG. 20D illustrates an example where the top surface of each subpixel has a rough tetragonal shape with rounded corners, and FIG. 20E illustrates an example where the top surface of each subpixel has a circular shape.

FIG. 20F illustrates an example where subpixels of different colors are arranged in a zigzag manner. Specifically, the positions of the top sides of two subpixels arranged in the column direction (e.g., the subpixel 110R and the subpixel 110G or the subpixel 110G and the subpixel 110B) are not aligned in the plan view.

In photolithography, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

Furthermore, in the method for manufacturing a display apparatus of one embodiment of the present invention, the EL layer is processed with the use of a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape by processing. As a result, the top surface of the EL layer may have a polygonal shape with rounded corners, an elliptical shape, a circular shape, or the like. For example, when a resist mask whose top surface has a square shape is intended to be formed, a resist mask whose top surface has a circular shape may be formed, and the top surface of the EL layer may be a circular shape.

Note that to obtain a desired top surface shape of the EL layer, a technique of correcting a mask pattern in advance so that a transferred pattern agrees with a design pattern (OPC (Optical Proximity Correction) technique) may be used. Specifically, with the OPC technique, a pattern for correction is added to a corner portion of a figure on a mask pattern, for example.

Note that the arrangement order of the subpixels is not particularly limited either in the pixel 108 employing stripe arrangement illustrated in FIG. 1; for example, the subpixel 110G, the subpixel 110R, and the subpixel 110B may be arranged in this order as illustrated in FIG. 20G.

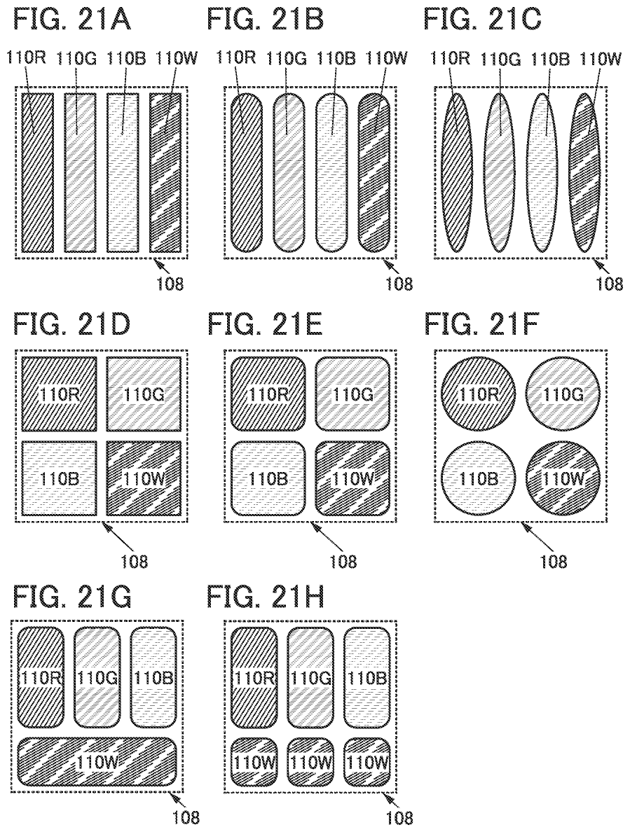

As illustrated in FIG. 21A to FIG. 21H, the pixel 108 can include a subpixel 110W in addition to the subpixel 110R, the subpixel 110G, and the subpixel 110B. Here, the subpixel 110W can exhibit white.

The pixels 108 illustrated in FIG. 21A to FIG. 21C each employ stripe arrangement.

FIG. 21A illustrates an example where each subpixel has a rectangular top surface shape, FIG. 21B illustrates an example where each subpixel has a top surface shape formed by combining two half circles and a rectangle, and FIG. 21C illustrates an example where each subpixel has an elliptical top surface shape.

The pixels 108 illustrated in FIG. 21D to FIG. 21F employ matrix arrangement.

FIG. 21D illustrates an example where each subpixel has a square top surface shape, FIG. 21E illustrates an example where each subpixel has a substantially square top surface shape with rounded corners, and FIG. 21F illustrates an example where each subpixel has a circular top surface shape.

FIG. 21G and FIG. 21H each illustrate an example where one pixel 108 consists of two rows and three columns.

The pixel 108 illustrated in FIG. 21G includes three subpixels (the subpixel 110R, the subpixel 110G, and the subpixel 110B) in the upper row (first row) and one subpixel (the subpixel 110W) in the lower row (second row). In other words, the pixel 108 includes the subpixel 110R in the left column (first column), the subpixel 110G in the center column (second column), the subpixel 110B in the right column (third column), and the subpixel 110W across these three columns.

The pixel 108 illustrated in FIG. 21H includes three subpixels (the subpixel 110R, the subpixel 110G, and the subpixel 110B) in the upper row (first row) and three subpixels 110W in the lower row (second row). In other words, the pixel 108 includes the subpixel 110R and the subpixel 110W in the left column (first column), the subpixel 110G and the subpixel 110W in the center column (second column), and the subpixel 110B and the subpixel 110W in the right column (third column). Matching the positions of the subpixels in the upper row and the lower row as illustrated in FIG. 21H enables dust that would be produced in the manufacturing process, for example, to be removed efficiently. Thus, a display apparatus with high display quality can be provided.

The pixel 108 illustrated in FIG. 21A to FIG. 21H consists of four subpixels: the subpixel 110R, the subpixel 110G, the subpixel 110B, and the subpixel 110W. The subpixel 110R, the subpixel 110G, the subpixel 110B, and the subpixel 110W include light-emitting elements emitting light of different colors.

As described above, the pixel composed of the subpixels each including the light-emitting element can employ any of a variety of layouts in the display apparatus of one embodiment of the present invention.

This embodiment can be combined with the other embodiments as appropriate. In this specification, in the case where a plurality of structure examples are described in one embodiment, the structure examples can be combined as appropriate.

### Embodiment 3

In this embodiment, a display apparatus of one embodiment of the present invention will be described.

The display apparatus in this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display apparatus in this embodiment can be a high-definition display apparatus or a large-sized display apparatus. Accordingly, the display apparatus of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer or the like, digital signage, and a large game machine such as a pachinko machine.

### [Display Module]

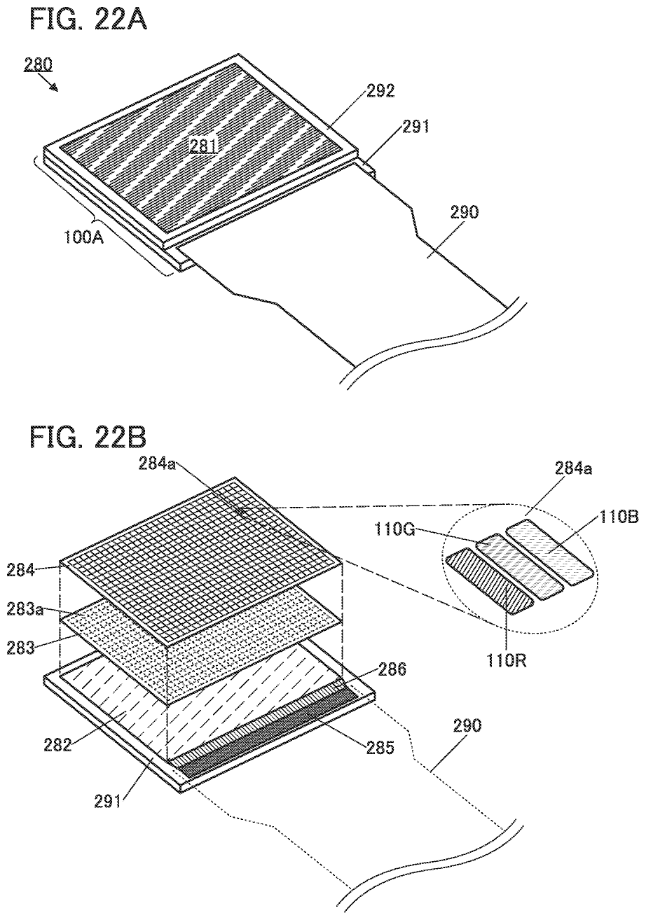

FIG. 22A is a perspective view of a display module 280. The display module 280 includes a display apparatus 100A and an FPC 290. Note that the display apparatus included in the display module 280 is not limited to the display apparatus 100A and may be any of a display apparatus 100B to a display apparatus 100F described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 22B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 22B. The pixel 284a can employ any of the structures described in the above embodiments. FIG. 22B illustrates an example where the pixel 284a has the same structure as the pixel 108 illustrated in FIG. 1.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each of which controls light emission of one light-emitting element. For example, the pixel circuit 283a can include at least one selection transistor, one current control transistor (driving transistor), and a capacitor for one light-emitting element. In that case, a gate signal is input to a gate of the selection transistor, and a video signal is input to a source or a drain of the selection transistor. Thus, an active-matrix display apparatus is achieved.

The circuit portion 282 includes a circuit for driving the pixel circuits 283a in the pixel circuit portion 283. For example, one or both of a scan line driver circuit and a signal line driver circuit are preferably included. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as an HMD or a glasses-type AR device. For example, even with a structure in which the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device such as a wrist watch.

### [Display Apparatus 100A]

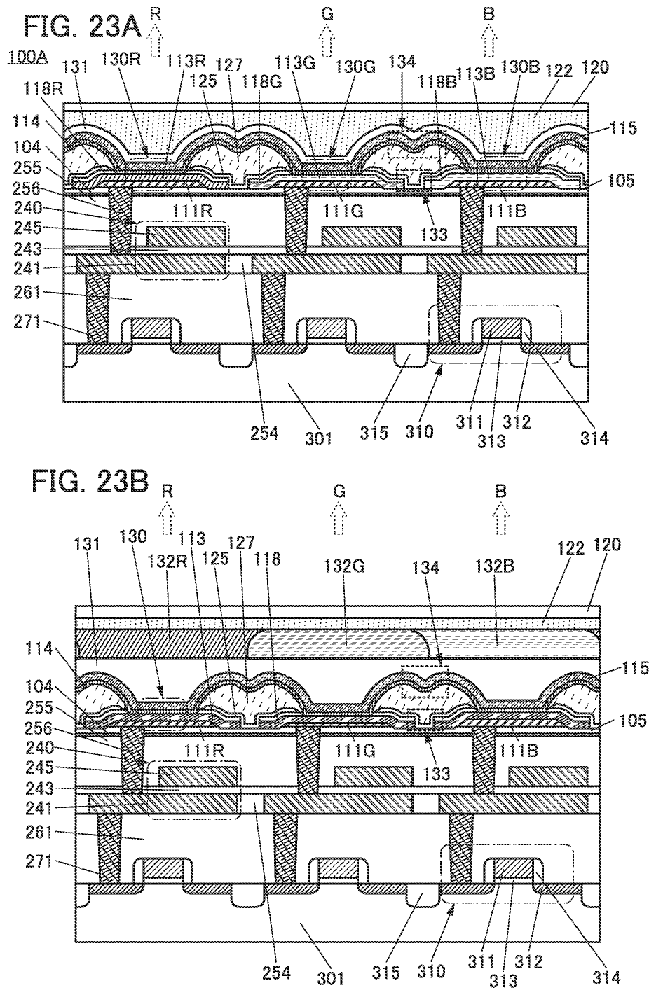

The display apparatus 100A illustrated in FIG. 23A includes a substrate 301, the light-emitting element 130R, the light-emitting element 130G, the light-emitting element 130B, a capacitor 240, and a transistor 310.

The substrate 301 corresponds to the substrate 291 illustrated in FIG. 22A and FIG. 22B. The transistor 310 includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance regions 312 are regions where the substrate 301 is doped with an impurity, and function as a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240; the insulating layer 104 is provided over the insulating layer 255; the insulating layer 105 is provided over the insulating layer 104. The light-emitting element 130R, the light-emitting element 130G, and the light-emitting element 130B are provided over the insulating layer 105. FIG. 23A illustrates an example in which the light-emitting element 130R, the light-emitting element 130G, and the light-emitting element 130B each have the stacked-layer structure illustrated in FIG. 2. An insulator is provided in a region between adjacent light-emitting elements. For example, in FIG. 23A, the insulating layer 125 and the insulating layer 127 over the insulating layer 125 are provided in this region.

The mask layer 118R is positioned over the EL layer 113R included in the light-emitting element 130R; the mask layer 118G is positioned over the EL layer 113G included in the light-emitting element 130G; the mask layer 118B is positioned over the EL layer 113B included in the light-emitting element 130B.

The pixel electrode 111R, the pixel electrode 111G, and the pixel electrode 111B are each electrically connected to one of the source and the drain of the transistor 310 through a plug 256 embedded in the insulating layer 243, the insulating layer 255, the insulating layer 104, and the insulating layer 105, the conductive layer 241 embedded in the insulating layer 254, and the plug 271 embedded in the insulating layer 261. The top surface of the insulating layer 105 and the top surface of the plug 256 are level with or substantially level with each other. A variety of conductive materials can be used for the plugs.

The protective layer 131 is provided over the light-emitting element 130R, the light-emitting element 130G, and the light-emitting element 130B. The substrate 120 is bonded to the protective layer 131 with the resin layer 122. Embodiment 1 can be referred to for details of the light-emitting element 130 and the components thereover up to the substrate 120. The substrate 120 corresponds to the substrate 292 in FIG. 22A.

FIG. 23B is a variation example of the display apparatus 100A illustrated in FIG. 23A. The display apparatus illustrated in FIG. 23B includes the coloring layer 132R, the coloring layer 132G, and the coloring layer 132B, and each of the light-emitting elements 130 includes a region overlapping with one of the coloring layer 132R, the coloring layer 132G, and the coloring layer 132B. FIG. 8A can be referred to for details of the insulating layer 104 and the components thereover up to the substrate 120 in the display apparatus illustrated in FIG. 23B. In the display apparatus illustrated in FIG. 23B, the light-emitting element 130 can emit white light, for example. For example, the coloring layer 132R can transmit red light, the coloring layer 132G can transmit green light, and the coloring layer 132B can transmit blue light.

### [Display Apparatus 100B]

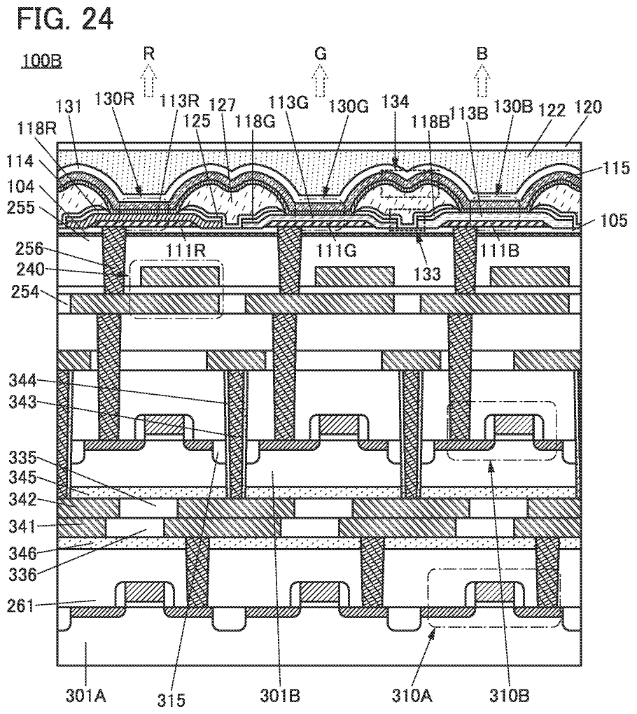

The display apparatus 100B illustrated in FIG. 24 has a structure where a transistor 310A and a transistor 310B in each of which a channel is formed in a semiconductor substrate are stacked. Note that in the description of the display apparatus below, portions similar to those of the above-mentioned display apparatus are not described in some cases.

In the display apparatus 100B, a substrate 301B provided with the transistor 310B, the capacitor 240, and light-emitting elements is bonded to a substrate 301A provided with the transistor 310A.

Here, an insulating layer 345 is preferably provided on the bottom surface of the substrate 301B. An insulating layer 346 is preferably provided over the insulating layer 261 over the substrate 301A. The insulating layer 345 and the insulating layer 346 function as protective layers and can inhibit diffusion of impurities into the substrate 301B and the substrate 301A. As the insulating layer 345 and the insulating layer 346, an inorganic insulating film that can be used as the protective layer 131 can be used.

The substrate 301B is provided with a plug 343 that penetrates the substrate 301B and the insulating layer 345. An insulating layer 344 is preferably provided to cover the side surface of the plug 343. The insulating layer 344 functions as a protective layer and can inhibit diffusion of impurities into the substrate 301B. As the insulating layer 344, an inorganic insulating film that can be used as the protective layer 131 can be used.

A conductive layer 342 is provided under the insulating layer 345 on the rear surface of the substrate 301B (the surface on the substrate 301A side). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

A conductive layer 341 is provided over the insulating layer 346 between the substrate 301A and the substrate 301B. The conductive layer 341 is preferably provided to be embedded in the insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 341 and the conductive layer 342. In that case, it is possible to employ Cu—Cu (copper-to-copper) direct bonding (a technique for achieving electrical continuity by connecting Cu (copper) pads).

### [Display Apparatus 100C]

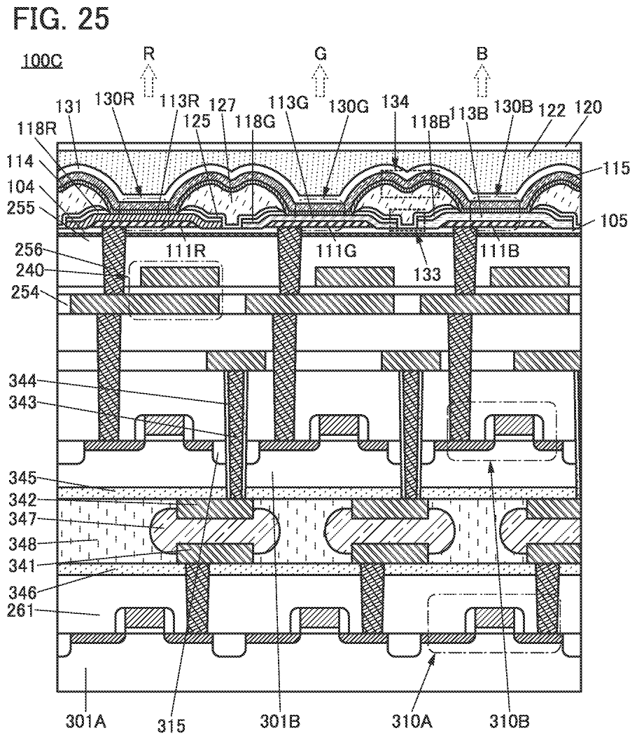

The display apparatus 100C illustrated in FIG. 25 has a structure in which the conductive layer 341 and the conductive layer 342 are bonded to each other through a bump 347.

As illustrated in FIG. 25, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Apparatus 100D]

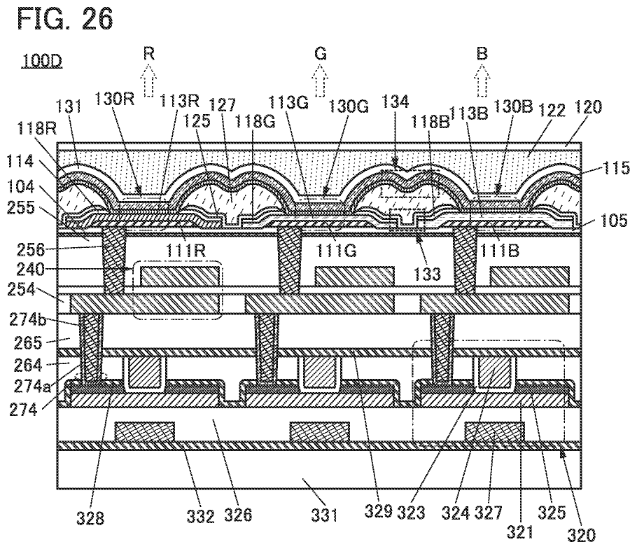

A display apparatus 100D illustrated in FIG. 26 differs from the display apparatus 100A mainly in a structure of a transistor.

A transistor 320 is a transistor (OS transistor) that contains a metal oxide (also referred to as an oxide semiconductor) in its semiconductor layer where a channel is formed.

The transistor 320 includes a semiconductor layer 321, an insulating layer 323, a conductive layer 324, a pair of conductive layers 325, an insulating layer 326, and a conductive layer 327.

The substrate 331 corresponds to the substrate 291 in FIG. 22A and FIG. 22B. As the substrate 331, an insulating substrate or a semiconductor substrate can be used.

The insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film through which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. A metal oxide film having semiconductor characteristics is preferably used as the semiconductor layer 321. The pair of conductive layers 325 is provided on and in contact with the semiconductor layer 321 and functions as a source electrode and a drain electrode.

An insulating layer 328 is provided to cover the top surfaces and the side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from, for example, the insulating layer 264 into the semiconductor layer 321 and release of oxygen from the semiconductor layer 321. As the insulating layer 328, an insulating film similar to the above insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level or substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from, for example, the insulating layer 265 into the transistor 320. For the insulating layer 329, an insulating film similar to the above insulating layer 328 and the above insulating layer 332 can be used.

A plug 274 electrically connected to one of the pair of conductive layers 325 is provided to be embedded in the insulating layer 265, the insulating layer 329, the insulating layer 264, and the insulating layer 328. Here, the plug 274 preferably includes a conductive layer 274a that covers the side surface of an opening formed in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material in which hydrogen and oxygen are less likely to be diffused is preferably used.

### [Display Apparatus 100E]

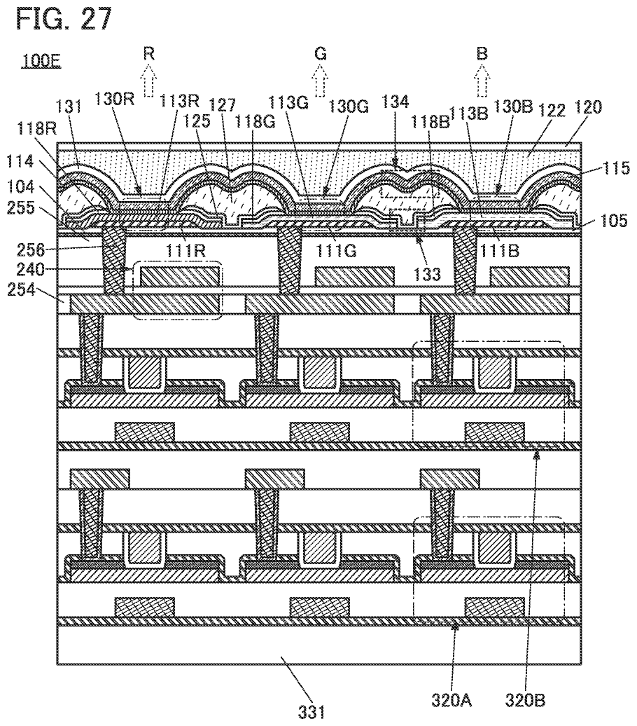

A display apparatus 100E illustrated in FIG. 27 has a structure in which a transistor 320A and a transistor 320B each including an oxide semiconductor in a semiconductor where a channel is formed are stacked.

The above display apparatus 100D can be referred to for the transistor 320A, the transistor 320B, and other peripheral structures.

Although the structure where two transistors including an oxide semiconductor are stacked is described, one embodiment of the present invention is not limited thereto. For example, three or more transistors may be stacked.

### [Display Apparatus 100F]

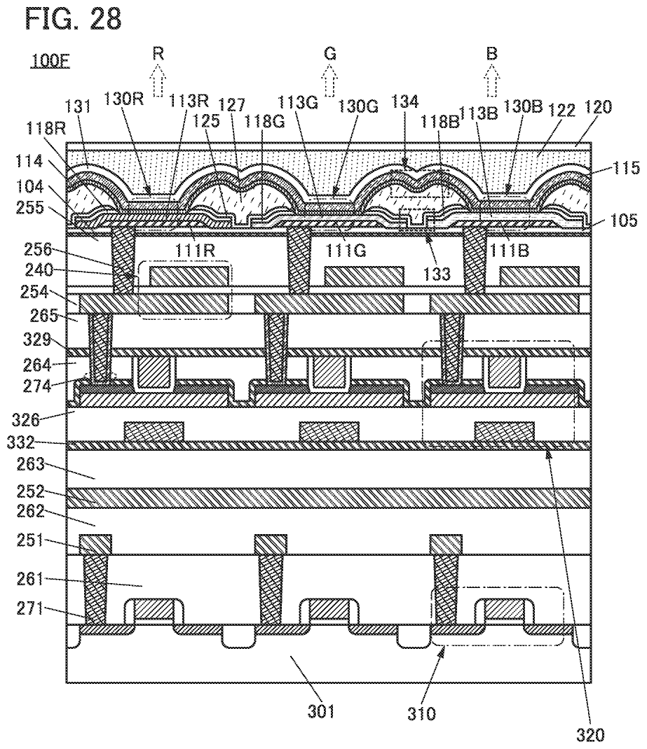

The display apparatus 100F illustrated in FIG. 28 has a structure in which the transistor 310 whose channel is formed in the substrate 301 and the transistor 320 including a metal oxide in a semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in a pixel circuit. In addition, the transistor 310 can be used as a transistor included in a pixel circuit or a transistor included in a driver circuit for driving the pixel circuit (a scan line driver circuit and a signal line driver circuit). Furthermore, the transistor 310 and the transistor 320 can be used as transistors included in a variety of circuits such as an arithmetic circuit and a memory circuit.

With such a structure, not only the pixel circuit but also, for example, the driver circuit can be formed directly under the light-emitting element; thus, the display apparatus can be downsized as compared with the case where the driver circuit is provided around a display region.

### [Display Apparatus 100G]

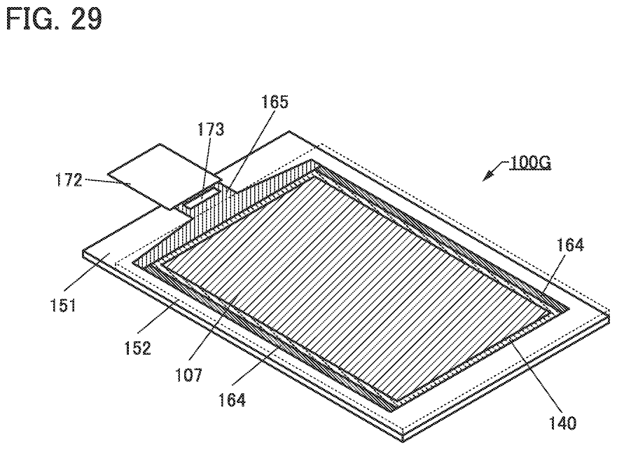

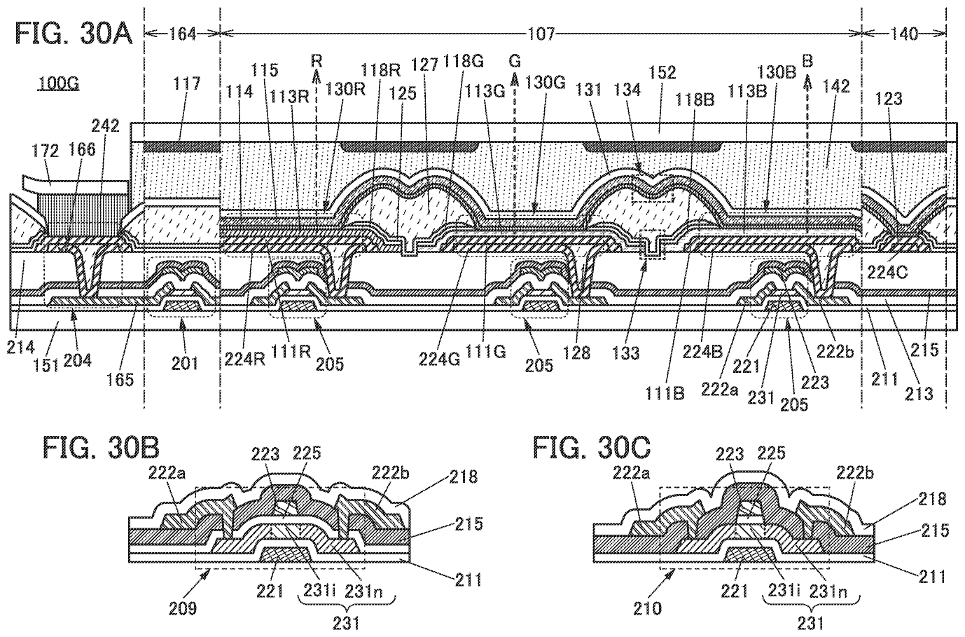

FIG. 29 is a perspective view of a display apparatus 100G, and FIG. 30A is a cross-sectional view of the display apparatus 100G.

In the display apparatus 100G, a substrate 152 and a substrate 151 are bonded to each other. In FIG. 29, the substrate 152 is denoted by a dashed line.

The display apparatus 100G includes the pixel portion 107, the connection portion 140, a circuit 164, a wiring 165, and the like. FIG. 29 illustrates an example where an IC 173 and an FPC 172 are mounted on the display apparatus 100G. Thus, the structure illustrated in FIG. 29 can be regarded as a display module including the display apparatus 100G, the IC (integrated circuit), and the FPC. Here, a display apparatus in which a substrate is equipped with a connector such as an FPC or mounted with an IC is referred to as a display module.

The connection portion 140 is provided outside the pixel portion 107. The connection portion 140 can be provided along one or more sides of the display portion 107. The number of the connection portions 140 may be one or more. FIG. 29 illustrates an example where the connection portion 140 is provided to surround the four sides of the pixel portion 107. A common electrode of a light-emitting element is electrically connected to a conductive layer in the connection portion 140, so that a potential can be supplied to the common electrode.

As the circuit 164, a scan line driver circuit can be used, for example.

The wiring 165 has a function of supplying a signal and electric power to the pixel portion 107 and the circuit 164. The signal and electric power are input to the wiring 165 from the outside through the FPC 172 or from the IC 173.

FIG. 29 illustrates an example where the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display apparatus 100G and the display module are not necessarily provided with an IC. The IC may be mounted on the FPC by a COF method, for example.

FIG. 30A illustrates an example of cross sections of part of a region including the FPC 172, part of the circuit 164, part of the pixel portion 107, part of the connection portion 140, and part of a region including an end portion of the display apparatus 100G.

The display apparatus 100G illustrated in FIG. 30A includes a transistor 201, a transistor 205, the light-emitting element 130R emitting red light, the light-emitting element 130G emitting green light, the light-emitting element 130B emitting blue light, and the like between the substrate 151 and the substrate 152.

The light-emitting element 130R, the light-emitting element 130G, and the light-emitting element 130B each have the same structure as the stacked-layer structure illustrated in FIG. 2 except for the structure of the pixel electrode. Embodiment 1 can be referred to for details of the light-emitting element.

The light-emitting element 130R includes a conductive layer 224R and a pixel electrode 111R over the conductive layer 224R. The light-emitting element 130G includes a conductive layer 224G and a pixel electrode 111G over the conductive layer 224G. The light-emitting element 130B includes a conductive layer 224B and a pixel electrode 111B over the conductive layer 224B. Note that the conductive layer 224R, the conductive layer 224G, and the conductive layer 224B, as well as the pixel electrode 111R, the pixel electrode 111G, and the pixel electrode 111B, can be referred to as pixel electrodes.

The conductive layer 224R is connected to a conductive layer 222b included in the transistor 205 through an opening provided in an insulating layer 214, an insulating layer 215, and an insulating layer 213. The end portion of the pixel electrode 111R is positioned on the outer side of the end portion of the conductive layer 224R.

The conductive layer 224G and the pixel electrode 111G in the light-emitting element 130G and the conductive layer 224B and the pixel electrode 111B in the light-emitting element 130B are similar to the conductive layer 224R and the pixel electrode 111R in the light-emitting element 130R, and thus will not be described in detail.

The conductive layer 224R, the conductive layer 224G, and the conductive layer 224B each have a depressed portion so as to cover an opening provided in the insulating layer 214. A layer 128 is embedded in the depressed portion.

The layer 128 has a function of filling the depressed portions of the conductive layer 224R, the conductive layer 224G, and the conductive layer 224B for planarization. Over the conductive layer 224R, the conductive layer 224G, the conductive layer 224B, and the layer 128, the pixel electrode 111R, the pixel electrode 111G, and the pixel electrode 111B that are electrically connected to the conductive layer 224R, the conductive layer 224G, and the conductive layer 224B, respectively are provided. Thus, regions overlapping with the depressed portions of the conductive layer 224R, the conductive layer 224G, and the conductive layer 224B can also be used as light-emitting regions, increasing the pixel aperture ratio.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 127 can be used, for example.

The protective layer 131 is provided over the light-emitting element 130R, the light-emitting element 130G, and the light-emitting element 130B. The protective layer 131 and the substrate 152 are bonded to each other with an adhesive layer 142. The substrate 152 is provided with a light-blocking layer 117. A solid sealing structure, a hollow sealing structure, or the like can be employed to seal the light-emitting element 130. In FIG. 30A, a solid sealing structure is employed in which a space between the substrate 152 and the substrate 151 is filled with the adhesive layer 142. Alternatively, a hollow sealing structure in which the space is filled with an inert gas (e.g., nitrogen or argon) may be employed. In that case, the adhesive layer 142 may be provided not to overlap with the light-emitting element. The space may be filled with a resin other than the frame-shaped adhesive layer 142.

FIG. 30A illustrates an example in which the connection portion 140 includes a conductive layer 224C obtained by processing the same conductive film as the conductive layer 224R, the conductive layer 224G, and the conductive layer 224B and the conductive layer 123 obtained by processing the same conductive film as the pixel electrode 111R, the pixel electrode 111G, and the pixel electrode 111B.

The display apparatus 100G has a top-emission structure. Light emitted from the light-emitting element is emitted toward the substrate 152 side. For the substrate 152, a material having a high visible-light-transmitting property is preferably used. The pixel electrode contains a material that reflects visible light, and the counter electrode (the common electrode 115) contains a material that transmits visible light.

The transistor 201 and the transistor 205 are formed over the substrate 151. These transistors can be manufactured using the same material in the same step.

An insulating layer 211, the insulating layer 213, the insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers that cover the transistors. Such a structure can effectively inhibit diffusion of impurities into the transistors from the outside and improve the reliability of the display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, an aluminum nitride film, or the like can be used. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably functions as an etching protective layer. This can inhibit formation of a depressed portion in the insulating layer 214 at the time of processing of the conductive layer 224R, the pixel electrode 111R, or the like. Alternatively, as illustrated in FIG. 30A, a depressed portion may be provided in the insulating layer 214 at the time of processing of the conductive layer 224R, the pixel electrode 111R, or the like.

Each of the transistor 201 and the transistor 205 includes a conductive layer 221 functioning as a gate, the insulating layer 211 functioning as a gate insulating layer, a conductive layer 222a and a conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. In addition, the transistor structure may be either a top-gate structure or a bottom-gate structure. Alternatively, gates may be provided above and below a semiconductor layer in which a channel is formed.

The structure in which the semiconductor layer where a channel is formed is provided between two gates is used for the transistor 201 and the transistor 205. The two gates may be connected to each other and supplied with the same signal to drive the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

It is preferable that a semiconductor layer of a transistor contain a metal oxide. That is, a transistor including a metal oxide in its channel formation region (hereinafter, also referred to as an OS transistor) is preferably used for the display apparatus of this embodiment.

Examples of an oxide semiconductor having crystallinity include a CAAC (c-axis-aligned crystalline)-OS and an nc (nanocrystalline)-OS.

Alternatively, a transistor using silicon in a channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of a Si transistors such as an LTPS transistor, a circuit required to be driven at a high frequency (e.g., a source driver circuit) can be formed on the same substrate as the display portion. This allows simplification of an external circuit mounted on the display apparatus and a reduction in costs of parts and mounting costs.

An OS transistor has much higher field-effect mobility than a transistor containing amorphous silicon. In addition, an OS transistor has an extremely low leakage current between a source and a drain in an off state (hereinafter, also referred to as off-state current), and charge accumulated in a capacitor that is connected in series to the transistor can be retained for a long period. Furthermore, the power consumption of the display apparatus can be reduced with the OS transistor.

To increase the emission luminance of the light-emitting element included in the pixel circuit, the amount of current flowing through the light-emitting element needs to be increased. For that purpose, the source-drain voltage of a driving transistor included in the pixel circuit needs to be increased. Since an OS transistor has a higher withstand voltage between the source and the drain than a Si transistor, a high voltage can be applied between the source and the drain of an OS transistor. Accordingly, when an OS transistor is used as the driving transistor included in the pixel circuit, the amount of current flowing through the light-emitting element can be increased, so that the emission luminance of the light-emitting element can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting element can be controlled. Consequently, the number of gray levels expressed by the pixel circuit can be increased.

Regarding saturation characteristics of current flowing when a transistor operates in a saturation region, even in the case where the source-drain voltage of an OS transistor increases gradually, more stable constant current (saturation current) can be fed through an OS transistor than through a Si transistor. Thus, by using an OS transistor as the driving transistor, a stable current can be fed through light-emitting elements even when the current-voltage characteristics of the organic EL elements vary, for example. In other words, when an OS transistor operates in a saturation region, the source-drain current hardly changes with an increase in the source-drain voltage; hence, the emission luminance of the light-emitting element can be stable.

As described above, by using an OS transistor as the driving transistor included in the pixel circuit, it is possible to achieve “inhibition of black floating”, “increase in emission luminance”, “increase in gray level”, “inhibition of variation in characteristics of light-emitting devices”, and the like.

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. In particular, M is preferably one or more kinds selected from aluminum, gallium, yttrium, and tin.

It is particularly preferable that an oxide containing indium (In), gallium (Ga), and zinc (Zn) (also referred to as IGZO) be used as the semiconductor layer. Alternatively, it is preferable to use an oxide containing indium, tin, and zinc. Further alternatively, it is preferable to use an oxide containing indium, gallium, tin, and zinc. Alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO).

When the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where the atomic ratio of Ga is greater than or equal to 1 and less than or equal to 3 and the atomic ratio of Zn is greater than or equal to 2 and less than or equal to 4 with the atomic ratio of In being 4. When the atomic ratio is described as In:Ga:Zn=5:1:6 or a composition in the neighborhood thereof, the case is included where the atomic ratio of Ga is greater than 0.1 and less than or equal to 2 and the atomic ratio of Zn is greater than or equal to 5 and less than or equal to 7 with the atomic ratio of In being 5. When the atomic ratio is described as In:Ga:Zn=1:1:1 or a composition in the neighborhood thereof, the case is included where the atomic ratio of Ga is greater than 0.1 and less than or equal to 2 and the atomic ratio of Zn is greater than 0.1 and less than or equal to 2 with the atomic ratio of In being 1.

The transistors included in the circuit 164 and the transistors included in the pixel portion 107 may have the same structure or different structures. One structure or two or more kinds of structures may be employed for a plurality of transistors included in the circuit 164. Similarly, a plurality of transistors included in the pixel portion 107 may have the same structure or two or more kinds of structures.

All of the transistors included in the pixel circuit portion 107 may be OS transistors or all of the transistors included in the pixel circuit portion 107 may be Si transistors; alternatively, some of the transistors included in the pixel circuit portion 107 may be OS transistors and the others may be Si transistors.

For example, when both an LTPS transistor and an OS transistor are used in the pixel portion 107, the display apparatus with low power consumption and high drive capability can be achieved. A structure where an LTPS transistor and an OS transistor are used in combination is referred to as LTPO in some cases. For example, it is preferable that an OS transistor be used as a transistor functioning as a switch for controlling electrical continuity between wirings and an LTPS transistor be used as a transistor for controlling current.

For example, one transistor included in the pixel portion 107 functions as a transistor for controlling current flowing through the light-emitting element and can also be referred to as a driving transistor. One of a source and a drain of the driving transistor is electrically connected to the pixel electrode of the light-emitting element. An LTPS transistor is preferably used as the driving transistor. In that case, the amount of current flowing through the light-emitting element can be increased in the pixel circuit.

Another transistor included in the pixel circuit portion 107 functions as a switch for controlling selection and non-selection of the pixel and can be referred to as a selection transistor. A gate of the selection transistor is electrically connected to a gate line, and one of a source and a drain thereof is electrically connected to a signal line. An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

As described above, the display apparatus of one embodiment of the present invention can have all of a high aperture ratio, high resolution, high display quality, and low power consumption.

The display apparatus of one embodiment of the present invention has a structure including the OS transistor and the light-emitting element having an MML (metal maskless) structure. This structure can significantly reduce a leakage current that would flow through a transistor and a leakage current that would flow between adjacent light-emitting elements (sometimes referred to as a horizontal-direction leakage, a horizontal leakage current, or a lateral leakage current). In addition, with this structure, a viewer can notice any one or more of image crispness, image sharpness, a high chroma, and a high contrast ratio in an image displayed on the display apparatus. Note that with the structure where the leakage current that would flow through the transistor and the lateral leakage current that would flow between light-emitting elements are extremely low, display with little leakage of light at the time of black display (what is called black floating) can be achieved.

In particular, in the case where a light-emitting element having an MML structure employs the above-described SBS structure, a layer provided between light-emitting elements is split; accordingly, lateral leakage current can be prevented or made extremely low

FIG. 30B and FIG. 30C illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 30B illustrates an example of the transistor 209 where the insulating layer 225 covers the top and side surfaces of the semiconductor layer 231. The conductive layer 222a and the conductive layer 222b are connected to the corresponding low-resistance regions 231n through openings provided in the insulating layer 225 and the insulating layer 215. One of the conductive layer 222a and the conductive layer 222b functions as a source, and the other functions as a drain.

In the transistor 210 illustrated in FIG. 30C, the insulating layer 225 overlaps with the channel formation region 231i of the semiconductor layer 231 and does not overlap with the low-resistance regions 231n. The structure illustrated in FIG. 30C can be formed by processing the insulating layer 225 using the conductive layer 223 as a mask, for example. In FIG. 30C, the insulating layer 215 is provided to cover the insulating layer 225 and the conductive layer 223, and the conductive layer 222a and the conductive layer 222b are connected to the corresponding low-resistance regions 231n through the openings in the insulating layer 215.

A connection portion 204 is provided in a region of the substrate 151 that does not overlap with the substrate 152. In the connection portion 204, the wiring 165 is electrically connected to the FPC 172 through a conductive layer 166 and a connection layer 242. An example is described in which the conductive layer 166 has a stacked-layer structure of a conductive film obtained by processing the same conductive film as the conductive layer 224R, the conductive layer 224G, and the conductive layer 224B and a conductive film obtained by processing the same conductive film as the pixel electrode 111R, the pixel electrode 111G, and the pixel electrode 111B. On the top surface of the connection portion 204, the conductive layer 166 is exposed. Thus, the connection portion 204 and the FPC 172 can be electrically connected to each other through the connection layer 242.

A light-blocking layer 117 is preferably provided on the surface of the substrate 152 on the substrate 151 side. The light-blocking layer 117 can be provided between adjacent light-emitting elements, in the connection portion 140, and in the circuit 164, for example. A variety of optical members can be arranged on the outer surface of the substrate 152.

The material that can be used for the substrate 120 can be used for each of the substrate 151 and the substrate 152.

The material that can be used for the resin layer 122 can be used for the adhesive layer 142.

As the connection layer 242, an anisotropic conductive film (ACF), an anisotropic conductive paste (ACP), or the like can be used.

### [Display Apparatus 100H]

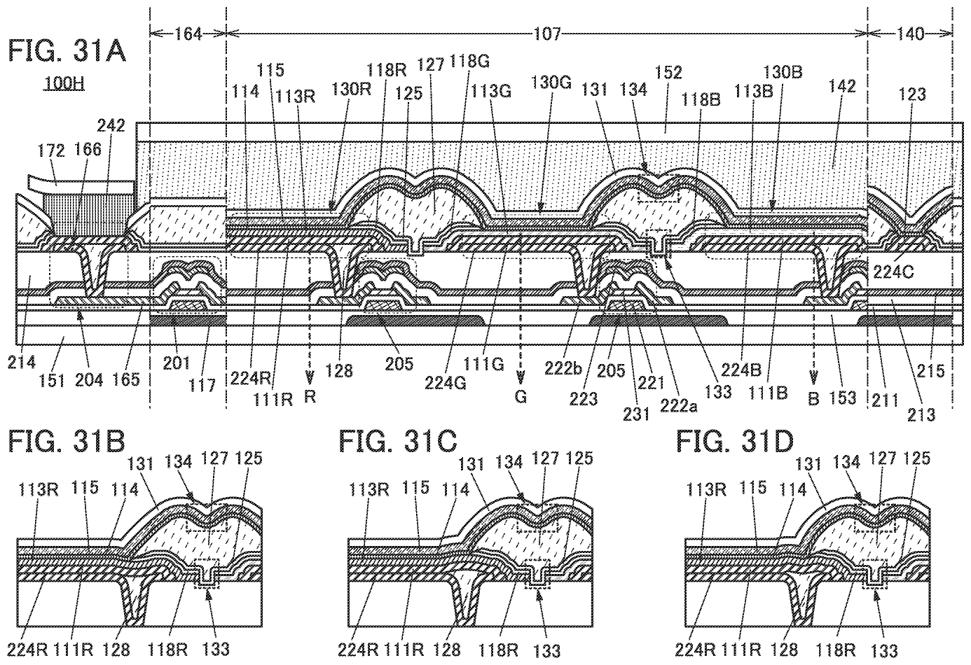

A display apparatus 100H illustrated in FIG. 31A is a variation example of the display apparatus 100G illustrated in FIG. 30A and differs from the display apparatus 100G mainly in being a bottom-emission display apparatus.

Light emitted from the light-emitting element 130 is emitted toward the substrate 151 side. For the substrate 151, a material having a high visible-light-transmitting property is preferably used. By contrast, there is no limitation on the light-transmitting property of a material used for the substrate 152.

The light-blocking layer 117 is preferably provided between the substrate 151 and the transistor 201 and between the substrate 151 and the transistor 205. FIG. 31A illustrates an example in which the light-blocking layer 117 is provided over the substrate 151, an insulating layer 153 is provided over the light-blocking layer 117, and the transistor 201, the transistor 205, and the like are provided over the insulating layer 153.

A material having a high visible-light-transmitting property is used for each of the conductive layer 224R, the conductive layer 224G, the conductive layer 224B, the pixel electrode 111R, the pixel electrode 111G, and the pixel electrode 111B. By contract, a material reflecting visible light is preferably used for the common electrode 115.

Although FIG. 30A, FIG. 31A, and the like illustrate an example where the top surface of the layer 128 includes a flat portion, the shape of the layer 128 is not particularly limited. FIG. 31B to FIG. 31D illustrate variation examples of the layer 128.

As illustrated in FIG. 31B and FIG. 31D, the top surface of the layer 128 can have a shape in which its center and the vicinity thereof are depressed, i.e., a shape including a concave surface, in a cross-sectional view.

As illustrated in FIG. 31C, the top surface of the layer 128 can have a shape in which its center and the vicinity thereof bulge, i.e., a shape including a convex surface, in a cross-sectional view.

The top surface of the layer 128 may include one or both of a convex surface and a concave surface. The number of convex surfaces and the number of concave surfaces included in the top surface of the layer 128 are not limited and can each be one or more.

The level of the top surface of the layer 128 and the level of the top surface of the conductive layer 224R, for example, may be the same or substantially the same, or may be different from each other. For example, the level of the top surface of the layer 128 may be either lower or higher than the level of the top surface of the conductive layer 224R.

FIG. 31B can be regarded as illustrating an example in which the layer 128 fits in the depressed portion of the conductive layer 224R. By contrast, as illustrated in FIG. 31D, the layer 128 may exist also outside the depressed portion of the conductive layer 224R, i.e., the top surface of the layer 128 may extend beyond the depressed portion.

### [Display Apparatus 100I]

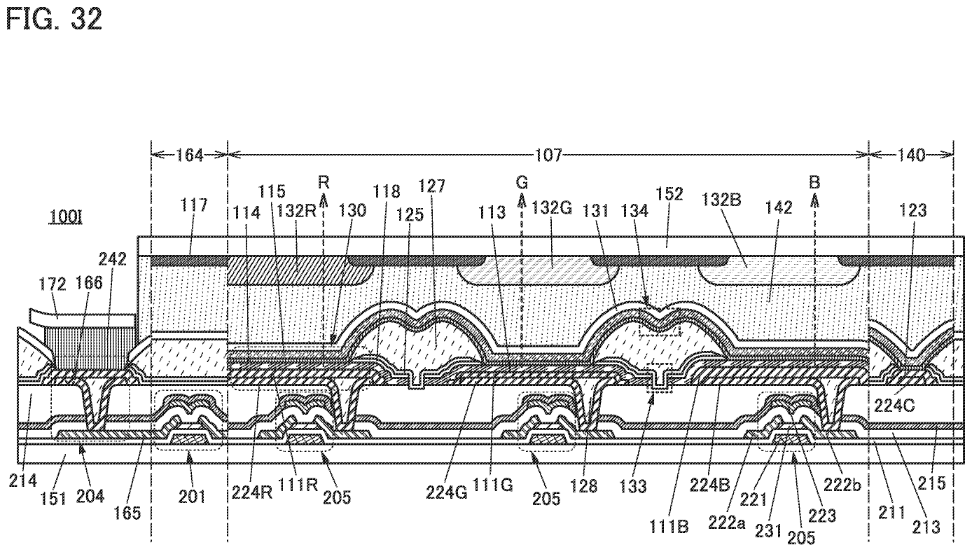

The display apparatus 100I illustrated in FIG. 32 is a variation example of the display apparatus 100G illustrated in FIG. 30A and differs from the display apparatus 100G mainly in including the coloring layer 132R, the coloring layer 132G, and the coloring layer 132B.

In the display apparatus 100I, the light-emitting element 130 includes a region that overlaps with one of the coloring layer 132R, the coloring layer 132G, and the coloring layer 132B. The coloring layer 132R, the coloring layer 132G, and the coloring layer 132B can be provided on a surface of the substrate 152 on the substrate 151 side. The end portions of the coloring layer 132R, the coloring layer 132G, and the coloring layer 132B can overlap with the light-blocking layer 117. Regarding the display apparatus 100I, FIG. 8A can be referred to for the details of the structure of the light-emitting element 130, for example.

In the display apparatus 100I, the light-emitting element 130 can emit white light, for example. For example, the coloring layer 132R can transmit red light, the coloring layer 132G can transmit green light, and the coloring layer 132B can transmit blue light. Note that in the display apparatus 100I, the coloring layer 132R, the coloring layer 132G, and the coloring layer 132B may be provided between the protective layer 131 and the adhesive layer 142. In that case, the protective layer 131 is preferably planarized as illustrated in FIG. 8A.

### [Display Apparatus 100J]

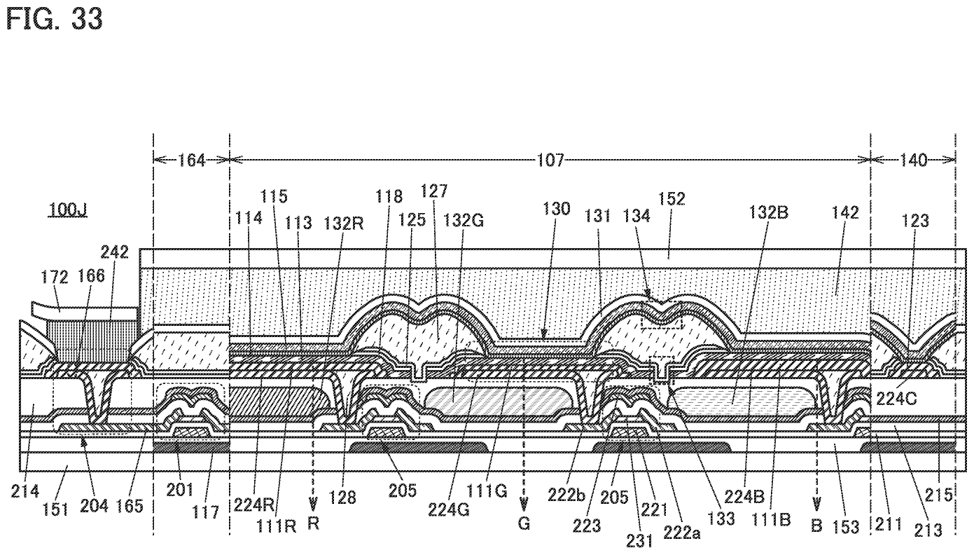

A display apparatus 100J illustrated in FIG. 33 is a variation example of the display apparatus 100I illustrated in FIG. 32 and differs from the display apparatus 100I mainly in being a bottom-emission display apparatus.

Light emitted from the light-emitting element 130 is emitted to the substrate 151 side as in the case of the display apparatus 100H illustrated in FIG. 31A. For the substrate 151, a material having a high visible-light-transmitting property is preferably used. By contrast, there is no limitation on the light-transmitting property of a material used for the substrate 152.

The coloring layer 132 is provided between the light-emitting element 130 and the substrate 151. FIG. 33 illustrates an example in which the coloring layer 132R, the coloring layer 132G, and the coloring layer 132B are provided between the insulating layer 215 and the insulating layer 214.

As in the display apparatus 100H illustrated in FIG. 31A, the light-blocking layer 117 is preferably provided between the substrate 151 and the transistor 201 and between the substrate 151 and the transistor 205. FIG. 33 illustrates an example in which the light-blocking layer 117 is provided over the substrate 151, the insulating layer 153 is provided over the light-blocking layer 117, and the transistor 201, the transistor 205, and the like are provided over the insulating layer 153.

Furthermore, as in the display apparatus 100H illustrated in FIG. 31A, a material having a high visible-light-transmitting property is used for each of the conductive layer 224R, the conductive layer 224G, the conductive layer 224B, the pixel electrode 111R, the pixel electrode 111G, and the pixel electrode 111B. By contract, a material reflecting visible light is preferably used for the common electrode 115.

This embodiment can be combined with the other embodiments as appropriate. In this specification, in the case where a plurality of structure examples are described in one embodiment, the structure examples can be combined as appropriate.

### Embodiment 4

In this embodiment, light-emitting elements that can be used in the display apparatus of one embodiment of the present invention will be described.

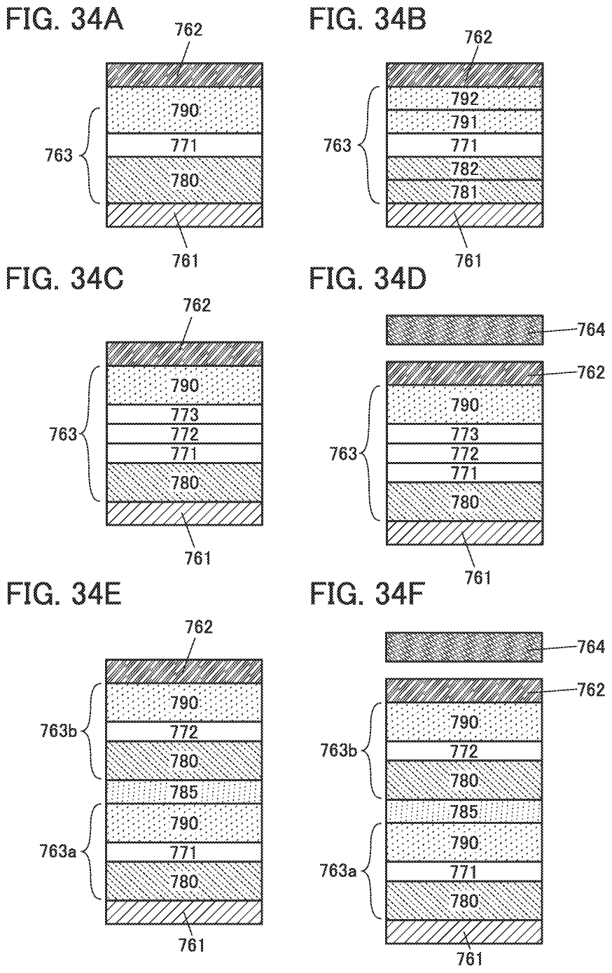

As illustrated in FIG. 34A, a light-emitting element includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance.

In the case where the lower electrode 761 is an anode and the upper electrode 762 is a cathode, the layer 780 includes one or more of a layer containing a substance with a high hole-injection property (a hole-injection layer), a layer containing a substance with a high hole-transport property (a hole-transport layer), and a layer containing a substance with a high electron-blocking property (an electron-blocking layer). The layer 790 includes one or more of a layer containing a substance with a high electron-injection property (an electron-injection layer), a layer containing a substance with a high electron-transport property (an electron-transport layer), and a layer containing a substance with a high hole-blocking property (a hole-blocking layer). In the case where the lower electrode 761 is a cathode and the upper electrode 762 is an anode, the structures of the layer 780 and the layer 790 are interchanged.

The structure including the layer 780, the light-emitting layer 771, and the layer 790, which are provided between a pair of electrodes, can function as a single light-emitting unit, and the structure in FIG. 34A is referred to as a single structure in this specification.

FIG. 34B is a variation example of the EL layer 763 included in the light-emitting element illustrated in FIG. 34A. Specifically, the light-emitting element illustrated in FIG. 34B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be enhanced.

Note that the structures in which a plurality of light-emitting layers (light-emitting layers 771, 772, and 773) are provided between the layer 780 and the layer 790 as illustrated in FIG. 34C and FIG. 34D are variations of the single structure.

A structure in which a plurality of light-emitting units (an EL layer 763a and an EL layer 763b) are connected in series with a charge-generation layer 785 therebetween as illustrated in FIG. 34E and FIG. 34F is referred to as a tandem structure in this specification. Note that the tandem structure may be referred to as a stack structure. Note that the tandem structure enables a light-emitting element to emit light at high luminance.

In FIG. 34C and FIG. 34D, light-emitting substances that emit light of the same color or the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. A color conversion layer may be provided as a layer 764 illustrated in FIG. 34D.

Alternatively, light-emitting substances that emit light of different colors may be used for the light-emitting layer 771, the light-emitting layer 772, and the light-emitting layer 773. White light can be obtained when the light-emitting layer 771, the light-emitting layer 772, and the light-emitting layer 773 emit light of complementary colors. A color filter (also referred to as a coloring layer) may be provided as the layer 764 illustrated in FIG. 34D. When white light passes through the color filter, light of a desired color can be obtained.

A light-emitting element that emits white light preferably includes two or more light-emitting layers. For example, to obtain white light emission by using two light-emitting layers, the two light-emitting layers are selected such that the light-emitting layers emit light of complementary colors. For example, when an emission color of a first light-emitting layer and an emission color of a second light-emitting layer are complementary colors, the light-emitting element can be configured to emit white light as a whole. To obtain white light emission by using three or more light-emitting layers, the light-emitting element is configured to emit white light as a whole by combining emission colors of the three or more light-emitting layers.

In FIG. 34E and FIG. 34F, light-emitting substances that emit light of the same color or the same light-emitting substance may be used for the light-emitting layer 771 and the light-emitting layer 772. Alternatively, light-emitting substances that emit light of different colors may be used for the light-emitting layer 771 and the light-emitting layer 772. White light can be obtained when the light-emitting layer 771 and the light-emitting layer 772 emit light of complementary colors. FIG. 34F illustrates an example in which the layer 764 is further provided. One or both of a color conversion layer and a color filter (coloring layer) can be used as the layer 764.

In FIG. 34C, FIG. 34D, FIG. 34E, and FIG. 34F, the layer 780 and the layer 790 may independently have a stacked-layer structure of two or more layers as illustrated in FIG. 34B.

Next, materials that can be used for the light-emitting element are described.

A conductive film transmitting visible light is used for the electrode through which light is extracted, which is either the lower electrode 761 or the upper electrode 762. A conductive film that reflects visible light is preferably used as the electrode through which light is not extracted. In the case where a display apparatus includes a light-emitting element that emits infrared light, a conductive film that transmits visible light and infrared light is used as the electrode through which light is extracted, and a conductive film that reflects visible light and infrared light is preferably used as the electrode through which light is not extracted.

A conductive film that transmits visible light may be used also for the electrode through which light is not extracted. In that case, the electrode is preferably provided between a reflective layer and the EL layer 763. In other words, light emitted from the EL layer 763 may be reflected by the reflective layer to be extracted from the display apparatus.

As the material of the pair of electrodes of the light-emitting element, a metal, an alloy, an electrically conductive compound, a mixture thereof, and the like can be used as appropriate. Specific examples include an indium tin oxide (In—Sn oxide, also referred to as ITO), an In—Si—Sn oxide (also referred to as ITSO), an indium zinc oxide (In—Zn oxide), an In—W—Zn oxide, an alloy containing aluminum (an aluminum alloy) such as an alloy of aluminum, nickel, and lanthanum (Al—Ni—La), and an alloy containing silver such as an alloy of silver and magnesium and an alloy of silver, palladium, and copper (Ag—Pd—Cu, also referred to as APC). In addition, it is possible to use a metal such as aluminum (Al), magnesium, titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 of the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these, graphene, or the like.

The light-emitting element preferably employs a microcavity structure. Therefore, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The light transmittance of the transparent electrode is greater than or equal to 40%. For example, an electrode having a visible light (light with a wavelength greater than or equal to 400 nm and less than 750 nm) transmittance higher than or equal to 40% is preferably used in the light-emitting elements. The transflective electrode has a visible light reflectance higher than or equal to 10% and lower than or equal to 95%, preferably higher than or equal to 30% and lower than or equal to 80%. The reflective electrode has a visible light reflectance of higher than or equal to 40% and lower than or equal to 100%, preferably higher than or equal to 70% and lower than or equal to 100%. These electrodes preferably have a resistivity less than or equal to 1×10⁻² Ωcm.

Either a low molecular compound or a high molecular compound can be used for the light-emitting element, and an inorganic compound may also be contained. Each of the layers included in the light-emitting element can be formed by an evaporation method (including a vacuum evaporation method), a transfer method, a printing method, an inkjet method, a coating method, or the like.

The light-emitting layer can contain one or more kinds of light-emitting substances. As the light-emitting substance, a substance that exhibits an emission color of blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (a host material, an assist material, and the like) in addition to the light-emitting substance (a guest material). As one or more kinds of organic compounds, one or both of a substance with a high hole-transport property (hole-transport material) and a substance with a high electron-transport property (electron-transport material) can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength is to be overlapped with the wavelength of the lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer 763 may further include layers containing a substance with a high hole-injection property, a substance with a high hole-transport property, a hole-blocking material, a substance with a high electron-transport property, a substance with a high electron-injection property, an electron-blocking material, a substance with a bipolar property (a substance with a high electron-transport property and a high hole-transport property), and the like.

The hole-injection layer is a layer injecting holes from an anode to the hole-transport layer, and a layer containing a material with a high hole-injection property. Examples of the material with a high hole-injection property include an aromatic amine compound, a composite material containing a hole-transport material and an acceptor material (an electron-accepting material), and the like.

As the hole-transport material, it is possible to use a material with a high hole-transport property that can be used for the hole-transport layer and will be described later.

As the acceptor material, an oxide of a metal that belongs to any of Groups 4 to 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can be used. As the material with a high hole-injection property, a mixed material in which an oxide of a metal belonging to any of Group 4 to Group 8 of the periodic table (typically, molybdenum oxide) and an organic material are mixed may be used.

The hole-transport layer is a layer that transports holes, which are injected from the anode by the hole-injection layer, to the light-emitting layer. The hole-transport layer is a layer containing a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, materials with a high hole-transport property, such as a π-electron rich heteroaromatic compound (e.g., a carbazole derivative, a thiophene derivative, and a furan derivative) and an aromatic amine (a compound having an aromatic amine skeleton), are preferable.

The electron-blocking layer is provided in contact with the light-emitting layer. The electron-blocking layer has a hole-transport property and contains a material capable of blocking electrons. Any of the materials with an electron-blocking property among the above hole-transport materials can be used for the electron-blocking layer.

The electron-blocking layer has a hole-transport property, and thus can also be referred to as a hole-transport layer. A layer with an electron-blocking property among the hole-transport layers can also be referred to as an electron-blocking layer.

The electron-transport layer is a layer that transports electrons, which are injected from the cathode by the electron-injection layer, to the light-emitting layer. The electron-transport layer is a layer containing an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The hole-blocking layer is provided in contact with the light-emitting layer. The hole-blocking layer has an electron-transport property and contains a material capable of blocking holes. Any of the materials with a hole-blocking property among the above electron-transport materials can be used for the hole-blocking layer.

The hole-blocking layer has an electron-transport property, and thus can also be referred to as an electron-transport layer. A layer with a hole-blocking property among the electron-transport layers can also be referred to as a hole-blocking layer.

The electron-injection layer is a layer that injects electrons from the cathode to the electron-transport layer and a layer that contains a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

The LUMO level of the material with a high electron-injection property preferably has a small difference (specifically, 0.5 eV or less) from the work function of a material for the cathode.

For the electron-injection layer, it is possible to use, for example, an alkali metal, an alkaline earth metal, or a compound thereof, such as lithium, cesium, ytterbium, lithium fluoride (LiF), cesium fluoride (CsF), calcium fluoride (CaF_{X}, where X is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOx), or cesium carbonate. The electron-injection layer may have a stacked-layer structure of two or more layers. In the stacked-layer structure, for example, lithium fluoride can be used for the first layer and ytterbium can be used for the second layer.

The electron-injection layer may contain an electron-transport material. For example, a compound having an unshared electron pair and an electron deficient heteroaromatic ring can be used for the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a: 2′,3′-c]phenazine (abbreviation: HATNA), 2,4,6-tris[3′-(pyridin-3-yl) biphenyl-3-yl]-1,3,5-triazine (abbreviation: TmPPPyTz), or the like can be used for the organic compound having an unshared electron pair. Note that NBPhen has a higher glass transition temperature (Tg) than BPhen and thus has high heat resistance.

In the case of manufacturing a tandem light-emitting element, a charge-generation layer (also referred to as an intermediate layer) is provided between two light-emitting units. The intermediate layer has a function of injecting electrons into one of the two light-emitting units and injecting holes to the other when voltage is applied between the pair of electrodes.

For the charge-generation layer, for example, a material that can be used for the electron-injection layer, such as lithium, can be suitably used. For the charge-generation layer, for example, a material that can be used for the hole-injection layer can be suitably used. For the charge-generation layer, a layer containing a hole-transport material and an acceptor material (electron-accepting material) can be used. For the charge-generation layer, a layer containing an electron-transport material and a donor material can be used. Forming such a charge-generation layer can inhibit an increase in the driving voltage that would be caused by stacking light-emitting units.

This embodiment can be combined with the other embodiments as appropriate. In this specification, in the case where a plurality of structure examples are described in one embodiment, the structure examples can be combined as appropriate.

### Embodiment 5

In this embodiment, electronic devices of one embodiment of the present invention will be described.

Electronic devices of this embodiment include the display apparatus of one embodiment of the present invention in their display portions. The display apparatus of one embodiment of the present invention is highly reliable and can be easily increased in resolution and definition. Thus, the display apparatus of one embodiment of the present invention can be used for display portions of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display apparatus of one embodiment of the present invention can have a high resolution, and thus can be suitably used for an electronic device including a relatively small display portion. Examples of such an electronic device include a watch-type or a bracelet-type information terminal device (wearable device), and a wearable device worn on a head, such as a device for VR such as a head mounted display, a glasses-type device for AR, and a device for MR.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the resolution is preferably 4K, 8K, or higher. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With the use of such a display apparatus with one or both of high resolution and high definition, the electronic device can have higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (square), 4:3, 16:9, and 16:10. The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

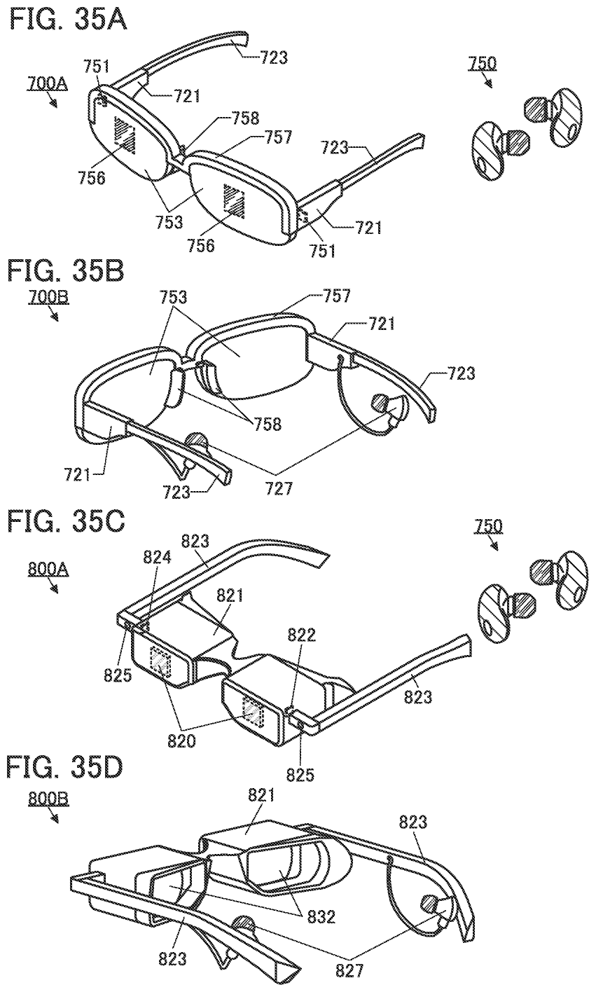

Examples of head-mounted wearable devices are described with reference to FIG. 35A to FIG. 35D. These wearable devices have at least one of a function of displaying AR contents, a function of displaying VR contents, a function of displaying SR contents, and a function of displaying MR contents. The electronic appliance having a function of displaying contents of at least one of AR, VR, SR, MR, and the like enables the user to feel a higher level of immersion.

An electronic device 700A illustrated in FIG. 35A and an electronic device 700B illustrated in FIG. 35B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used in the display panels 751. Thus, a highly reliable electronic device can be obtained.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when each of the electronic device 700A and the electronic device 700B is provided with an acceleration sensor such as a gyroscope sensor, the orientation of the user's head can be sensed and an image corresponding to the orientation can be displayed on the display region 756.

The communication portion includes a wireless communication device, and a picture signal, for example, can be supplied by the wireless communication device. Note that instead of or in addition to the wireless communication device, a connector to which a cable for supplying a picture signal and a power supply potential can be connected may be provided.

In addition, each of the electronic device 700A and the electronic device 700B is provided with a battery so that each of the electronic device 700A and the electronic device 700B can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be applied to the touch sensor module. Any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving element. One or both of an inorganic semiconductor and an organic semiconductor can be used for an active layer of the photoelectric conversion device.

An electronic device 800A illustrated in FIG. 35C and an electronic device 800B illustrated in FIG. 35D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, a highly reliable electronic device can be obtained.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. FIG. 35C illustrates an example in which the wearing portion 823 has a shape like a temple (also referred to as a joint or the like) of glasses, for example; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portion 825 is provided is described here, a range sensor capable of measuring a distance between the user and an object (hereinafter also referred to as a detecting portion) just needs to be provided. In other words, the image capturing portion 825 is one embodiment of the sensing portion. For the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be applied to any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying, for example, a video signal from a video output device, power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 35A has a function of transmitting information to the earphones 750 with the wireless communication function. As another example, the electronic device 800A in FIG. 35C has a function of transmitting information to the earphones 750 with the wireless communication function.

The electronic device may include an earphone portion. The electronic device 700B illustrated in FIG. 35B includes earphone portions 727. For example, the earphone portion 727 can be connected to the control portion by wire. Part of a wiring that connects the earphone portions 727 and the control portion may be positioned inside the housing 721 or the wearing portion 723.

Similarly, the electronic device 800B in FIG. 35D includes earphone portions 827. For example, the earphone portion 827 can be connected to the control portion 824 by wire. Part of a wiring that connects the earphone portions 827 and the control portion 824 may be positioned inside the housing 821 or the wearing portion 823. Alternatively, the earphone portions 827 and the mounting portions 823 may include magnets. This is preferable because the earphone portions 827 can be fixed to the wearing portions 823 with magnetic force and thus can be easily housed.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

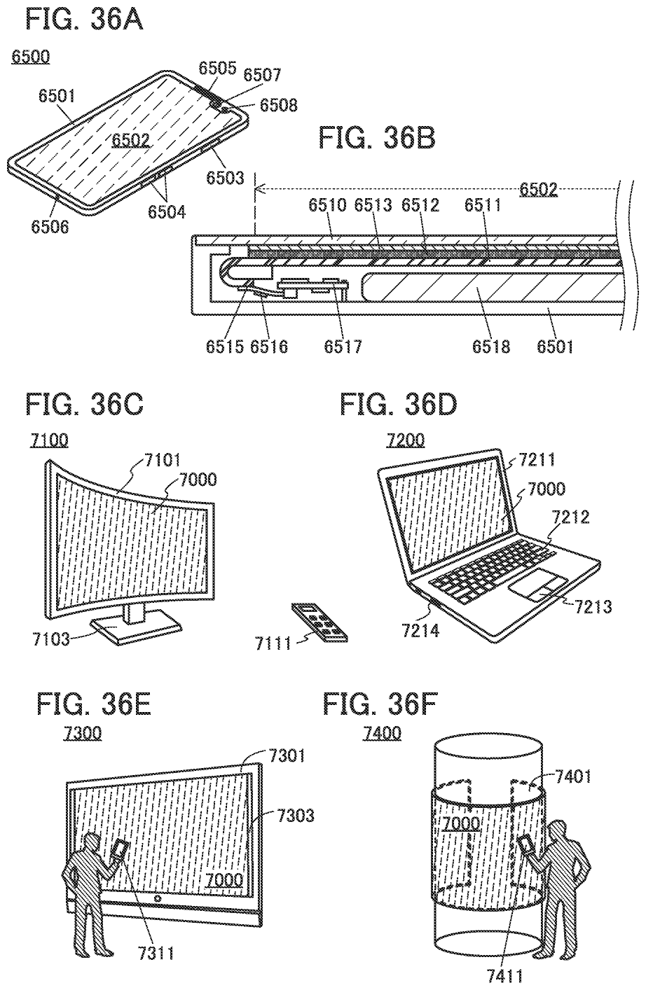

An electronic device 6500 in FIG. 36A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, a highly reliable electronic device can be obtained.

FIG. 36B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be obtained. Since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of the pixel portion, whereby an electronic device with a narrow bezel can be obtained.

FIG. 36C illustrates an example of a television device. In a television device 7100, a display portion 7000 is incorporated in a housing 7101. Here, the housing 7101 is supported by a stand 7103.

The display apparatus of one embodiment of the present invention can be used in the display portion 7000. Thus, a highly reliable electronic device can be obtained.

Operation of the television device 7100 illustrated in FIG. 36C can be performed with an operation switch provided in the housing 7101 and a separate remote controller 7111. Alternatively, the display portion 7000 may include a touch sensor, and the television device 7100 may be operated by a touch on the display portion 7000 with a finger or the like. The remote controller 7111 may include a display portion for displaying information output from the remote controller 7111. With operation keys or a touch panel provided in the remote controller 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 36D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used in the display portion 7000. Thus, a highly reliable electronic device can be obtained.

FIG. 36E and FIG. 36F illustrate examples of digital signage.

Digital signage 7300 illustrated in FIG. 36E includes a housing 7301, the display portion 7000, a speaker 7303, and the like. Furthermore, the digital signage can include an LED lamp, operation keys (including a power switch or an operation switch), a connection terminal, a variety of sensors, a microphone, and the like.

FIG. 36F is digital signage 7400 attached to a cylindrical pillar 7401. The digital signage 7400 includes the display portion 7000 provided along a curved surface of the pillar 7401.

The display apparatus of one embodiment of the present invention can be used in the display portion 7000 in FIG. 36E and FIG. 36F. Thus, a highly reliable electronic device can be obtained.

A larger area of the display portion 7000 can increase the amount of information that can be provided at a time. The larger the display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 36E and FIG. 36F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

Furthermore, it is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

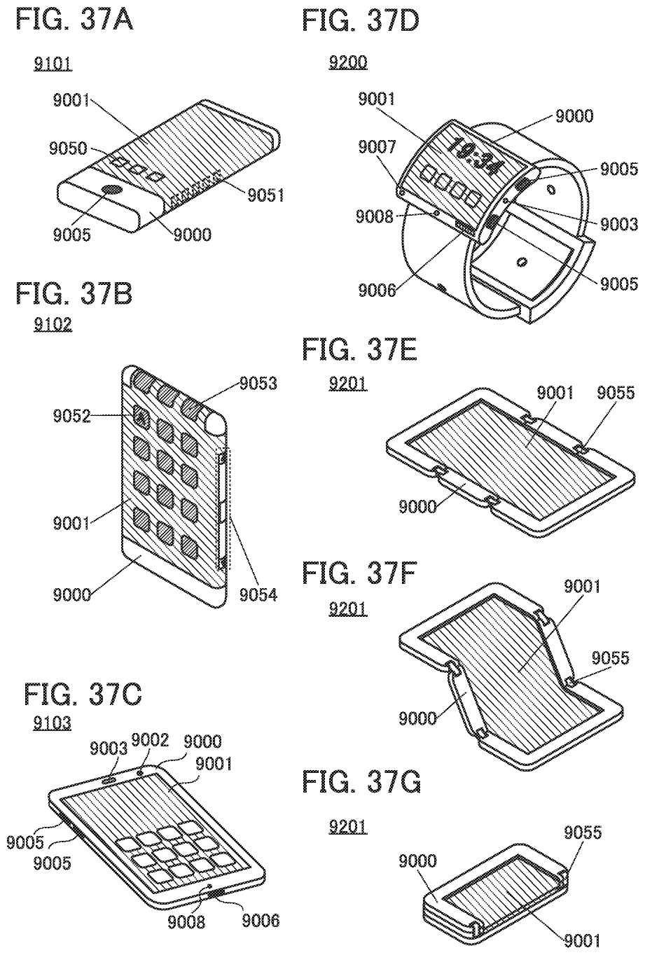

Electronic devices illustrated in FIG. 37A to FIG. 37G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, a smell, or infrared ray), a microphone 9008, and the like.

The electronic devices illustrated in FIG. 37A to FIG. 37G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may be provided with, for example, a camera and have a function of capturing a still image or a moving image, a function of storing the captured image in a storage medium (an external storage medium or a storage medium incorporated in the camera), a function of displaying the captured image on the display portion, and the like.

The electronic devices illustrated in FIG. 37A to FIG. 37G are described in detail below.

FIG. 37A is a perspective view illustrating a portable information terminal 9101. The portable information terminal 9101 can be used as a smartphone, for example. Note that the portable information terminal 9101 may be provided with the speaker 9003, the connection terminal 9006, the sensor 9007, or the like. The portable information terminal 9101 can display characters and image information on its plurality of surfaces. FIG. 37A illustrates an example in which three icons 9050 are displayed. Furthermore, information 9051 indicated by dashed rectangles can be displayed on another surface of the display portion 9001. Examples of the information 9051 include notification of reception of an e-mail, SNS, or an incoming call, the title and sender of an e-mail, SNS, or the like, the date, the time, remaining battery, and the radio field intensity. Alternatively, the icon 9050 or the like may be displayed at the position where the information 9051 is displayed.

FIG. 37B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is described. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 37C is a perspective view of a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 37D is a perspective view illustrating a watch-type portable information terminal 9200. The portable information terminal 9200 can be used for a Smartwatch (registered trademark), for example. The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 37E to FIG. 37G are perspective views illustrating a foldable portable information terminal 9201. FIG. 37E is a perspective view of an opened state of the portable information terminal 9201, FIG. 37G is a perspective view of a folded state thereof, and FIG. 37F is a perspective view of a state in the middle of change from one of FIG. 37E and FIG. 37G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate. In this specification, in the case where a plurality of structure examples are described in one embodiment, the structure examples can be combined as appropriate.

### REFERENCE NUMERALS

100A: display apparatus, 100B: display apparatus, 100C: display apparatus, 100D: display apparatus, 100E: display apparatus, 100F: display apparatus, 100G: display apparatus, 100H: display apparatus, 100I: display apparatus, 100J: display apparatus, 100: display apparatus, 101: insulating layer, 102: conductive layer, 103: insulating layer, 104: insulating layer, 105: insulating layer, 106: plug, 107: pixel portion, 108: pixel, 109: conductive layer, 110B: subpixel, 110G: subpixel, 110R: subpixel, 110W: subpixel, 110: subpixel, 111B: pixel electrode, 111f: conductive film, 111G: pixel electrode, 111R: pixel electrode, 111: pixel electrode, 113B: EL layer, 113Bf: EL film, 113f: EL film, 113G: EL layer, 113Gf: EL film, 113R: EL layer, 113Rf: EL film, 113: EL layer, 114: common layer, 115: common electrode, 117: light-blocking layer, 118B: mask layer, 118Bf: mask film, 118f: mask film, 118G: mask layer, 118Gf: mask film, 118R: mask layer, 118Rf: mask film, 118: mask layer, 119B: mask layer, 119Bf: mask film, 119f: mask film, 119G: mask layer, 119Gf: mask film, 119R: mask layer, 119Rf: mask film, 119: mask layer, 120: substrate, 122: resin layer, 123: conductive layer, 124a: pixel, 124b: pixel, 125f: insulating film, 125: insulating layer, 127a: insulating layer, 127f: insulating film, 127: insulating layer, 128: layer, 130B: light-emitting element, 130G: light-emitting element, 130R: light-emitting element, 130: light-emitting element, 131: protective layer, 132a: mask, 132b: mask, 132B: coloring layer, 132G: coloring layer, 132R: coloring layer, 132: coloring layer, 133: region, 134: depressed portion, 140: connection portion, 141: region, 142: adhesive layer, 151: substrate, 152: substrate, 153: insulating layer, 164: circuit, 165: wiring, 166: conductive layer, 172: FPC, 173: IC, 190B: resist mask, 190G: resist mask, 190R: resist mask, 190: resist mask, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 224B: conductive layer, 224C: conductive layer, 224G: conductive layer, 224R: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: connection layer, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: EL layer, 763b: EL layer, 763: EL layer, 764: layer, 771: light-emitting layer, 772: light-emitting layer, 773: light-emitting layer, 780: layer, 781: layer, 782: layer, 785: charge-generation layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a first light-emitting element;
a second light-emitting element;
a first insulating layer; and
a second insulating layer,
the first light-emitting element comprising:
a first pixel electrode;
a first EL layer over the first pixel electrode; and
a common electrode over the first EL layer,
the second light-emitting element comprising:
a second pixel electrode;
a second EL layer over the second pixel electrode; and
the common electrode over the second EL layer,
wherein the first insulating layer covers a side surface and part of a top surface of the first EL layer and a side surface and part of a top surface of the second EL layer,
wherein the second insulating layer overlaps with the part of the top surface of the first EL layer and the part of the top surface of the second EL layer with the first insulating layer therebetween,
wherein the second insulating layer comprises a region positioned between the side surface of the first EL layer and the side surface of the second EL layer,
wherein the second insulating layer comprises a depressed portion in a position overlapping with the region, and
wherein the common electrode is provided over the second insulating layer.

2. The display apparatus according to claim 1,
wherein the depressed portion of the second insulating layer comprises a concave shape.

3. The display apparatus according to claim 1,
wherein a shortest part in the depressed portion in a cross-sectional view does not overlap with either the first EL layer or the second EL layer.

4. The display apparatus according to claim 1,
the first EL layer further comprising:
a first light-emitting layer; and
a first functional layer over the first light-emitting layer, and
the second EL layer further comprising:
a second light-emitting layer; and
a second functional layer over the second light-emitting layer,
wherein the first functional layer and the second functional layer each comprise at least one of a hole-injection layer, an electron-injection layer, a hole-transport layer, an electron-transport layer, a hole-blocking layer, and an electron-blocking layer.

5. The display apparatus according to claim 1,
wherein the second insulating layer covers at least part of a side surface of the first insulating layer.

6. The display apparatus according to claim 1,
wherein an end portion of the second insulating layer is positioned on an outer side of an end portion of the first insulating layer.

7. The display apparatus according to claim 1,
wherein the end portion of the first insulating layer and the end portion of the second insulating layer have a tapered shape with a taper angle of less than 90° in a cross-sectional view.

8. The display apparatus according to claim 1, further comprising:
a third insulating layer; and
a fourth insulating layer,
wherein the third insulating layer is positioned between the top surface of the first EL layer and the first insulating layer,
wherein the fourth insulating layer is positioned between the top surface of the second EL layer and the first insulating layer, and
wherein an end portion of the third insulating layer and an end portion of the fourth insulating layer are each positioned on the outer side of the end portion of the first insulating layer.

9. The display apparatus according to claim 8,
wherein the second insulating layer covers at least part of a side surface of the third insulating layer and at least part of a side surface of the fourth insulating layer.

10. The display apparatus according to claim 8,
wherein the end portion of the third insulating layer and the end portion of the fourth insulating layer each have a tapered shape with a taper angle of less than 90° in a cross-sectional view.

11. The display apparatus according to claim 1,
wherein the first insulating layer is an inorganic insulating layer, and
wherein the second insulating layer is an organic insulating layer.

12. A display module comprising:
the display apparatus according to claim 1; and
at least one of a connector and an integrated circuit.

13. An electronic device comprising:
the display module according to claim 12; and
at least one of a housing, a battery, a camera, a speaker, and a microphone.

14. A method for manufacturing a display apparatus, comprising the steps of:
forming a first pixel electrode and a second pixel electrode;
forming a first EL film over the first pixel electrode and the second pixel electrode;
forming a first mask film over the first EL film;
forming a first EL layer over the first pixel electrode and a first mask layer over the first EL layer by processing the first EL film and the first mask film;
forming a second EL film over the first mask layer and the second pixel electrode;
forming a second mask film over the second EL film;
forming a second EL layer over the second pixel electrode and a second mask layer over the second EL layer by processing the second EL film and the second mask film;
forming an inorganic insulating film over the first mask layer and the second mask layer;
forming an organic insulating film over the inorganic insulating film with the use of a photosensitive material;
forming an organic insulating layer in a region positioned between a side surface of the first EL layer and a side surface of the second EL layer by performing first light exposure and first development on the organic insulating film;
reducing the thickness of part of the inorganic insulating film by performing first etching treatment on the inorganic insulating film with the use of a first chemical solution and the organic insulating layer as a mask;
performing second light exposure on the organic insulating layer;
performing, with the use of a second chemical solution configured to serve as a developer, second development on the organic insulating layer and second etching treatment on the inorganic insulating film, the first mask layer, and the second mask layer with the use of the organic insulating layer as a mask to form a depressed portion in the organic insulating layer in a position overlapping with the region, form an inorganic insulating layer under the organic insulating layer, and reduce a thickness of part of the first mask layer and a thickness of part of the second mask layer;
curing the organic insulating layer by performing heat treatment;
exposing a top surface of the first EL layer and a top surface of the second EL layer by performing third etching treatment on the first mask layer and the second mask layer with the use of a third chemical solution and the organic insulating layer as a mask; and
forming a common electrode over the first EL layer, [over] the second EL layer, and the organic insulating layer.

15. The method for manufacturing a display apparatus, according to claim 14,
wherein the energy density of the second light exposure is lower than the energy density of the first light exposure.

16. The method for manufacturing a display apparatus, according to claim 14,
wherein the first chemical solution is configured to serve as a developer.

17. The method for manufacturing a display apparatus, according to claim 14,
wherein the first chemical solution and the third chemical solution are each configured to serve as a developer.

18. The method for manufacturing a display apparatus, according to claim 14,
wherein the first mask film and the second mask film comprise the same material as the inorganic insulating film.

19. The method for manufacturing a display apparatus, according to claim 14,
wherein the first mask film, the second mask film, and the inorganic insulating film are each formed by an ALD method.

20. The method for manufacturing a display apparatus, according to claim 14,
wherein a first light-emitting film and a first functional film over the first light-emitting film are formed as the first EL film,
wherein a second light-emitting film and a second functional film over the second light-emitting film are formed as the second EL film, and
wherein the first functional film and the second functional film each comprise at least one of films to be a hole-injection layer, an electron-injection layer, a hole-transport layer, an electron-transport layer, a hole-blocking layer, and an electron-blocking layer.
